(19) United States
(12) Patent Application Publication
(10) Pub. No.: US 2024/0360360 A1
(43) Pub. Date: Oct. 31, 2024

(54) ELECTROLUMINESCENT DEVICE AND DISPLAY DEVICE

(71) Applicants: SHARP KABUSHIKI KAISHA, Sakai City, Osaka (JP); NS Materials Inc., Chikushino-city, Fukuoka (JP)

(72) Inventors: Masaki YAMAMOTO, Sakai City, Osaka (JP); Kazuki GOTO, Sakai City, Osaka (JP); HIROHISA YAMADA, Sakai City, Osaka (JP); MASAYA UEDA, Sakai City, Osaka (JP); Yuko OGURA, Chikushino-city, Fukuoka (JP); Masanori TANAKA, Chikushino-city, Fukuoka (JP); Mikihiro TAKASAKI, Chikushino-city, Fukuoka (JP); Yuka TAKAMIZUMA, Chikushino-city, Fukuoka (JP); Soichiro NIKATA, Chikushino-city, Fukuoka (JP); Tetsuji ITO, Chikushino-city, Fukuoka (JP); Mayuko WATANABE, Chikushino-city, Fukuoka (JP)

(21) Appl. No.: 18/273,976

(22) PCT Filed: Jan. 28, 2021
(86) PCT No.: PCT/JP2021/003074

§ 371 Date: Jul. 25, 2023

(51) Int. Cl. C09K 11/88; C09K 11/02; C09K 11/56; H10K 50/115; H10K 50/87

(52) U.S. Cl. CPC C09K 11/883; C09K 11/02; C09K 11/565; H10K 50/115; H10K 50/87

(57) ABSTRACT

A quantum dot includes a core including Zn and Se, and a shell composed of ZnS and provided on a surface of the core, adjacently to the core. The quantum dot-emits blue light, is Cd free, and has a particle diameter within a range from 3 nm to 20 nm and a fluorescence lifetime in a thin film state of 50 ns or less.

### TECHNICAL FIELD

The disclosure relates to a quantum dot, an electroluminescent device and a manufacturing method therefor, a light-emitting device, a display device, and a control method of the display device.

### BACKGROUND ART

An electroluminescent device that uses quantum dots is expected to have a higher reliability, larger size, higher definition, lower cost, and the like compared to an organic electroluminescent (EL) element. For this reason, electroluminescent devices that use quantum dots have attracted attention as electroluminescent devices for next-generation displays.

For example, PTL 1 discloses an electroluminescent device using a quantum dot including a core including zinc (Zn), tellurium (Te), and selenium (Se) and a shell including a material different from those of the core (for example, Zn, Se, and sulfur (S)). NPL 1 discloses an electroluminescent device that uses, as a quantum dot, ZnSe/ZnS formed by adding zinc octanoate and trioctylphosphine sulfide to a ZnSe nanoparticle solution and heating at 280° C. for 20 minutes.

Further, PTL 2 discloses a quantum dot obtained by overcoating a cadmium (Cd)-based core such as CdSe with a shell such as ZnS. NPL 2 discloses a quantum dot obtained by using ZnSeTe for the core and ZnS for the shell.

### CITATION LIST

### Patent Literature

PTL 1: US 2019/0280231 A
PTL 2: JP 2001-523758 A

### Non Patent Literature

NPL 1: Christian Ippen, et al., “ZnSe/ZnS quantum dots as emitting material in blue QD-LEDs with narrow emission peak and wavelength tunability,” Organic Electronics 15 (2014), pp. 126-131
NPL 2: Chunliang Li, et al., “Synthesis of Cd-free water-soluble ZnSel-xTex nanocrystals with high luminescence in the blue region,” Journal of Colloid and Interface Science 321 (2008), 321, pp. 468-476

### SUMMARY

### Technical Problem

However, in an electroluminescent device including a quantum dot layer including known quantum dots, there is a possibility that the quantum dot layer or the like deteriorates due to environmental changes, the passage of time, or the like, irreversibly reducing a fluorescence quantum efficiency of the quantum dot layer, for example. As a result, there is a possibility that the electroluminescent device using the quantum dot layer as a light-emitting layer irreversibly reduces in luminance with this deterioration of the quantum dot layer or the like.

An aspect of the disclosure has been made in view of the above-described problems, and an object thereof is to provide a quantum dot that can be used to obtain an electroluminescent device that can increase a fluorescence quantum efficiency when the quantum dot is formed into a quantum dot layer and can improve a lowered luminance even when the luminance is temporarily decreased due to deterioration of the quantum dot layer or the like, by the quantum dot being heated, an electroluminescent device including the quantum dot and a manufacturing method therefor, a light-emitting device including the quantum dot, a display device including the quantum dot, and a control method of the display device.

### Solution to Problem

To solve the problem described above, a quantum dot according to an aspect of the disclosure includes a core including Zn and Se, and a shell composed of ZnS and provided on a surface of the core, adjacently to the core. The quantum dot emits blue light, is Cd free, and has a particle diameter within a range from 3 nm to 20 nm and a fluorescence lifetime in a thin film state of 50 ns or less.

To solve the problem described above, a quantum dot according to an aspect of the disclosure includes a core composed of ZnSe, and a shell composed of ZnS and provided on a surface of the core, adjacently to the core. The quantum dot emits blue light and is Cd free, and 3≤d≤20 and d−(6.1/((1240/λp)−2.7))^{1/2}≤3.2, where λp (nm) is a fluorescent peak wavelength and d (nm) is a particle diameter of the quantum dot.

To solve the problem described above, an electroluminescent device according to an aspect of the disclosure includes a first electrode, a second electrode, and a light-emitting layer provided between the first electrode and the second electrode. The light-emitting layer includes the quantum dot according to an aspect of the disclosure.

To solve the problem described above, a light-emitting device according to an aspect of the disclosure includes at least one electroluminescent device according to an aspect of the disclosure.

To solve the problem described above, a display device according to an aspect of the disclosure includes a plurality of pixels including at least one blue pixel. Each of the plurality of pixels is provided with an electroluminescent device, and the electroluminescent device provided to the blue pixel includes a first electrode, a second electrode, a light-emitting layer provided between the first electrode and the second electrode, and at least one heat source configured to heat the light-emitting layer. The light-emitting layer includes the quantum dot according to an aspect of the disclosure.

To solve the problem described above, a control method of the display device according to an aspect of the disclosure is a control method of a display device including a plurality of pixels including at least one blue pixel, each of the plurality of pixels being provided with an electroluminescent device. The display device further includes a luminance sensor configured to measure, when at least one of the electroluminescent devices emits light, the luminance of the electroluminescent device, a storage unit configured to store the luminance measured by the luminance sensor as a luminance value, and a control unit. The electroluminescent device provided to the blue pixel includes a first electrode, a second electrode, a light-emitting layer provided between the first electrode and the second electrode, and at least one heat source configured to heat the light-emitting layer. The light-emitting layer includes the quantum dot according to an aspect of the disclosure. The control unit is configured to cause the storage unit to store, as a first luminance value, a luminance of the electroluminescent device measured by the luminance sensor when the electroluminescent device before being heated by the heat source emits light according to a current value set in advance, cause, when the first luminance value stored in the storage unit is less than a target luminance value set in advance, the storage unit to store, as a second luminance value, a luminance of the electroluminescent device measured by the luminance sensor when, after the light-emitting layer is heated by the heat source under a heating condition set in advance, the electroluminescent device emits light according to the current value set in advance, overwrite the first luminance value with the second luminance value stored in the storage unit when the second luminance value stored in the storage unit is equal to or greater than the first luminance value and less than the target luminance value, and heat the light-emitting layer by the heat source under the heating condition set in advance when at least one of the first luminance value or the second luminance value is less than the target luminance value. The control method includes storing in the storage unit, as the first luminance value, a luminance measured by the luminance sensor when the electroluminescent device emits light according to the current value set in advance, heating, when the first luminance value stored in the storage unit is less than the target luminance value set in advance, the light-emitting layer by the heat source under the heating condition set in advance, storing in the storage unit, as the second luminance value, a luminance measured by the luminance sensor when, after the light-emitting layer is heated during the heating, the electroluminescent device emits light according to the current value set in advance, and overwriting the first luminance value with the second luminance value stored in the storage unit and heating the light-emitting layer once again when the second luminance value stored in the storage unit during the storing as the second luminance value is equal to or greater than the first luminance value and less than the target luminance value.

To solve the problem described above, a method for manufacturing the electroluminescent device according to an aspect of the disclosure includes forming the light-emitting layer, and heating the light-emitting layer at a temperature from 80° C. to 100° C. for 30 minutes to 600 minutes after the forming.

To solve the problem described above, an electroluminescent device according to an aspect of the disclosure is an electroluminescent device manufactured by the method of manufacturing the electroluminescent device according to an aspect of the disclosure.

### Advantageous Effects of Disclosure

According to an aspect of the disclosure, it is possible to provide a quantum dot that can be used to obtain an electroluminescent device that can increase a fluorescence quantum efficiency when the quantum dot is formed into a quantum dot layer and can improve a lowered luminance even when the luminance is temporarily decreased due to deterioration of the quantum dot layer or the like, by the quantum dot being heated, an electroluminescent device including the quantum dot and a manufacturing method therefor, a light-emitting device including the quantum dot, a display device including the quantum dot, and a control method of the display device.

### BRIEF DESCRIPTION OF DRAWINGS

FIG. 1 is a schematic view illustrating an example of a quantum dot according to a first embodiment.

FIG. 2 is a cross-sectional view schematically illustrating a schematic configuration of a light-emitting device according to the first embodiment.

FIG. 3 is a cross-sectional view schematically illustrating a schematic configuration of main portions of a display device according to a second embodiment.

FIG. 4 is a diagram schematically illustrating a schematic configuration of the main portions of the display device according to the second embodiment in a cross section taken along line A-A in FIG. 3.

FIG. 5 is a cross-sectional view for describing a size of a heating element layer illustrated in FIG. 3.

FIG. 6 is a cross-sectional view illustrating, in process order, a method for manufacturing the main portions of the display device according to the second embodiment.

FIG. 7 is another cross-sectional view illustrating, in process order, the method for manufacturing the main portions of the display device according to the second embodiment.

FIG. 8 is a cross-sectional view schematically illustrating an example of a schematic configuration of main portions of the display device according to a first modified example of the second embodiment.

FIG. 9 is a cross-sectional view schematically illustrating an example of a schematic configuration of main portions of the display device according to a second modified example of the second embodiment.

FIG. 10 is a perspective view schematically illustrating a schematic configuration of main portions of the display device according to a third modified example of the second embodiment.

FIG. 11 is a cross-sectional view schematically illustrating a schematic configuration of the main portions of the display device according to the third modified example of the second embodiment.

FIG. 12 is a cross-sectional view schematically illustrating a schematic configuration of main portions of a display device according to a third embodiment.

FIG. 13 is a cross-sectional view illustrating, in process order, a method for manufacturing the main portions of the display device according to the third embodiment.

FIG. 14 is another cross-sectional view illustrating, in process order, the method for manufacturing the main portions of the display device according to the third embodiment.

FIG. 15 is a cross-sectional view schematically illustrating a schematic configuration of main portions of the display device according to a first modified example of the third embodiment.

FIG. 16 is a cross-sectional view illustrating, in process order, a method for manufacturing the main portions of the display device according to the first modified example of the third embodiment.

FIG. 17 is a cross-sectional view schematically illustrating a schematic configuration of main portions of a display device according to a fourth embodiment.

FIG. 18 is a diagram illustrating, in a cross-sectional view and a top view and in process order, a method for manufacturing the main portions of the display device according to the fourth embodiment.

FIG. 19 is another diagram illustrating, in a cross-sectional view and a top view and in process order, the method for manufacturing the display device according to the fourth embodiment.

FIG. 20 is a block diagram illustrating a schematic configuration of main portions of a display device according to a fifth embodiment.

FIG. 21 is a flowchart illustrating a flow of processing of luminance improvement control executed by a control unit in the display device illustrated in FIG. 20.

### DESCRIPTION OF EMBODIMENTS

### First Embodiment

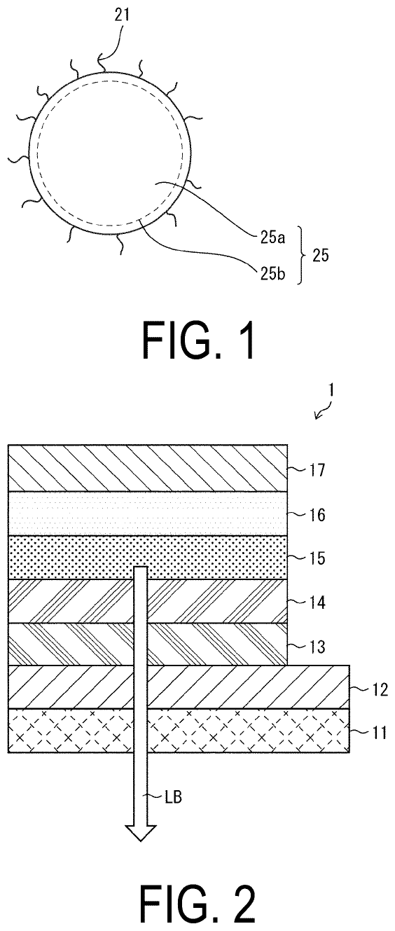

An embodiment of the disclosure will be described below with reference to FIGS. 1 and 2. Below, an electroluminescent device (hereinafter simply referred to as “light-emitting device”) according to the present embodiment will be described. Note that, in the following, a description of “from A to B” for two numbers A and B is intended to mean “equal to or greater than A and equal to or less than B,” unless otherwise specified.

### Structural Example of Light-Emitting Device

FIG. 2 is a cross-sectional view schematically illustrating a schematic configuration of a light-emitting device 1 according to the present embodiment.

The light-emitting device 1 illustrated in FIG. 2 emits light when a voltage is applied to a quantum dot (also referred to as a semiconductor nanoparticle). Examples of the light-emitting device 1 include a quantum dot light-emitting diode (QLED). Note that hereinafter, a quantum dot is abbreviated as “QD”. In the present embodiment, the QD included in the light-emitting device 1 is a blue QD.

The light-emitting device 1 includes an anode 12 (anode), a cathode 17 (cathode), and a function layer provided between the anode 12 and the cathode 17. The function layer includes at least a QD layer 15 (quantum dot light-emitting layer, blue quantum dot light-emitting layer) including QDs. Note that, in the present embodiment, the layers between the anode 12 and the cathode 17 are collectively referred to as a function layer.

The function layer may be a single layer type formed only of the QD layer 15, or may be a multi-layer type including a function layer in addition to the QD layer 15. Of the function layer, examples of function layers besides the QD layer 15 include a hole injection layer 13 (HIL), a hole transport layer 14 (HTL), and an electron transport layer 16 (ETL).

Note that, in the disclosure, a direction from the anode 12 to the cathode 17 in FIG. 2 is referred to as an upward direction, and the opposite direction thereof is referred to as a downward direction. In the disclosure, a horizontal direction is a direction (main surface direction of each portion included in the light-emitting device 1) perpendicular to a vertical direction. The vertical direction can also be referred to as a normal direction of each portion described above.

Each layer from the anode 12 to the cathode 17 is generally formed on a substrate used as a support body. Accordingly, the light-emitting device 1 may be provided with a substrate as a support body.

The light-emitting device 1 illustrated in FIG. 2 illustrates, as an example, a case in which a lower electrode (first electrode) is the anode 12 and an upper electrode (second electrode) is the cathode 17. However, the present embodiment is not limited thereto, and the lower electrode may be the cathode 17 and the upper electrode may be the anode 12.

That is, as one example, the light-emitting device 1 illustrated in FIG. 2 has a configuration in which the anode 12, the hole injection layer 13, the hole transport layer 14, the QD layer 15, the electron transport layer 16, and the cathode 17 are layered, in this order, on a substrate 11 in the upward direction of FIG. 2. However, the light-emitting device 1 is not limited to the above configuration, and may have a configuration in which the cathode 17, the electron transport layer 16, the QD layer 15, the hole transport layer 14, the hole injection layer 13, and the anode 12 are layered, in this order, on the substrate 11.

Thus, the QD layer 15 is interposed between the anode 12 and the cathode 17. In other words, the anode 12 and the cathode 17 are provided so as to sandwich the QD layer 15. Note that the light-emitting device 1 may include an electron injection layer between the QD layer 15 and the cathode 17. For example, when the light-emitting device 1 includes the electron transport layer 16 as illustrated in FIG. 2, the light-emitting device 1 may include an electron injection layer between the electron transport layer 16 and the cathode 17.

Hereinafter, each layer described above will be described in greater detail.

The substrate 11 is a support body for forming each layer from the anode 12 to the cathode 17, as described above. As illustrated in FIG. 2, the substrate 11 supports, in the upward direction thereof, the anode 12, the hole injection layer 13, the hole transport layer 14, the QD layer 15, the electron transport layer 16, and the cathode 17.

The substrate 11 may be, for example, a glass substrate, or may be a flexible substrate such as a plastic substrate.

Note that the light-emitting device 1 may be used as, for example, a light source of an electronic device such as a display device (light-emitting device). When the light-emitting device 1 is part of a display device (light-emitting device), for example, a substrate of the display device is used as the substrate 11. Thus, the light-emitting device 1 may be referred to as the light-emitting device 1 including the substrate 11, or may be referred to as the light-emitting device 1 not including the substrate 11.

In this manner, the light-emitting device 1 may itself include the substrate 11, or the substrate 11 of the light-emitting device 1 may be a substrate of an electronic device such as a display device (light-emitting device) provided with the light-emitting device 1. When the light-emitting device 1 is part of a display device (light-emitting device), for example, an array substrate on which a plurality of thin film transistors are formed may be used as the substrate 11.

In this case, the anode 12, which is the lower electrode provided on the substrate 11, may be electrically connected to the thin film transistors of the array substrate. In the case in which the light-emitting device 1 is, for example, part of a display device (light-emitting device) in this manner, the light-emitting device 1 is provided as a light source on the substrate 11 for each pixel. Specifically, a red pixel (R pixel) is provided with, as a red light source, a light-emitting device (red light-emitting device) that emits red light. A green pixel (G pixel) is provided with, as a green light source, a light-emitting device (green light-emitting device) that emits green light. A blue pixel (B pixel) is provided with, as a blue light source, a light-emitting device (blue light-emitting device) that emits blue light. Accordingly, banks partitioning adjacent pixels may be formed as pixel separation films such that light-emitting devices can be formed on the substrate 11 for each R pixel, G pixel, and B pixel.

In the present embodiment, as described above, a case is described in which the light-emitting device 1 illustrated in FIG. 2 is a blue light-emitting device in which the QD layer 15 including blue QDs is used. However, the above-mentioned red light-emitting device is enabled by providing a QD layer including red QDs as the QD layer 15. Similarly, the above-mentioned green light-emitting device is enabled by providing a QD layer including green QDs as the QD layer 15.

In a bottom emission (BE) type light-emitting device, light emitted from the QD layer 15 is emitted downward (that is, towards the substrate 11 side). In a top emission (TE) type light-emitting device, light emitted from the QD layer 15 is emitted upward (that is, towards the side opposite to the substrate 11). In a double-sided light-emitting device, the light emitted from the QD layer 15 is emitted downward and upward.

In a case in which the light-emitting device 1 is a bottom emission (BE) type light-emitting device or a double-sided light-emitting device, the substrate 11 is constituted of a transparent substrate made of a light-transmissive material. In a case in which the light-emitting device 1 is a top emission (TE) type light-emitting device, the substrate 11 may be constituted of a light-transmissive material, or may be constituted of a light-reflective material.

Of the anode 12 and the cathode 17, the electrode serving as the light output face side must be light-transmissive. Also note that the electrode of the side opposite the light output face may or may not be light-transmissive.

For example, when the light-emitting device 1 is a BE-type light-emitting device, the electrode on the upper-layer side is a light reflective electrode, and the electrode on the lower-layer side is a light-transmissive electrode. When the light-emitting device 1 is a TE-type light-emitting device, the electrode on the upper-layer side is a light-transmissive electrode, and the electrode on the lower-layer side is a light reflective electrode. Note that the light reflective electrode may be a layered body of a layer formed of a light-transmissive material and a layer formed of a light-reflective material.

FIG. 2 illustrates, as one example, a case in which the light-emitting device 1 is a BE-type light-emitting device in which the anode 12 is used as the electrode on the lower-layer side, the cathode 17 is used as the electrode on the upper-layer side, and blue light LB emitted from the QD layer 15 is emitted downward. Therefore, a light-transmissive electrode is used as the anode 12 such that the blue light LB emitted from the QD layer 15 can be transmitted through the anode 12. A light reflective electrode is used as the cathode 17 such that the blue light LB emitted from the QD layer 15 is reflected. Note that in the following description, the “blue light LB” is also abbreviated simply as “LB.” Other members will be similarly abbreviated as appropriate.

The anode 12 is an electrode that supplies positive holes (holes) to the QD layer 15 when a voltage is applied. The anode 12 includes for example, a material having a relatively large work function. Examples of the material include tin-doped indium oxide (ITO), zinc-doped indium oxide (IZO), aluminum-doped zinc oxide (AZO), gallium-doped zinc oxide (GZO), and antimony-doped tin oxide (ATO). A single type of these materials may be used alone, or two or more types may be mixed and used, as appropriate.

The cathode 17 is an electrode that supplies electrons to the QD layer 15 when a voltage is applied to the cathode 17. The cathode 17 includes, for example, a material having a relatively small work function. Examples of the material include aluminum (Al), silver (Ag), barium (Ba), ytterbium (Yb), calcium (Ca), lithium (Li)—Al alloys, magnesium (Mg)—Al alloys, Mg—Ag alloys, Mg-indium (In) alloys, and Al-aluminum oxide (Al₂O₃) alloys.

Film formation of the anode 12 and the cathode 17 may be implemented using, for example, physical vapor deposition (PVD), such as sputtering or vacuum vapor deposition, a spin coating method, or an ink-jet method.

The hole injection layer 13 is a layer that transports positive holes, supplied from the anode 12, to the hole transport layer 14. The hole injection layer 13 may be formed of an organic material or may be formed of an inorganic material. An example of the organic material is an electrically conductive polymer material. As the polymer material, for example, a composite (PEDOT:PSS) of poly(3,4-ethylenedioxythiophene) (PEDOT), poly(3,4-ethylenedioxythiophene) (PEDOT) and polystyrene sulfonic acid (PSS) can be used.

The hole transport layer 14 is a layer that transports positive holes, supplied from the hole injection layer 13, to the QD layer 15. The hole transport layer 14 may be formed of an organic material or may be formed of an inorganic material. An example of the organic material is an electrically conductive polymer material. As the polymer material, for example, poly[(9,9-dioctylfluorenyl-2,7-diyl)-co-(4,4′-(N-(4-sec-butylphenyl) diphenylamine))] (TFB) and poly(N-vinylcarbazole) (PVK) can be used. A single type of these polymer materials may be used alone, or two or more types may be mixed and used, as appropriate. In addition, the hole transport layer 14 is preferably formed so as to have a layer thickness within a range from 5 nm to 50 nm. This allows an even higher external quantum efficiency (EQE) to be obtained.

In the film formation of the hole injection layer 13 and the hole transport layer 14, for example, PVD such as sputtering or vacuum vapor deposition, spin coating, or an ink-jet method may be used. Note that in a case in which positive holes can be sufficiently supplied to the QD layer 15 only by the hole transport layer 14, the hole injection layer 13 need not be provided.

The electron transport layer 16 is a layer that transports electrons, supplied from the cathode 17, to the QD layer 15. The electron transport layer 16 may be formed of an organic material or may be formed of an inorganic material. When the electron transport layer 16 is formed of an inorganic material, the electron transport layer 16 may include, as the inorganic material, a metal oxide including at least one element selected from the group consisting of zinc (Zn), magnesium (Mg), titanium (Ti), silicon (Si), tin (Sn), tungsten (W), tantalum (Ta), barium (Ba), zirconium (Zr), aluminum (Al), yttrium (Y), and hafnium (Hf), for example. Examples of such metal oxides include zinc oxide (ZnO) and zinc magnesium oxide (ZnMgO). A single type of these metal oxides may be used alone, or two or more types may be mixed and used, as appropriate. Also, nanoparticles may be used in the inorganic material. When the electron transport layer 16 is formed of an inorganic material, PVD such as sputtering and vacuum vapor deposition, spin coating, or an ink-jet method, for example, can be used for film formation of the electron transport layer 16.

If the electron transport layer 16 is formed of an organic material, the electron transport layer 16 preferably includes, as the organic material, at least one type of compound selected from the group consisting of (i) 1,3,5-tris(1-phenyl-1H-benzimidazol-2-yl)benzene (TPBi), (ii) 3-(biphenyl-4-yl)-5-(4-tert-butylphenyl)-4-phenyl-4H-1,2,4-triazole (TAZ), (iii) bathophenanthroline (Bphen), and (iv) tris(2,4,6-trimethyl-3-(pyridin-3-yl)phenyl)borane (3TPYMB), for example. When the electron transport layer 16 is formed of an organic material, vacuum vapor deposition, spin coating, or an ink-jet method, for example, may be used for film formation of the electron transport layer 16.

The QD layer 15 is a light-emitting layer (QD light-emitting layer) provided between the anode 12 and the cathode 17 and including the QDs.

The QDs emit the LB as illustrated in FIG. 2 in association with recombination of the positive holes supplied from the anode 12 and the electrons (free electrons) supplied from the cathode 17. That is, the QD layer 15 emits light through electroluminescence (EL). More specifically, the QD layer 15 emits light through injection type EL.

FIG. 1 is a schematic view illustrating an example of a QD 25 according to the present embodiment.

The QD 25 according to the present embodiment is a QD phosphor particle (also referred to as a semiconductor nanoparticle phosphor). The QD 25 emits fluorescence as LB in association with the recombination of positive holes and electrons.

As illustrated in FIG. 1, the QD 25 according to the present embodiment includes a core 25a and a shell 25b provided on a surface of the core 25a. Preferably, the QD 25 has a core-shell structure (core/shell structure) including the core 25a and the shell 25b covering at least a portion of the surface of the core 25a. Note that it is particularly desirable that the shell 25b covers the core 25a in its entirety. The shell 25b can be said to have a core-shell structure when the shell 25b is found by observation to enclose the core 25a in a cross section of the QD 25. For example, when a diameter of the QD 25 and a diameter of the core 25a are calculated and a difference therebetween is 0.3 nm or greater, the shell 25b can be said to enclose the core 25a (cover the core 25a in its entirety).

The diameter of the QD 25 (average value of assumed particle diameters) can be calculated by, for example, the following method.

First, from an outer shape of each cross section of 100 QDs 25 adjacent to each other, an area (S) of the cross section of each QD 25 is determined by, for example, scanning electron microscopy (SEM) or transmission electron microscopy (TEM). Next, assuming that all 100 QDs 25 are circles, each diameter (2r, assumed particle diameter) of the circle corresponding to the area (S=πr², r indicating radius) of each cross section of the 100 QDs 25 may be calculated and then an average value thereof may be calculated.

Further, the diameter of the core 25a (average value of the assumed particle diameters) may be calculated by observing the cross sections of the core 25b using SEM or TEM in the same manner as with the diameter of the QD 25 (average value of the assumed particle diameters), as long as before formation of the shell 25a.

In this case, first, from the outer shape of each cross section of the 100 cores 25a adjacent to each other, the area (S) of the cross section of each core 25a is determined by, for example, SEM or TEM. Next, assuming that all 100 cores 25a are circles, each diameter (2r, assumed particle diameter) of the circle corresponding to the area (S=πr², r indicating radius) of each cross-section of the 100 cores 25a may be calculated and then an average value thereof may be calculated.

Further, the diameter of the core 25a (assumed core diameter) may be calculated using effective mass approximation for components of the core 25a, regardless of whether or not the shell 25b is formed.

The QD 25 is a Cd-free nanocrystal that includes the core 25a including zinc (Zn) and selenium (Se), and the shell 25b composed of zinc sulfide (ZnS) and provided on the surface of the core 25a, adjacently to the core 25a, and does not include cadmium (Cd).

For example, given (p as the assumed core diameter of the core 25a and Xp (mm) as the fluorescent peak wavelength of the QD 25 in a case in which the core 25a is ZnSe, the diameter can be calculated by the following equation using effective mass approximation for ZnSe.

ΦD=(6.1/((1240/λp)−2.7))1/2

Note that, in the disclosure, the term “nanocrystal” indicates a nanoparticle having a particle diameter from about several nm to several tens of nm.

Further, in the disclosure, “not including Cd” or “Cd free” means that the QD 25 does not include Cd at a mass ratio of 1/30 or greater in relation to Zn. Accordingly, the QD 25 “not including Cd” as described above means that the core 25a and the shell 25b both do not include Cd at a mass ratio of 1/30 or greater in relation to Zn.

Note that the shell 25b may be formed in a state of being solid-solved on the surface of the core 25a. In FIG. 1, a boundary between the core 25a and the shell 25b is indicated by a dotted line, and this indicates that the boundary between the core 25a and the shell 25b may or may not be confirmed by analysis.

Further, numerous ligands 21 are coordinated (adsorbed) on the surface of the QD 25 illustrated in FIG. 1. The ligand 21 is a surface-modifying group (ligand) that modifies the surface of the QD 25. The QD layer 15 formed by the solution method includes the QDs 25 having a substantially spherical shape and the ligands 21.

The QDs 25 are preferably nanocrystals including Zn and Se, Zn, Se, and sulfur (S), Zn, Se, and tellurium (Te), or Zn, Se, Te, and S. Specifically, ZnSe-based, ZnSeS-based, ZnSeTe-based, or ZnSeTeS-based QDs are used as the QDs 25.

Accordingly, the core 25a need only include at least Zn and Se as described above, and is formed of, for example, ZnSe, ZnSeS, ZnSeTe, or ZnSeTeS. Among these exemplary materials, the material of the core 25a is preferably ZnSe or ZnSeS, and more preferably ZnSe.

The shell 25b, as described above, is made of ZnS and is provided on the surface of the core 25a, adjacently to the core 25a. Therefore, the shell 25b does not include Cd as well as Se and Te. Accordingly, the QD 25 according to the present embodiment does not include a layer including Se or Te (for example, a layer made of ZnSeS) between the core 25a including Zn and Se and the shell 25b made of ZnS as described above.

Note that, as described above, in the disclosure, “not including Cd” means that the QD 25 does not include Cd at a mass ratio of 1/30 or greater in relation to Zn. On the other hand, in the disclosure, “not including Se or Te” means that the QD 25 does not include Se or Te at a mass ratio of 1/30 or greater in relation to S.

According to the present embodiment, a fluorescence quantum efficiency (QY) can be further increased by thus covering the core 25a formed of a nanocrystal such as ZnSe, ZnSeS, ZnSeTe, or ZnSeTeS with a shell 25b formed of ZnS.

The fluorescence quantum efficiency of the QDs 25 according to the present embodiment is 5% or greater. The above-described fluorescence quantum efficiency is preferably 20% or greater, more preferably 50% or greater, and even more preferably 80% or greater. In this manner, the fluorescence quantum efficiency of the QDs 25 can be increased in the present embodiment. This makes it possible to increase the fluorescence quantum efficiency of the QDs 25 in a thin film state (in other words, the fluorescence quantum efficiency of the QD layer 15).

Note that the Zn and Se, the Zn, Se, and S, the Zn, Se, and Te, or the Zn, Se, Te, and S included in QDs 25 are the main components. The QDs 25 may include elements besides these elements.

For example, the QDs 25 may further include copper (Cu) as an element in at least, of the core 25b and the shell 25a, the core 25a. As a compound, for example, Cu₂Se may be included in at least, of the core 25b and the shell 25a, the core 25a.

When the QDs 25 include Cu, regardless of whether Cu is included only in the core 25a or in both the core 25a and the shell 25b, the content of Cu with respect to Zn in the QDs 25 is desirably from 0.1 ppm to 10 ppm. Note that the contents of Zn and Cu in the QDs 25 and the content of Cu relative to Zn can be determined by, for example, inductively coupled plasma (ICP) emission spectrometry.

Synthesizing the QDs 25 by a cation exchange method as described below enables control of the particle diameter with the copper chalcogenide precursor, and also enables the synthesis of the QDs 25 that are naturally difficult to react. ZnSe-based QDs 25 synthesized by a cation exchange method tend to have a higher residual amount of Cu than ZnSe-based QDs 25 synthesized by a direct method. However, as long as the amount of Cu relative to Zn is within the range described above, favorable light-emission characteristics can be obtained. The residual amount of Cu is used to determine whether the cation exchange method was used and is thus advantageous. Note that the core-shell structure can be synthesized at the stage of the copper chalcogenide precursor.

However, the QDs 25 preferably do not include Cd and do not include phosphorus (P). Organic phosphorus compounds are expensive. Furthermore, organic phosphorus compounds are easily oxidized in air, and therefore a variety of problems are likely to occur such as unstable synthesis, an increase in costs, unstable fluorescence characteristics, and an increase in the complexity of the manufacturing process.

The QDs 25 have fluorescence characteristics due to band-end light emission, and a quantum size effect occurs due to the particles being of a nano size.

A peak wavelength of the QDs 25 depends on subtle differences among the compositional ratios of the constituent elements of the QDs 25, and the relationship between the particle diameter and the magnitude of wavelength dependence varies depending on the particle diameter region. However, the particle diameter of the QDs 25 is preferably within a range from 3 nm to 20 nm. Further, the particle diameter of the QDs 25 is more preferably within a range from 5 nm to 20 nm. Moreover, the particle diameter of the QDs 25 is more preferably 15 nm or less, and even more preferably 10 nm or less. In the present embodiment, the particle diameter of the QDs 25 can be adjusted within the range described above, and a large number of the QDs 25 can be produced with a substantially uniform particle diameter.

Note that the particle diameter of the QDs 25 is indicated by, for example, an average value of the assumed particle diameters of the QDs 25 covered with the shell 25b (outermost particle diameter of the QDs 25).

In the present embodiment, as described above, the particle diameter of the QDs 25 can be reduced, and variations in the particle diameters of the QDs 25 can be reduced, making it possible to obtain QDs 25 having a uniform size.

Accordingly, in the present embodiment, the fluorescence full-width at half-maximum of the QDs 25 can be narrowed to 25 nm or less, and the formation of a high-color gamut can be improved. Note that, in the disclosure, the “fluorescence full-width at half-maximum” is a full width at half maximum (FWHM), which indicates the spread of fluorescence wavelengths at half the intensity of a peak value of a fluorescence intensity in a fluorescent spectrum.

Additionally, the fluorescence full-width at half-maximum is preferably 23 nm or smaller, more preferably 20 nm or smaller, and even more preferably 15 nm or smaller. In the present embodiment, the fluorescence full-width at half-maximum can be narrowed in this manner, and thus the formation of a high color gamut can be improved.

In particular, the QDs 25 according to the present embodiment are synthesized by synthesizing a copper chalcogenide as a precursor from a copper (Cu) raw material and an organic chalcogen compound (organic chalcogenide) as an Se raw material or a Te raw material, and then subjecting the result to a metal exchange of Cu of the copper chalcogenide with Zn. Note that an organic copper compound or an inorganic copper compound is used for the Cu raw material.

According to the present embodiment, synthesis can be safely implemented by synthesizing the QDs 25 on the basis of an indirect synthesis reaction using such types of materials having relatively high stability (materials with relatively low reactivity) and, as described above, the QDs 25 having a uniform size can be obtained. As a result, the fluorescence full-width at half-maximum can be narrowed, and a fluorescence full-width at half-maximum of 25 nm or less can be achieved as described above.

In addition, according to the present embodiment, a fluorescence lifetime (τ) of the QDs 25 in a thin film state can be set to 50 ns or less. Note that, in the disclosure, “fluorescence lifetime” indicates the “time until the initial intensity becomes 1/e (approximately 37%).”

According to the present embodiment, the fluorescence lifetime (τ) of the QDs 25 in a thin film state can be adjusted to 40 ns or less, and even 30 ns or less. The fluorescence lifetime of the QDs 25 in a thin film state can be shortened in this manner, but can also be extended to about 50 ns, and thus the fluorescence lifetime can be adjusted according to the usage application.

In general, the fluorescence lifetime of a QD indicates a fluorescence lifetime in a state of a solution (dispersion) obtained by dissolving (dispersing) the QD in a solvent. Note that, here, the “solution” means a colloidal solution. In the present embodiment, not only the fluorescence lifetime of the QDs 25 in a solution (dispersion) state can be set to 50 ns or less, but also the fluorescence lifetime of the QDs 25 in a thin film state can be set to 50 ns or less. Further, the fluorescence lifetime of the QDs 25 in a solution (dispersion) state can be adjusted to 40 ns or less, and even 30 ns or less, similarly to the fluorescence lifetime of the QDs 25 in a thin film state.

The fluorescence lifetime of the QDs 25 in a thin film state may be, for example, the fluorescence lifetime of the QDs 25 in a thin film state formed on glass as a QD layer, or the fluorescence lifetime of the QDs 25 in a state incorporated as a QD layer into a light-emitting device or a light-emitting device including the light-emitting device.

As described above, the QDs 25 according to the present embodiment maintain the characteristics of the solution state even in the thin film state. The QDs 25 according to the present embodiment have a fluorescence lifetime in a thin film state of 50 ns or less as described above, and have a high fluorescence quantum efficiency even after formation into a thin film (that is, after formation of the QD layer). Further, the fluorescence quantum efficiency can be improved by heating.

On the other hand, in a QD layer in the related art, the fluorescence quantum efficiency decreases when the layer is maintained at high temperature. Note that, even if the fluorescence quantum efficiency does not decrease, it is only maintained at best.

Therefore, in a light-emitting device including a known QD layer including QDs, there is a possibility that the QD layer or the like deteriorates due to environmental changes, the passage of time, or the like, irreversibly reducing the fluorescence quantum efficiency of the QD layer, for example. As a result, there is a possibility that the light-emitting device using this QD layer as a light-emitting layer may irreversibly reduce in luminance with this deterioration of the QD layer or the like.

However, with the QDs 25 according to the present embodiment, the fluorescence quantum efficiency can be increased by heating (heating and maintaining) the QD layer after formation of the QD layer. Even if the QD layer and the like deteriorate due to environmental changes, the passage of time, or the like and the fluorescence quantum efficiency and the fluorescence lifetime of the QD layer decrease, for example, the fluorescence quantum efficiency of the QD layer can be improved by heating the QD layer.

Therefore, in the light-emitting device 1 including the QD layer 15 including the QDs 25 as the light-emitting layer formed of the QD layer, even if the QD layer 15 or the like deteriorates due to environmental changes, the passage of time, or the like and the light-emitting device 1 temporarily decreases in luminance, the reduced luminance can be improved and returned to the original state or close to the original state by heating the QD layer 15. According to the present embodiment, even if the luminance of the light-emitting device 1 is reduced due to deterioration of components other than the QD layer 15, the luminance of the light-emitting device 1 can be improved by the advantageous effects described above.

Note that the QD layer 15 is desirably heated at a temperature from 80° C. to 100° C. for 30 minutes to 600 minutes. By heating the QD layer 15 at a temperature from 80° C. to 100° C. for 30 minutes to 600 minutes, the fluorescence quantum efficiency of the QD layer 15 can be increased beyond the value before heating.

If the heating temperature of the QD layer 15 is too low or the heating time period is too short, a sufficient effect by heating may not be obtained and the fluorescence quantum efficiency of the QD layer 15 may not be sufficiently increased (improved). On the other hand, if the heating temperature of the QD layer 15 is too high or the heating time period is too long, there is a possibility that the QDs 25 themselves thermally deteriorate by the heating to a greater extent than the improvement of the fluorescence quantum efficiency by the heating. For this reason, the QD layer 15 is desirably heated within the range of the above-described conditions.

According to the present embodiment, after formation of the QD layer 15, the QD layer 15 is heated under the conditions described above, for example, making it possible to manufacture the light-emitting device 1 having a higher fluorescence quantum efficiency. In this manner, the light-emitting device 1 having a higher luminance according to the present embodiment can be manufactured. Note that, to increase the fluorescence quantum efficiency of the light-emitting device 1 as a product (that is, the fluorescence quantum efficiency of the light-emitting device 1 before shipment), the QD layer 15 need only be heated, for example, under the conditions described above after formation of the QD layer 15 and before shipment as a product.

In this case, for example, the light-emitting device 1 having a high fluorescence quantum efficiency can be manufactured by heating the QD layer 15 after formation of the QD layer 15 and before completion of the light-emitting device 1.

Further, to improve the fluorescence quantum efficiency reduced by deterioration of the QD layer 15 or the like caused by environmental changes, the passage of time, or the like, the deteriorated QD layer 15 need only be heated under the conditions described above, for example.

Moreover, for the purpose of preventing or suppressing a reduction in fluorescence quantum efficiency due to deterioration of the QD layer 15 or the like, the QD layer 15 may be periodically heated under the conditions described above, for example.

Note that the heating method of the QD layer 15 is not particularly limited. When the QD layer 15 is heated immediately after formation of the QD layer 15, the QD layer 15 may be heated using an external heating device. However, to improve the fluorescence quantum efficiency reduced by deterioration of the QD layer 15 or the like caused by environmental changes, the passage of time, or the like, desirably the light-emitting device 1 includes at least one heat source for heating the QD layer 15, as illustrated in an embodiment described below.

Further, according to the present embodiment, the fluorescence lifetime (τ) of the QDs 25 in a thin film state increases by heating. Specifically, in the QDs 25, the fluorescence lifetime (τ) in a thin film state is relatively increased by 10% or more (in other words, at least 10%) of the original value (that is, the value before heating) after being maintained at 80° C. for 60 minutes.

Thus, the fluorescence quantum efficiency of the QD layer 15 is improved by heating the QD layer 15. Note that, according to the present embodiment, the fluorescence lifetime (τ) of the QDs 25 in a thin film state can be increased by, for example, 20% or more of the original value (that is, the value before heating) by heating and, with the increase in the fluorescence lifetime by heating, the fluorescence quantum efficiency also increases. As a result, according to the present embodiment, the fluorescence quantum efficiency of the QDs 25 in a thin film state (in other words, the fluorescence quantum efficiency of the QD layer 15) can also be increased by, for example, 10% or more, preferably 20% or more, more preferably 50% or more, and even more preferably 100% or more of the original value (that is, the value before heating) by heating. Note that, in the present embodiment, the fluorescence lifetime indicates a value measured at room temperature.

The reason that the fluorescence quantum efficiency increases (improves) by heating is not clear, but presumably the core 25a including Zn and Se and the shell 25b composed of ZnS are adjacent to each other, and another layer (for example, ZnSeS layer) is not present between the core 25a and the shell 25b. As a result, the ligand 21 released when the QDs 25 change from a solution state to a thin film state is readily re-coordinated to the QDs 25 by heating as compared with a case in which such a layer is present.

The ligand 21 that can be used in the present embodiment is not particularly limited, and examples include amine-based (aliphatic primary amine-based), fatty acid-based, thiol-based (sulfur-based), phosphine-based (phosphorus-based), and phosphine oxide-based ligands.

Examples of the aliphatic primary amine-based ligands 21 include oleylamine (C₁₈H₃₅NH₂), stearyl (octadecyl) amine (C₁₈H₃₇NH₂), dodecyl (lauryl) amine (C₁₂H₂₅NH₂), decylamine (C₁₀H₂₁NH₂), and octylamine (C₈H₁₇NH₂).

Examples of the fatty acid-based ligands 21 include oleic acid (C₁₇H₃₃COOH), stearic acid (C₁₇H₃₅COOH), palmitic acid (C₁₅H₃₁COOH), myristic acid (C₁₃H₂₇COOH), lauric (dodecanoic) acid (C₁₁H₂₃COOH), decanoic acid (C₉H₁₉COOH), and octanoic acid (C₇H₁₅COOH).

Examples of the thiol-based ligands 21 include octadecanethiol (C₁₈H₃₇SH), hexanedecanethiol (C₁₆H₃₃SH), tetradecanethiol (C₁₄H₂₉SH), dodecanethiol (C₁₂H₂₅SH), decanethiol (C₁₀H₂₁SH), and octanethiol (C₈H₁₇SH).

Examples of the phosphine-based ligands 21 include trioctylphosphine ((C₈H₁₇)₃P), triphenylphosphine ((C₆H₅)₃P), and tributyl phosphine ((C₄H₉)₃P).

Examples of the phosphine oxide-based ligands 21 include trioctylphosphine oxide ((C₈H₁₇)₃P═O), triphenylphosphine oxide ((C₆H₅)₃P═O), and tributyl phosphine oxide f ((C₄H₉)₃P═O).

By coordinating the ligands 21 on the surfaces of the QDs 25, mutual aggregation of the QDs 25 can be suppressed and the exhibition of target optical characteristics can be facilitated. Furthermore, the addition of the amine-based or thiol-based ligands 21 can greatly improve the stability of the light-emission characteristics of the QDs 25.

Further, according to the present embodiment, as described above, by setting the particle diameter (for example, the average value of the assumed particle diameters) of the QDs 25 to within the range from 3 nm to 20 nm, the QDs 25 that emit blue light having a fluorescent peak wavelength (λp) from 410 nm to 470 nm can be provided.

Note that, in the present embodiment, the fluorescent peak wavelength can be freely controlled to an approximate range from 410 nm to 470 nm. The fluorescent peak wavelength of the QDs 25 is within a range from 410 nm to 470 nm. According to the present embodiment, the fluorescent peak wavelength can be controlled by adjusting the particle diameter and composition of the QDs 25. The QDs 25 are, for example, ZnSe-based or ZnSeS-based solid solution bodies in which a chalcogen element is used in addition to Zn. In this case, the fluorescent peak wavelength can be preferably set within a range from 430 nm to 470 nm, and more preferably within a range from 450 nm to 470 nm. Furthermore, in the ZnSeTe-based or ZnSeTeS-based QDs 25, the fluorescent peak wavelength can be set within a range from 450 nm to 470 nm. In this manner, the fluorescent peak wavelength of the QDs 25 can be controlled to blue in the present embodiment.

Further, according to the present embodiment, the fluorescence lifetime can be further shortened by adopting a core-shell structure for the QDs 25 in comparison to the core 25a alone having the same composition and particle diameter.

Furthermore, the fluorescent peak wavelength can be shortened or lengthened by covering the core 25a with the shell 25b to a greater extent than the case of the core 25a alone. For example, when the particle diameter of the core 25a is small, the fluorescent peak wavelength tends to be lengthened by covering the core 25a with the shell 25b. On the other hand, when the particle diameter of the core 25a is large, the fluorescent peak wavelength tends to be shortened by covering the core 25a with the shell 25b. Note that the magnitude of change in the wavelength varies depending on the conditions of covering with the shell 25b.

A thickness (shell thickness) of the shell 25b is one factor determining the efficiency and reliability of the light-emitting device 1. In order to obtain better light emission performance, it is desirable that the QDs 25 have a core-shell structure as described above.

However, when the shell thickness is too thick, the fluorescence quantum efficiency decreases. Therefore, the shell thickness is desirably 3.2 nm or less (that is, greater than 0 and not more than 3.2 nm). By setting the shell thickness to 3.2 nm or less, a fluorescent peak wavelength of 50 ns or less can be obtained and a high fluorescence quantum efficiency can thus be attained.

Further, when the core 25a is made of ZnSe, for example, by setting the shell thickness to 3.2 nm or less, the fluorescence quantum efficiency of the QDs 25 in a thin film state (in other words, the fluorescence quantum efficiency of the QD layer 15) can be improved by heating as described above.

Specifically, when the core 25a is made of ZnSe as described above, given Xp (nm) as the fluorescent peak wavelength of the QDs 25 and d (nm) as the particle diameter of the QDs 25 (for example, the average value of the assumed particle diameters described above), desirably d−(6.1/((1240/λp)−2.7))^{1/2}≤3.2.

Note that, as described above, the particle diameter (for example, average value of the assumed particle diameters) of the QDs 25 including the shell 25b is from 3 nm to 20 nm, and is more preferably from 5 nm to 20 nm. Accordingly, in the above formula, the particle diameter d is 3≤d≤20. Further, (6.1/((1240/λp)−2.7))^{1/2} represents the assumed core diameter φ calculated using effective mass approximation for ZnSe. That is, in the QDs 25 according to the present embodiment, when the core 25a is made of ZnSe, desirably 3≤d≤20 and d−φ≤3.2. Thus, when the core 25a is ZnSe, the fluorescence quantum efficiency of the QD layer 15 can be improved by heating.

Note that, when the core 25a is made of ZnSe, the QDs 25 satisfying the formula described above means that an extra layer such as ZnSeS is not included between the core 25a and the shell 25b made of ZnS. The reason that the QDs 25 increase (improve) in fluorescence quantum efficiency by heating is not clear, but presumably an extra layer such as a ZnSeS layer is not included between the core 25a made of ZnSe and the shell 25b made of ZnS, and thus the ligand 21 released when the QDs 25 change from a solution state to a thin film state is readily re-coordinated to the QDs 25 by heating as compared with a case in which such a layer is present.

Note that the lower limit value of the shell thickness is not particularly limited, but is desirably 0.5 nm or greater, and more desirably 1.0 nm or greater. When the shell thickness is less than 0.5 nm, defects present in the core 25a are insufficiently protected, and the fluorescence quantum efficiency may decrease. Further, when the light-emitting device 1 using such QDs 25 is manufactured, the luminous efficiency of the light-emitting device 1 may decrease. Accordingly, when the core 25a is made of ZnSe as described above, more desirably the QDs 25 satisfy 3≤d≤20 and 0.5≤d−φ≤3.2.

The QD layer 15 is formed by applying a solution (dispersion or liquid composition) including the QDs 25 described above to evaporate the solvents and form a thin film.

The QD layer 15 is preferably formed so that a layer thickness thereof is from 10 nm to 60 nm, and more preferably formed so that the layer thickness is from 15 nm to 35 nm. This allows an even higher EQE to be obtained.

Note that a technique such as spin coating, an ink-jet method, or photolithography is preferably used for film formation of the QD layer 15.

In the light-emitting device 1, a forward voltage is applied between the anode 12 and the cathode 17. In other words, the anode 12 is set to a higher potential than the cathode 17. Through this, (i) electrons can be supplied from the cathode 17 to the QD layer 15, and (ii) positive holes can be supplied from the anode 12 to the QD layer 15. As a result, the QD layer 15 can generate the LB in association with the recombination of the positive holes and the electrons. The above-described application of voltage may be controlled by a thin film transistor (TFT) (not illustrated). As an example, a TFT layer including a plurality of TFTs may be formed in the substrate 11.

Note that the light-emitting device 1 may include, as a function layer, a hole blocking layer (HBL) that suppresses the transport of positive holes. The hole blocking layer is provided between the anode 12 and the QD layer 15. By providing the hole blocking layer, the balance of the carriers (that is, positive holes and electrons) supplied to the QD layer 15 can be adjusted.

In addition, the light-emitting device 1 may include, as a function layer, an electron blocking layer (EBL) that suppresses the transport of electrons. The electron blocking layer is provided between the QD layer 15 and the cathode 17. By providing the electron blocking layer, the balance of the carriers (that is, positive holes and electrons) supplied to the QD layer 15 can be adjusted.

The light-emitting device 1 may be sealed after film formation as far as the cathode 17 has been completed. For example, a glass or a plastic can be used as a sealing member. The sealing member has, for example, a concave shape so that a layered body from the substrate 11 to the cathode 17 can be sealed. For example, after a sealing adhesive (for example, an epoxy-based adhesive) is applied between the sealing member and the substrate 11, sealing is implemented in a nitrogen (N₂) atmosphere, and thereby the light-emitting device 1 is manufactured.

### Application in Display Device

As described above, the light-emitting device 1 is adopted, for example, as a blue light source of a display device. The light source including the light-emitting device 1 may include a light-emitting device as a red light source and a light-emitting device as a green light source. In this case, the light source functions as, for example, a light source for lighting the R pixel, the G pixel, and the B pixel, as indicated in an embodiment described below. The display device including this light source can express an image by a plurality of pixels including the R pixel, the G pixel, and the B pixel.

For example, the R pixel, the G pixel, and the B pixel are each formed by separately patterning each layer of the light-emitting device 1, including at least the QD layer 15, on the substrate 11 provided with a bank. For example, indium phosphide (InP) can be suitably used as the red QDs and the green QDs used for the R pixel and G pixel respectively, as long as the materials are limited to non-Cd-based materials. When InP is used, the fluorescence full-width at half-maximum can be made relatively narrow, and high luminous efficiency can be obtained.

Film formation of the electron transport layer 16 may be implemented with a plurality of pixel units or may be implemented in common for the plurality of pixels, provided that the display device can light up the R pixel, G pixel, and B pixel individually.

### Method for Manufacturing Light-Emitting Device

Next, an example of a method for manufacturing the light-emitting device 1 will be described. The light-emitting device 1 is manufactured by, for example, performing film formation of the anode 12, the hole injection layer 13, the hole transport layer 14, the QD layer 15, the electron transport layer 16, and the cathode 17 on or above the substrate 11 in this order.

Specifically, for example, the anode 12 is formed on the substrate 11 by sputtering (anode formation process). Next, after a solution including, for example, PEDOT.PSS has been applied to the anode 12 by spin coating, the solvent is volatilized by baking to form the hole injection layer 13 (hole injection layer formation process). Next, after a solution including, for example, TFB is applied to the hole injection layer 13 by spin coating, the solvent is volatilized by baking to form the hole transport layer 14 (hole transport layer formation process). Next, the QD layer 15 is formed on the hole transport layer 14 using a solution method. Specifically, after a dispersion (liquid composition) in which the QDs 25 are dispersed has been applied to the hole transport layer 14 by spin coating, the solvent is volatilized by baking to form the QD layer 15 (light-emitting layer formation process). Next, after a solution including, for example, nanoparticles of ZnO has been applied to the QD layer 15 by spin coating, a solvent is volatilized by baking to form the electron transport layer 16 (electron transport layer formation process).

Next, the cathode 17 is formed on the electron transport layer 16 by vacuum vapor deposition (cathode formation process). Note that the manufacturing process of the light-emitting device 1 according to the present embodiment desirably includes a light-emitting layer heating process of heating the light-emitting layer after the light-emitting layer formation process. The light-emitting layer heating process may be performed, for example, immediately after the light-emitting layer formation process or after the cathode formation process. As described above, heating at this time is desirably performed at a temperature from 80° C. to 100° C. for 30 minutes to 600 minutes.

Note that the QDs 25 included in the QD layer 15 are synthesized by synthesizing a copper chalcogenide as a precursor from an organic copper compound or an inorganic copper compound and an organic chalcogen compound and then using the copper chalcogenide (quantum dot synthesis process). That is, in the light-emitting layer formation process, the QD layer 15 including the QDs 25 synthesized in this manner is formed. The quantum dot synthesis process (also referred to as a QD synthesis process) will be described below.

Note that, as described above, in the light-emitting layer formation process, the QD layer 15 is formed so that a layer thickness thereof is from 10 nm to 60 nm, preferably from 15 nm to 35 nm.

Further, as described above, in the hole transport layer formation process, the hole transport layer 14 is formed so that the layer thickness of the hole transport layer 14 is from 5 nm to 50 nm.

Note that, after film formation of the cathode 17, the substrate 11 and the layered body (the anode 12 to the cathode 17) formed on the substrate 11 may be sealed with a sealing member in an N₂ atmosphere.

### Method for Synthesizing QDs 25

Next, an example of a method for synthesizing the QDs 25 (QD synthesis process) will be described.

In the present embodiment, first, a copper chalcogenide is synthesized as the precursor from a Cu raw material (an organic copper compound or an inorganic copper compound) and an organic chalcogen compound as an Se raw material or Te raw material. Preferable examples of the copper chalcogenide (precursor) include Cu₂Se, Cu₂SeS, Cu₂SeTe, and Cu₂SeTeS.

The organic copper compound (organic copper reagent) used as the Cu raw material is not particularly limited, and examples thereof include acetates and fatty acid salts. Furthermore, the inorganic copper compound (inorganic copper reagent) used as the Cu raw material is also not particularly limited, and examples thereof include halides (copper halides).

More specifically, examples of the acetates include copper (I) acetate (Cu(OAc)) and copper (II) acetate (Cu(OAc)₂).

Examples of the fatty acid salts include copper stearate (Cu(OC(═O)C₁₇H₃₅)₂), copper oleate (Cu(OC(═O)C₁₇H₃₃)₂), copper myristate (Cu(OC(═O)C₁₃H₂₇)₂), copper dodecanoate (Cu(OC(═O)C₁₁H₂₃)₂), and copper acetylacetonate (Cu(acac)₂).

Both monovalent and divalent compounds can be used as the halide. Examples of the halide include copper(I) chloride (CuCl), copper(II) chloride (CuCl₂), copper(I) bromide (CuBr), copper(II) bromide (CuBr₂), copper(I) iodide (CuI), and copper(II) iodide (CuI₂).

In the present embodiment, an organic selenium compound (organic chalcogen compound) is used as a raw material of Se. The organic selenium compound (organic chalcogen compound) is not particularly limited, and for example, trioctylphosphine selenide ((C₈H₁₇)₃P═Se) obtained by dissolving Se in trioctylphosphine, and tributylphosphine selenide ((C₄H₉)₃P═Se) obtained by dissolving Se in tributylphosphine can be used. Also, other examples of the organic selenium compound (organic chalcogen compound) that can be used include a solution (Se-ODE) in which Se is dissolved at a high temperature in a high boiling point solvent, which is a long chain hydrocarbon such as octadecene, and a solution (Se-DDT/OLAm) in which Se is dissolved in a mixture of oleylamine and dodecanethiol.

In the present embodiment, an organic tellurium compound (organic chalcogen compound) is used as the Te raw material. The organic tellurium compound (organic chalcogen compound) is not particularly limited, and for example, trioctylphosphine telluride ((C₈H₁₇)₃P═Te) obtained by dissolving Te in trioctylphosphine, and tributylphosphine telluride ((C₄H₉)₃P═Te) obtained by dissolving Te in tributylphosphine can be used. Also, as the organic tellurium compound (organic chalcogen compound), a dialkyl ditelluride (R₂Te₂; where R denotes a C₁-C₆ alkyl group), such as diphenyl ditelluride ((C₆H₅)₂Te₂) can be used.

In the synthesis of the copper chalcogenide, first, an organic copper compound or an inorganic copper compound, and an organic chalcogen compound are mixed and dissolved in a solvent.

Examples of the solvent include saturated or unsaturated hydrocarbons having a high boiling point. Examples of high boiling point saturated hydrocarbons that can be used include n-dodecane, n-hexadecane, and n-octadecane. An example of a high boiling point unsaturated hydrocarbon that can be used is octadecene. Note that, for example, an aromatic solvent having a high boiling point, and an ester-based solvent having a high boiling point may also be used as the solvent. For example, t-butyl benzene can be used as an aromatic solvent having a high boiling point. Examples of high boiling point ester-based solvents that can be used include butyl butyrate (C₄H₉COOC₄H₉) and benzyl butyrate (C₆H₅CH₂COOC₄H₉). However, aliphatic amine-based compounds, fatty acid-based compounds, aliphatic phosphorus-based compounds, or mixtures thereof can also be used as the solvent.

Next, the reaction temperature is set to within a range from 140° C. to 250° C., and the copper chalcogenide (precursor) is synthesized. Note that the reaction temperature is preferably a lower temperature within a range from 140° C. to 220° C., and more preferably an even lower temperature within a range from 140° C. to 200° C. In this manner, according to this embodiment, the copper chalcogenide can be synthesized at a low temperature, and therefore the copper chalcogenide can be safely synthesized. In addition, since the reaction during synthesis is gentle, the reaction is easier to control.

Note that, in the present embodiment, the reaction method is not particularly limited, but it is important to synthesize Cu₂Se, Cu₂SeS, Cu₂SeTe, and Cu₂SeTeS having uniform particle diameters in order to obtain the QDs 25 having a narrow fluorescence full-width at half-maximum.

Also, the particle diameter of the copper chalcogenide (precursor) such as Cu₂Se, Cu₂SeS, Cu₂SeTe, and Cu₂SeTeS is preferably 20 nm or less, more preferably 15 nm or less, and even more preferably 10 nm or less. Wavelength control of the QDs 25 such as ZnSe-based, ZnSeS-based, ZnSeTe-based, and ZnSeTeS-based QD phosphor particles is enabled depending on the composition and particle diameter of this copper chalcogenide. Therefore, it is important to appropriately control the particle diameter.

It is also important to solid-solve S in the core in order to obtain the QDs 25 with a narrower fluorescence full-width at half-maximum. For this reason, thiol is preferably added in the synthesis of, for example, Cu₂Se or Cu₂SeTe as the precursor. Also, the above-described Se-DDT/OLAm is more preferably used as the Se raw material in order to obtain the QDs 25 having a narrower fluorescence full-width at half-maximum.

While the thiol is not particularly limited, examples of thiols that can be used include octadecanethiol (C₁₈H₃₇SH), hexanedecanethiol (C₁₆H₃₃SH), tetradecanethiol (C₁₄H₂₉SH), dodecanethiol (C₁₂H₂₅SH), decanethiol (C₁₀H₂₁SH), and octanethiol (C₈H₁₇SH).

Next, an organic zinc compound or an inorganic zinc compound is prepared as a Zn raw material of ZnSe, ZnSeS, ZnSeTe, or ZnSeTeS. The organic zinc compound or the inorganic zinc compound is a raw material that is stable even in air and easy to handle. The organic zinc compound or the inorganic zinc compound is not particularly limited, but a zinc compound with high ionic properties is preferably used in order to efficiently carry out a metal exchange reaction. Examples of the organic zinc compound include acetates, nitrates, and fatty acid salts. Examples of the inorganic zinc compound include halides (zinc halides).

An example of the acetate that can be used is zinc acetate (Zn(OAc)₂). An example of the nitrate that can be used is zinc nitrate (Zn(NO₃)₂).

More specifically, examples of fatty acid salts that can be used include zinc stearate (Zn(OC(═O)C₁₇H₃₅)₂), zinc oleate (Zn(OC(═O)C₁₇H₃₃)₂), zinc palmitate (Zn(OC(═O)C₁₅H₃₁)2), zinc myristate (Zn(OC(═O)C₁₃H₂₇)₂), zinc dodecanoate (Zn(OC(═O)C₁₁H₂₃)₂), and zinc acetylacetonate (Zn(acac)₂).

Note that the organic zinc compound may be a zinc carbamate. Examples of zinc carbamates that can be used include zinc diethyldithiocarbamate (Zn(SC(═S)N(C₂H₅)₂)₂), zinc dimethyldithiocarbamate (Zn(SC(═S)N(CH₃)₂)₂), and zinc dibutyldithiocarbamate (Zn(SC(═S)N(C₄H₉)₂)₂).

Examples of halides that can be used include zinc chloride (ZnCl₂), zinc bromide (ZnBr₂), and zinc iodide (ZnI₂).

Subsequently, the above-described organic zinc compound or inorganic zinc compound is added to the reaction solution in which the copper chalcogenide (precursor) was synthesized. This results in a metal exchange reaction between Cu of the copper chalcogenide and Zn. The metal exchange reaction is preferably carried out at a temperature from 150° C. to 300° C. Further, the metal exchange reaction is more preferably carried out at a lower temperature in a range from 150° C. to 280°, and is even more preferably carried out at a temperature in a range from 150° C. to 250° C. In this manner, in the present embodiment, the metal exchange reaction can be carried out at a lower temperature, and therefore the safety of the metal exchange reaction can be increased. Furthermore, the metal exchange reaction is more easily controlled.

In the present embodiment, preferably, the metal exchange reaction between Cu and Zn proceeds quantitatively, and the nanocrystals do not include the Cu of the precursor. This is because when the Cu of the copper chalcogenide remains in the nanocrystals, the Cu serves as a dopant, light is emitted by another light emission mechanism, and the fluorescence full-width at half-maximum could be widened as a result. The residual amount of this Cu is preferably 100 ppm or less, more preferably 50 ppm or less, and ideally 10 ppm or less, in relation to the Zn.

ZnSe-based QDs 25 synthesized by a cation exchange method tend to have a higher residual amount of Cu than ZnSe-based QDs 25 synthesized by a direct method. Basically; however, Cu can be completely substituted to reduce the concentration of Cu to substantially zero. The lower the concentration of Cu, the more the characteristics of the QDs 25 can be improved. However, as long as Cu is used as a raw material, there is a possibility that Cu remains, depending on conditions.

According to the present embodiment, even though Cu is included within a range from about 0.1 to about 10 ppm in relation to Zn, for example, favorable light-emission characteristics can be obtained. Note that, as described above, the residual amount of Cu enables the determination as to whether the QDs 25 were synthesized by the cation exchange method. That is, synthesis by the cation exchange method enables control of the particle diameter with the copper chalcogenide, and also enables the synthesis of the QDs 25 that are naturally difficult to react. Therefore, the residual amount of Cu can be used to determine whether the cation exchange method was used.

Further, in the present embodiment, a compound having an auxiliary role of releasing the metal of the copper chalcogenide into the reaction solution by coordination, chelating, or the like is required when metal exchange is carried out.

An example of the compound having the above-described role is a ligand (surface modifier) capable of forming a complex with Cu. As this ligand, a ligand similar to the ligands given as examples above can be used. Preferable examples of the ligand include the above-described phosphine-based (phosphorus-based) ligands, amine-based ligands, and thiol-based (sulfur-based) ligands. Among these, in consideration of the magnitude of the reaction efficiency, a phosphine-based (phosphorus-based) ligand is more preferable. Through the use of such ligands, the metal exchange between Cu and Zn is appropriately implemented, and QDs 25 having a narrow fluorescence full-width at half-maximum and based on Zn and Se can be manufactured. In the present embodiment, the QDs 25 can be more easily mass-produced by the above-described cation exchange method than the direct synthesis method.

That is, in the direct synthesis method, for example, an organic zinc compound such as diethylzine (Et₂Zn) is used to increase the reactivity of Zn raw material. However, diethylzinc is highly reactive and ignites in air, and therefore raw material handling and storage are difficult. For example, the material needs to be handled in an inert gas stream. A reaction using diethylzinc also carries risks such as exotherm and ignition, and therefore diethylzinc is not suited for mass production. Likewise, reactions in which, for example, hydrogen selenide (H₂Se) is used to increase the reactivity of the Se raw material are also not suited for mass production from the perspectives of toxicity and safety.

In addition, in reaction systems using a Zn raw material and an Se raw material with high reactivity as described above, ZnSe is produced, but particle production is not controlled, and as a result, the fluorescence full-width at half-maximum of the produced ZnSe becomes wider.

In contrast, as described above, in the present embodiment, the copper chalcogenide is synthesized as the precursor from an organic copper compound or an inorganic copper compound and an organic chalcogen compound. Furthermore, the QDs 25 are synthesized by implementing metal exchange using the precursor. Thus, in the present embodiment, the QDs 25 are synthesized through the synthesis of the precursor, and the QDs 25 are not synthesized directly from the raw materials. According to the present embodiment, through this type of indirect synthesis, it is not necessary to use dangerous reagents that are highly reactive and difficult to handle, and ZnSe-based QDs 25 having a narrow fluorescence full-width at half-maximum can be safely and stably synthesized.

Furthermore, in the present embodiment, it is also not always necessary to isolate and purify the precursor. Thus, for example, the desired QDs 25 can be obtained by implementing metal exchange between Cu and Zn in one pot. However, the copper chalcogenide, which is the precursor, may also be isolated and purified prior to synthesis of the QDs 25, and then used.

The QDs 25 synthesized by the above-described technique can exhibit predetermined fluorescence characteristics without the implementation of various treatments such as cleaning, isolation and purification, a covering treatment, and ligand exchange.

However, as described above, the fluorescence quantum efficiency can be further increased by covering the core 25a made of a nanocrystal such as ZnSe, ZnSeS, ZnSeTe, or ZnSeTeS, with the shell 25b made of ZnS. Furthermore, adopting the core-shell structure allows the fluorescence lifetime to be shortened in comparison to prior to covering with a shell.

In addition, as described above, the fluorescent peak wavelength can be shortened or lengthened by adopting a core-shell structure in comparison to a case of the core 25a alone.

Furthermore, by adding, to the core 25a made of nanocrystals such as ZnSe, ZnSeS, ZnSeTe, or ZnSeTeS obtained by the cation exchange method, the same raw materials of ZnSe, ZnSeS, ZnSeTe, or ZnSeTeS, the core 25a of the QDs 25 changed to any particle size while maintaining a uniform particle size can be obtained. Therefore, the wavelength is easily controlled to a range from 410 nm to 470 nm while maintaining the fluorescence full-width at half-maximum at 25 nm or less.

According to the present embodiment, the core-shell structure (core/shell structure) can be formed at the stage of synthesizing the precursor. For example, as the precursor, a precursor (copper chalcogenide) having a core/shell structure of Cu₂Se/Cu₂S can be synthesized by first synthesizing Cu₂Se, and then continuously adding the S raw material. Subsequently, the QDs 25 having a core/shell structure of ZnSe/ZnS can be synthesized by carrying out metal exchange between Cu and Zn.

In the present embodiment, the S-based material used in the shell 25b is not particularly limited. Examples of the S-based material that can be typically used include thiols.

Examples of the above-mentioned thiols that can be used include octadecanethiol (C₁₈H₃₇SH), hexanedecanethiol (C₁₆H₃₃SH), tetradecanethiol (C₁₄H₂₉SH), dodecanethiol (C₁₂H₂₅SH), decanethiol (C₁₀H₂₁SH), octanethiol (C₈H₁₇SH), benzenethiol (C₆H₅SH), a solution (S-TOP) obtained by dissolving sulfur in a high boiling point solvent that is a long-chain phosphine-based hydrocarbon, such as a trioctylphosphine, a solution (S-ODE) obtained by dissolving sulfur in a high boiling point solvent that is a long-chain hydrocarbon such as octadecene, and a solution (S-DDT/OLAm) obtained by dissolving sulfur in a mixture of oleylamine and dodecanethiol.

The reactivity differs depending on the S raw material that is used, and as a result, the covering thickness of the shell 25b (for example, ZnS) can be differed. The thiol-based is proportional to the degradation rate thereof, and the reactivity of S-TOP or S-ODE varies in proportion to the stability thereof. Through this, the covering thickness of the shell 25b and the final fluorescence quantum efficiency can be controlled by also using a proper S raw material.

In the present embodiment, examples of the Zn raw material that can be used in the core-shell structure include a Zn raw material such as an organic zinc compound or an inorganic zinc compound described above.

Furthermore, with regard to the solvent used during covering with the shell 25b, as the amount of an amine-based solvent is reduced, it becomes easier to form the covering of the shell 25b, and more favorable light-emission characteristics can be obtained. In addition, the light-emission characteristics of the shell 25b after covering differ depending on the ratio of the amine-based solvent and the carboxylic acid-based solvent or phosphine-based solvent.

Moreover, the QDs 25 synthesized by the manufacturing method of the present embodiment are aggregated by adding a polar solvent such as methanol, ethanol, or acetone as a poor solvent, and the QDs 25 and the unreacted raw materials can thereby be separated and recovered. The recovered QDs 25 are again dispersed by adding, once again, a solvent such as toluene or hexane thereto. By adding a solvent that becomes the ligands 21 to the re-dispersed solution, the light-emission characteristics and stability of those light-emission characteristics can be further improved. The change in light-emission characteristics caused by the addition of the ligand 21 differs greatly depending on the presence or absence of a covering operation of the shell 25b. In particular the fluorescence stability of the QDs 25 that are covered by the shell 25b can be improved by adding thiol-based ligands 21.

### EXAMPLES

Next, the advantageous effects of the QD 25 and the light-emitting device 1 according to the present embodiment will be described through examples and comparative examples. Note that the QD 25 and the light-emitting device 1 according to the present embodiment are not limited to the following examples.

First, synthesis examples of the QDs 25 according to the present embodiment will be described.

Note that, in the following synthesis examples, as the oleylamine (OLAm), “Farmin” available from Kao Corporation was used. Also, “Lunac O-V” available from Kao Corporation was used as the oleic acid (OLAc). “Thiokalcol 20” available from Kao Corporation was used as the dodecanethiol (DDT). Furthermore, an anhydrous copper acetate available from Wako Pure Chemical Industries, Ltd. was used as the anhydrous copper acetate. An octadecene (ODE) available from Idemitsu Kosan Co., Ltd. was used as the octadecene. A trioctylphosphine (TOP) available from Hokko Chemical Industry Co., Ltd. was used as the trioctylphosphine. An anhydrous zinc acetate (Zn(OAc)₂) available from Kishida Chemical Co., Ltd. was used as the anhydrous zinc acetate.

### Synthesis Example of QDs 25

A 300 mL reaction vessel was charged with 543 mg of anhydrous copper acetate (Cu(OAc)₂) as a Cu raw material (organic copper compound), 28.5 mL of oleylamine (OLAm) as a ligand, and 46.5 mL of octadecene (ODE) as a solvent. The raw materials in the reaction vessel were then heated and dissolved at 150° C. for 20 minutes in an inert gas (N₂) atmosphere while being stirred, and a solution was thereby obtained.

Next, 8.4 mL of an Se-DDT/OLAm solution (0.285 M) was added as an organic chalcogen compound to the solution, and the resulting mixture was heated at 150° C. for 10 minutes while being stirred. The reaction solution (Cu₂Se reaction liquid, copper chalcogenide) thereby obtained was cooled to room temperature.

Subsequently, 4.092 g of anhydrous zinc acetate (Zn(OAc)₂) as an organic zinc compound, 60 mL of trioctylphosphine (TOP) as a solvent, and 2.4 mL of oleylamine (OLAm) as a ligand were added to the Cu₂Se reaction liquid, and the resulting mixture was heated at 180° C. for 30 minutes in an inert gas (N₂) atmosphere while being stirred. As a result, a metal exchange reaction occurred between Cu of the copper chalcogenide and Zn. The resulting reaction solution (ZnSe solution) was cooled to room temperature.

Next, ethanol was added to the reaction solution cooled to room temperature to generate a precipitate, and the reaction solution was centrifuged to recover the precipitate. Next, 72 mL of octadecene (ODE) was added as a solvent (dispersion medium) to the recovered precipitate, and the precipitate was dispersed, and thereby a ZnSe-ODE dispersion was obtained.

Subsequently, 4.092 g of anhydrous zinc acetate (Zn(OAc)₂) as an organic zinc compound, 30 mL of trioctylphosphine (TOP) as a solvent (dispersion medium), and 3 mL of oleylamine (OLAm) and 36 mL of oleic acid (OLAc) as ligands were added to 72 mL of this ZnSe-ODE dispersion, and the mixture was heated at 280° C. for 30 minutes in an inert gas (N₂) atmosphere while being stirred. The resulting reaction solution (ZnSe dispersion) was cooled to room temperature.

The fluorescence wavelength and the fluorescence full-width at half-maximum of ZnSe in this reaction solution (ZnSe dispersion) were measured using a fluorescence spectrometer. The F-2700 fluorescence spectrometer available from JASCO Corporation was used as the fluorescence spectrometer. The measurement results indicated optical characteristics including a fluorescent peak wavelength of approximately 430.5 nm and a fluorescence full-width at half-maximum of approximately 15 nm.

Furthermore, the fluorescence quantum efficiency of ZnSe in the reaction solution (ZnSe dispersion) was measured using a quantum efficiency measurement system. The QE-1100 quantum efficiency measurement system available from Otsuka Electronics Co. Ltd. was used as the quantum efficiency measurement system. The measurement results showed that the fluorescence quantum efficiency was approximately 30%. The fluorescence lifetime of ZnSe in the reaction solution (ZnSe dispersion) was also measured and was found to be 48 ns. Note that the C11367 fluorescence lifetime measurement device available from Hamamatsu Photonics K.K. was used to measure the fluorescence lifetime.

Further, the particle diameter (average value of assumed particle diameters) of ZnSe in the reaction solution (ZnSe dispersion) was measured using a scanning transmission electron microscope (STEM). Furthermore, X-ray diffraction (XRD) spectrum of ZnSe in the reaction solution (ZnSe dispersion) was measured using an X-ray diffraction (XRD) device. The SU9000 available from Hitachi High-Technologies Corporation was used as the scanning transmission electron microscope. Furthermore, the D2 PHASER X-ray diffraction device available from Bruker Corporation was used as the X-ray diffraction device.

As a result, the particle diameter (average value of assumed particle diameters) of the ZnSe was approximately 5 nm. Additionally, it was found that the ZnSe crystal was a cubic crystal, and the peak position thereof was consistent with the crystal peak position of ZnSe.

Next, 47 mL of the reaction solution (ZnSe dispersion) was collected, ethanol was added thereto as a poor solvent to generate a precipitate, and the mixture was centrifuged to recover (isolate) the precipitate. 35 mL of octadecene (ODE) as a solvent (dispersion medium) was added to the recovered precipitate to thereby disperse the precipitate. As a result, a ZnSe-ODE dispersion obtained by dispersing ZnSe particles (hereinafter simply referred to as “ZnSe”) in octadecene (ODE) as a core was obtained.

Subsequently, 35 mL of the ZnSe-ODE dispersion was heated at 310° C. for 20 minutes in an inert gas (N₂) atmosphere while being stirred.

Next, a mixed solution of 2.2 mL of an S-TOP solution (2.2 M) as an S raw material and 11 mL of a zinc oleate (Zn(OLAc)₂) solution (0.8 M) as an organic zinc compound was prepared, 1.1 mL of the mixed solution was added to the ZnSe-ODE dispersion, and the mixture was heated at 310° C. for 20 minutes while being stirred, and thereby, as a core, ZnSe (core size of 5.3 nm) was covered with ZnS as a shell. In the present synthesis example, this operation (covering with a shell) was repeated twelve times. As a result, a reaction solution (ZnSe/ZnS dispersion) including, as the QDs 25, ZnSe/ZnS particles (hereinafter referred to simply as “ZnSe/ZnS”) with ZnSe as the core covered with ZnS as the shell was obtained.

Subsequently, ethanol was added to the reaction solution (ZnSe/ZnS dispersion) to generate a precipitate, and the solution was centrifuged to recover the precipitate (ZnSe/ZnS particles). Next, hexane was added as a solvent (dispersion medium) to the precipitate, and the precipitate was dispersed. Thus, a ZnSe/ZnS-hexane dispersion with ZnSe/ZnS as the QDs 25 dispersed in hexane as a solvent (dispersion medium) was obtained.

The fluorescence wavelength and the fluorescence full-width at half-maximum of the ZnSe/ZnS dispersed in the hexane were measured using the fluorescence spectrometer described above. The measurement results indicated optical characteristics including a fluorescent peak wavelength of approximately 423 nm and a fluorescence full-width at half-maximum of approximately 15 nm.

Furthermore, the fluorescence quantum efficiency of the ZnSe/ZnS dispersed in the hexane was measured using the quantum efficiency measurement system described above. The measurement results showed that the fluorescence quantum efficiency was approximately 60%. Furthermore, the fluorescence lifetime of the ZnSe/ZnS dispersed in the hexane was measured using the fluorescence lifetime measurement device described above, and was found to be 44 ns.

Additionally, the particle diameter (outermost particle diameter, average value (d) of assumed particle diameters) of the ZnSe/ZnS dispersed in the hexane was measured using the scanning electron microscope described above. Furthermore, the X-ray diffraction spectrum of the ZnSe/ZnS dispersed in the hexane was measured using the X-ray diffraction (XRD) device described above.

As a result, it was confirmed that the particle diameter (outermost particle diameter, average value (d) of assumed particle diameters) of the ZnSe/ZnS was approximately 8.5 nm, and the shell thickness was increased by 1.6 nm with the covering of ZnSe with ZnS. Additionally, it was found that the ZnSe/ZnS crystal was a cubic crystal, and the maximum peak intensity thereof was shifted 1.1° further to a higher angle side than the crystal peak position of ZnSe.

As described above, according to the synthesis example of the QDs 25 described above, the QDs 25 having a particle diameter within a range from 3 nm to 20 nm can be obtained. Further, it was found that the fluorescence quantum efficiency of the QDs 25 obtained in the synthesis example of the QDs 25 described above was 5% or greater, and the fluorescence full-width at half-maximum was 25 nm or less. It was also possible to achieve a fluorescence lifetime of 50 ns or less. Furthermore, it was found that the fluorescent peak wavelength could be adjusted within a range from 410 nm to 470 nm. Additionally, it was found that, in the core-shell structure (ZnSe/ZnS) formed of Zn, Se, and S, the maximum intensity peak position in the X-ray diffraction spectrum was shifted from 0.050 to 1.2° to the higher angle side than the crystal peak with the ZnSe core alone.

From this peak shift to the higher angle side, it was determined that the lattice constant was changed by covering the ZnSe core with ZnS. From these results, it was also discovered that this peak shift amount and the coverage amount of ZnS are proportional. In addition, in the present results, the maximum intensity peak position in the X-ray diffraction spectrum of the QDs 25 having the core-shell structure is almost close to the peak position of ZnS, but because blue (from 430 nm to 455 nm) light is emitted, it is thought that the core 25a is ZnSe, and the core 25a is covered with ZnS as the shell 25b.

Also, when the core 25a is covered with the shell 25b, the maximum intensity peak in the X-ray diffraction spectrum of the QDs 25 moves to a higher angle side than the crystal peak in the X-ray diffraction spectrum of the core 25a alone. Note that the matter of “the maximum intensity peak in the X-ray diffraction spectrum of the QDs 25 moves to a higher angle side than the crystal peak in the X-ray diffraction spectrum of the core 25a alone” indicates that the QDs 25 have a core-shell structure, and thereby the lattice constant of the QDs 25 is smaller than that of the core 25a alone.

Further, as described above, when the core is ZnSe, and the maximum intensity peak in the X-ray diffraction spectrum of the QDs 25 is shifted from 0.050 to 1.2° to the higher angle side than the crystal peak in the X-ray diffraction spectrum of the core 25a alone, an even higher EQE can be achieved.

Further, according to the above (synthesis example of QDs 25), as described above, environmentally-friendly QDs can be provided by using QDs that do not include Cd, or in other words, QDs that are composed of a non-Cd-based material.

### Example 1

First, ethanol was added as a poor solvent to a ZnSe/ZnS-hexane dispersion including the QDs 25 (ZnSe/ZnS) obtained in the above (synthesis example of QDs 25) at a ratio of 20 mg/mL to precipitate the QDs 25, and a cleaning process of removing the supernatant was performed twice. Subsequently, the QDs 25 were re-dispersed in hexane at a concentration of 20 mg/mL to obtain a ZnSe/ZnS-hexane dispersion as the QD dispersion. Next, this QD dispersion was applied onto glass for 30 seconds at 3000 rpm in a nitrogen gas atmosphere to form a QD thin film (QD layer) having a thickness of approximately 50 nm. Subsequently, the QD thin film was resin-sealed in a nitrogen atmosphere to prepare sample (1) as a sample obtained by forming QDs in a thin film state. An epoxy resin was used for resin sealing. Note that a step gauge was used to measure the layer thickness.

Next, the fluorescence quantum efficiency (QY) and the fluorescence lifetime (τ) of the sample (1) were measured at room temperature, and then the sample (1) was heated and maintained at 80° C. for 60 minutes. The sample (1) was heated using a temperature-controllable hot plate. Subsequently, the sample (1) was returned to room temperature, and the fluorescence quantum efficiency and the fluorescence lifetime were measured again.

Note that the multi-channel spectrometer C₁₀₀₂₇ available from Hamamatsu Photonics K.K. was used to measure the fluorescence quantum efficiency. The fluorescence quantum efficiency (QY) excitation wavelength in the measurement of the QY was 350 nm, and the QY calculation fluorescence wavelength was 400 to 450 nm.

Further, the Quantaurus-Tau compact fluorescence lifetime measurement device available from Hamamatsu Photonics K.K. was used to measure the fluorescence quantum efficiency. The excitation wavelength during the measurement of the fluorescence quantum efficiency was 365 nm and the fluorescence measurement wavelength was 425 nm. The results along with the measurement conditions are shown in Table 1.

### Example 2

As a sample obtained by forming QDs in a thin film state, sample (2) was prepared using the same method as that for sample (1).

Next, the fluorescence quantum efficiency (QY) and the fluorescence lifetime (τ) of the sample (2) were measured at room temperature, and then the sample (2) was heated and maintained at 100° C. for 30 minutes. The sample (2) was heated using a temperature-controllable hot plate in the same manner as in example 1. Subsequently, the sample (2) was returned to room temperature, and the fluorescence quantum efficiency and the fluorescence lifetime were measured again.

To measure the fluorescence quantum efficiency, the same multi-channel spectrometer as in example 1 was used. As in example 1, the fluorescence quantum efficiency (QY) excitation wavelength in the measurement of the QY was 350 nm, and the QY calculation fluorescence wavelength was 400 to 450 nm.

Further, to measure the fluorescence quantum efficiency, the same fluorescence lifetime measurement device as in example 1 was used. As in example 1, the excitation wavelength in the measurement of the fluorescence quantum efficiency was 365 nm and the fluorescence measurement wavelength was 425 nm. The results along with the measurement conditions are shown in Table 1.

### Example 3

As a sample obtained by forming QDs in a thin film state, sample (3) was prepared using the same method as that for sample (1).

Next, the fluorescence quantum efficiency (QY) and the fluorescence lifetime (τ) of the sample (3) were measured at room temperature, and then the sample (3) was heated and maintained at 100° C. for 30 minutes. The sample (3) was heated using a temperature-controllable hot plate in the same manner as in example 1. Subsequently, the sample (3) was returned to room temperature, and the fluorescence quantum efficiency and the fluorescence lifetime were measured again.

To measure the fluorescence quantum efficiency, the same multi-channel spectrometer as in example 1 was used. However, the fluorescence quantum efficiency (QY) excitation wavelength in the measurement of the QY was 375 nm, and the QY calculation fluorescence wavelength was 400 to 450 nm.

Further, to measure the fluorescence quantum efficiency, the same fluorescence lifetime measurement device as in example 1 was used. As in examples 1 and 2, the excitation wavelength in the measurement of the fluorescence quantum efficiency was 365 nm and the fluorescence measurement wavelength was 425 nm. The results along with the measurement conditions are shown in Table 1.

### COMPARATIVE EXAMPLE

A 100 mL reaction vessel was charged with 182 mg of anhydrous copper acetate (Cu(OAc)₂) as a Cu raw material (organic copper compound), 4.8 mL of oleylamine (OLAm) as a ligand, and 7.75 mL of octadecene (ODE) as a solvent. The raw materials in the reaction vessel were then heated and dissolved at 163° C. for 10 minutes in an inert gas (N₂) atmosphere while being stirred, and a solution was thereby obtained.

Next, 1.14 mL of an Se-DDT/OLAm solution (0.7 M) was added as an organic chalcogen compound to the solution, and the resulting mixture was heated at 163° C. for 30 minutes while being stirred. The reaction solution (Cu₂Se reaction liquid, copper chalcogenide) thereby obtained was cooled to room temperature.

Subsequently, 1844 mg of anhydrous zinc acetate (Zn(OAc)₂) as an organic zinc compound, 10 mL of trioctylphosphine (TOP) as a solvent, and 0.4 mL of oleylamine (OLAm) as a ligand were added to the Cu₂Se reaction liquid, and the resulting mixture was heated at 180° C. for 60 minutes in an inert gas (N₂) atmosphere while being stirred. As a result, a metal exchange reaction occurred between Cu of the copper chalcogenide and Zn. The resulting reaction solution (ZnSe solution) was cooled to room temperature.

Next, toluene as a solvent and ethanol as a poor solvent were added to the reaction solution cooled to room temperature to generate a precipitate, and the reaction solution was centrifuged (cleaned and separated) to recover the precipitate. Next, 24 mL of octadecene (ODE) was added as a solvent (dispersion medium) to the recovered precipitate, and the precipitate was dispersed, and thereby a ZnSe-ODE dispersion was obtained. Note that the cleaning and separating above refers to a process of separating the particles in the reaction solution by controlling the degree of aggregation due to the difference in the coordination state of the ligand by the ratio between the solvent (non-polar solvent) such as toluene and the poor solvent (polar solvent) such as ethanol.

Subsequently, 1844 mg of anhydrous zinc acetate (Zn(OAc)₂) as an organic zinc compound, 10 mL of trioctylphosphine (TOP) as a ligand, and 1.0 mL of oleylamine (OLAm) and 6 mL of oleic acid (OLAc) as ligands were added to 24 mL of this ZnSe-ODE dispersion, and the mixture was heated at 280° C. for 20 minutes in an inert gas (N₂) atmosphere while being stirred. The resulting reaction solution (ZnSe dispersion) was cooled to room temperature.

The fluorescence wavelength and the fluorescence full-width at half-maximum of ZnSe in this reaction solution (ZnSe dispersion) were measured using the same fluorescence spectrometer as in the examples. The measurement results indicated optical characteristics including a fluorescent peak wavelength of approximately 447 nm and a fluorescence full-width at half-maximum of approximately 14 nm.

In addition, ethanol was added as a poor solvent to several mL of the reaction solution (ZnSe dispersion) to generate a precipitate, and the solution was centrifuged (isolated) to recover the precipitate. Hexane was added as a solvent (dispersion medium) to the recovered precipitate, and the precipitate was dispersed.

The fluorescence quantum efficiency of the ZnSe dispersed in the hexane was measured using a quantum efficiency measurement system. The QE-1100 quantum efficiency measurement system available from Otsuka Electronics Co. Ltd. described above (synthesis example of QDs 25) was used as the quantum efficiency measurement system. The measurement results showed that the fluorescence quantum efficiency was approximately 46%. Furthermore, the fluorescence lifetime of the ZnSe dispersed in the hexane was measured using a fluorescence lifetime measurement device, and was found to be 18 ns. Note that the C11367 fluorescence lifetime measurement device available from Hamamatsu Photonics K.K. described above (synthesis example of QDs 25) was used to measure the fluorescence lifetime.

Additionally, the particle diameter (average value of assumed particle diameters) of the ZnSe dispersed in the hexane was measured using the same scanning electron microscope as in the examples. Furthermore, the XRD spectrum of the ZnSe dispersed in the hexane was measured using the same X-ray diffraction (XRD) device as in the examples.

As a result, the particle diameter (average value of assumed particle diameters) of the ZnSe was approximately 8.3 nm. Additionally, it was found that the ZnSe crystal was a cubic crystal, and the peak position thereof was consistent with the crystal peak position of ZnSe.

Next, 20 mL of the reaction solution (ZnSe dispersion) was collected, toluene, ethanol, and methanol were added thereto as poor solvents to generate a precipitate, and the mixture was centrifuged to recover (isolate) the precipitate. 17.5 mL of octadecene (ODE) as a solvent (dispersion medium) was added to the recovered precipitate to thereby disperse the precipitate. As a result, a ZnSe-ODE dispersion obtained by dispersing ZnSe particles (hereinafter simply referred to as “ZnSe”) in octadecene (ODE) as a core was obtained.

Subsequently, 1 mL of oleic acid (OLAc) as a ligand and 2 mL of trioctylphosphine (TOP) as a solvent (dispersion medium) were added to 17.5 mL of the ZnSe-ODE dispersion, and the resulting mixture was heated at 320° C. for 10 minutes in an inert gas (N₂) atmosphere while being stirred.

Next, 0.5 mL of a mixed solution (A) described below was added to the solution thereby obtained, and the resulting mixture was heated at 320° C. for 10 minutes while being stirred, and thereby ZnSe as a core was covered with ZnSeS as a shell. Note that the mixed solution (A) was a mixed solution of 0.125 mL of dodecanethiol (DDT) as an S raw material, 0.5 mL of Se-TOP (1.0 M) as an Se raw material, 2.5 mL of octadecene (ODE) as a solvent (dispersion medium), 0.375 mL of trioctylphosphine (TOP) as a ligand, and 2.5 mL of a zinc oleate (Zn(OLAc)₂) solution (0.8 M) as an organic zinc compound. In this comparative example, this operation (covering with a shell) was repeated four times. That is, in this comparative example, “adding the mixed solution (A) and heating at 320° C. for 10 minutes while stirring” was performed once (covering with a shell), and this (covering with a shell) was repeated four times. As a result, a reaction solution (ZnSe/ZnSeS dispersion) including ZnSe/ZnSeS particles (hereinafter referred to simply as “ZnSe/ZnSeS”) with ZnSe as the core covered with ZnSeS as the shell was obtained.

Subsequently, toluene as a solvent and acetone and ethanol as poor solvents were added to the total amount of this reaction solution (ZnSe/ZnSeS dispersion) to generate a precipitate, and the solution was centrifuged (cleaned and separated) to recover the precipitate. 17.5 mL of octadecene (ODE) as a solvent (dispersion medium) was added to the recovered precipitate to thereby disperse the precipitate. As a result, a ZnSe/ZnSeS-ODE dispersion obtained by dispersing, in octadecene (ODE), ZnSe/ZnSeS particles (hereinafter referred to simply as “ZnSe/ZnSeS”) including ZnSe as the core covered with ZnSeS as the shell was obtained.

Next, 0.5 mL of a mixed solution (B) described below was added to this ZnSe/ZnSeS-ODE dispersion, and the resulting mixture was heated at 320° C. for 10 minutes while being stirred, thereby covering the ZnSe/ZnSeS particles with ZnS as a shell. Note that the mixed solution (B) was a mixed solution of 0.5 mL of dodecanethiol (DDT) as an S raw material, 5 mL of octadecene (ODE) as a solvent (dispersion medium), 1.5 mL of trioctylphosphine (TOP) as a ligand, and 5 mL of a zinc oleate (Zn(OLAc)₂) solution (0.8 M) as an organic zinc compound. In the present synthesis example, this operation (covering with a shell) was repeated ten times. That is, in this comparative example, “adding the mixed solution (B) and heating at 320° C. for 10 minutes while stirring” was performed once (covering with a shell), and this (covering with a shell) was repeated ten times. As a result, a reaction solution (ZnSe/ZnSeS/ZnS(1) dispersion) including ZnSe/ZnSes/ZnS particles (hereinafter referred to as “ZnSe/ZnSeS/ZnS(1)”) with ZnSe as the core covered with ZnSeS and ZnS, in this order from the core side, as the shell was obtained.

Subsequently, toluene, acetone, and ethanol were added as poor solvents to the total amount of the reaction solution (ZnSe/ZnSeS/ZnS(1) dispersion) to generate a precipitate, and the resulting solution was centrifuged to recover (separate) the precipitate (ZnSe/ZnSeS/ZnS(1)). 17.5 mL of octadecene (ODE) was added as a solvent (dispersion medium) to the recovered precipitate and dispersed, and a ZnSe/ZnSeS/ZnS(1)-ODE dispersion with ZnSe/ZnSeS/ZnS(1) dispersed in octadecene (ODE) was obtained.

Next, 0.5 mL of a mixed solution (C) having the same composition as the mixed solution (B) was added to this ZnSe/ZnSeS/ZnS(1)-ODE dispersion, and the resulting mixture was heated at 320° C. for 10 minutes while being stirred, thereby further covering the ZnSe/ZnSeS/ZnS(1) with ZnS as a shell. Note that the mixed solution (C) was a mixed solution of 0.5 mL of dodecanethiol (DDT) as an S raw material, 5 mL of octadecene as a solvent (dispersion medium), 1.5 mL of trioctylphosphine (TOP) as a ligand, and 5 mL of a zinc oleate (Zn(OLAc)₂) solution (0.8 M) as an organic zinc compound. In this comparative example, this operation (covering with a shell) was repeated six times. That is, in this comparative example, “adding the mixed solution (C) and heating at 320° C. for 10 minutes while stirring” was performed once (covering with a shell), and this (covering with a shell) was repeated six times. As a result, a reaction solution (ZnSe/ZnSeS/ZnS(2) dispersion) including ZnSe/ZnSes/ZnS particles (hereinafter referred to as “ZnSe/ZnSeS/ZnS(2)”) with ZnSe/ZnSeS/ZnS(1) further covered with ZnS as the shell was obtained.

Subsequently, toluene, acetone, and ethanol were added as poor solvents to the total amount of the reaction solution (ZnSe/ZnSeS/ZnS(2) dispersion) to generate a precipitate, and the resulting solution was centrifuged to recover (separate) the precipitate (ZnSe/ZnSeS/ZnS(2)). 17.5 mL of octadecene (ODE) was added as a solvent (dispersion medium) to the recovered precipitate and dispersed, and a ZnSe/ZnSeS/ZnS(2)-ODE dispersion with ZnSe/ZnSeS/ZnS(2) dispersed in octadecene (ODE) was obtained.

Next, 0.5 mL of a mixed solution (D) having the same composition as the mixed solutions (B), (C) was added to this ZnSe/ZnSeS/ZnS(2)-ODE dispersion, and the resulting mixture was heated at 320° C. for 10 minutes while being stirred, thereby further covering the ZnSe/ZnSeS/ZnS(2) with ZnS as a shell. Note that the mixed solution (D) was a mixed solution of 0.5 mL of dodecanethiol (DDT) as an S raw material, 5 mL of octadecene (ODE) as a solvent (dispersion medium), 1.5 mL of trioctylphosphine (TOP) as a ligand, and 5 mL of a zinc oleate (Zn(OLAc)₂) solution (0.8 M) as an organic zinc compound. In this comparative example, this operation (covering with a shell) was repeated six times. As a result, a reaction solution (ZnSe/ZnSeS/ZnS(3) dispersion) including ZnSe/ZnSes/ZnS particles (hereinafter referred to as “ZnSe/ZnSeS/ZnS(3)”) with ZnSe/ZnSeS/ZnS(2) further covered with ZnS as the shell was obtained.

Subsequently, toluene, acetone, and ethanol were added as poor solvents to the total amount of the reaction solution (ZnSe/ZnSeS/ZnS(3) dispersion) to generate a precipitate, and the resulting solution was centrifuged to recover (separate) the precipitate (ZnSe/ZnSeS/ZnS(3)). 17.5 mL of octadecene (ODE) was added as a solvent (dispersion medium) to the recovered precipitate and dispersed, and a ZnSe/ZnSeS/ZnS(3)-ODE dispersion with ZnSe/ZnSeS/ZnS(3) dispersed in octadecene (ODE) was obtained.

Next, 0.5 mL of a mixed solution (E) having the same composition as the mixed solutions (B) to (D) was added to this ZnSe/ZnSeS/ZnS(3)-ODE dispersion, and the resulting mixture was heated at 320° C. for 10 minutes while being stirred, thereby further covering the ZnSe/ZnSeS/ZnS(3) with ZnS as a shell. Note that the mixed solution (E) was a mixed solution of 0.5 mL of dodecanethiol (DDT) as an S raw material, 5 mL of octadecene as a solvent (dispersion medium), 1.5 mL of trioctylphosphine (TOP) as a ligand, and 5 mL of a zinc oleate (Zn(OLAc)₂) solution (0.8 M) as an organic zinc compound. In the present synthesis example, this operation (covering with a shell) was repeated six times. As a result, as the QD 25 according to the present embodiment, a reaction solution (ZnSe/ZnSeS/ZnS(4) dispersion) including ZnSe/ZnSes/ZnS particles (hereinafter referred to as “ZnSe/ZnSeS/ZnS(4)”) with ZnSe/ZnSeS/ZnS(3) further covered with ZnS as the shell was obtained.

The fluorescence wavelength and the fluorescence full-width at half-maximum of ZnSe/ZnSeS/ZnS(4) in this reaction solution (ZnSe/ZnSeS/ZnS(4)) dispersion) were measured using the same fluorescence spectrometer as in the examples. The measurement results indicated optical characteristics including a fluorescent peak wavelength of approximately 443 nm and a fluorescence full-width at half-maximum of approximately 15 nm.

Next, ethanol was added as a poor solvent to the reaction solution (ZnSe/ZnSeS/ZnS(4) dispersion) to generate a precipitate, and the resulting solution was centrifuged to recover (separate) the precipitate (ZnSe/ZnSeS/ZnS(4)). Subsequently, hexane was added as a solvent (dispersion medium) to this precipitate ((ZnSe/ZnSeS/ZnS (4)), and the precipitate was dispersed. As a result, a ZnSe/ZnSeS/ZnS(4)-hexane dispersion with ZnSe/ZnSeS/ZnS(4) as the QDs 25 dispersed in hexane as a solvent (dispersion medium) was obtained.

The fluorescence quantum efficiency of the (ZnSe/ZnSeS/ZnS(4) dispersed in the hexane was measured using the quantum efficiency measurement system described above. The measurement results showed that the fluorescence quantum efficiency was approximately 64%. Furthermore, the fluorescence lifetime of the ZnSe/ZnSeS/ZnS(4) dispersed in the hexane was measured using the fluorescence lifetime measurement device described above, and was 15 ns.

Further, in this comparative example, with every shell coating, the particle diameter (the outermost particle diameter, average value of assumed particle diameters) of the obtained particles (ZnSe/ZnSeS particles, ZnSe/ZnSeS/ZnS particles) was measured with the scanning electron microscope (SEM) described above.

As a result, in the ZnSe/ZnSeS-ODE dispersion described above, it was confirmed that the particle diameter (outermost particle diameter, average value of assumed particle diameters) of the ZnSe/ZnSeS (ZnSe/ZnSeS particles) dispersed in octadecene (ODE) was approximately 10.3 nm, and the shell thickness increased by 1 nm with the covering of ZnSe with ZnSeS. Further, it was confirmed that the particle diameter (outermost particle diameter, average value of assumed particle diameters) of the ZnSe/ZnSeS/ZnS(4) dispersed in hexane was approximately 12.3 nm, and the shell thickness further increased by 1 nm with the covering of ZnSe/ZnSeS with ZnS.

That is, it was confirmed that the diameter of the core (average value of assumed particle diameters) of the comparative QD (ZnSe/ZnSeS/ZnS(4)) obtained in this comparative example was approximately 8.3 nm as described above, and the thickness (total thickness) of the shell of the comparative QD was 2 nm, this thickness including the 1-nm thickness of the ZnSeS layer and the 1-nm thickness of the ZnS layer.

Next, sample (4) was prepared as a comparative sample with QDs formed in a thin film state by the same method as with sample (1) except that a ZnSe/ZnSeS/ZnS(4)-hexane dispersion including the comparative QDs (ZnSe/ZnSeS/ZnS(4)) obtained in this comparative example at a ratio of 20 mg/mL was used instead of the ZnSe/ZnS-hexane dispersion used in examples 1 to 3.

Next, the fluorescence quantum efficiency (QY) and the fluorescence lifetime (τ) of the sample (4) were measured at room temperature, and then, as in example 1, the sample (4) was heated and maintained at 80° C. for 60 minutes. The sample (4) was heated using a temperature-controllable hot plate in the same manner as in example (1). Subsequently, the sample (4) was returned to room temperature, and the fluorescence quantum efficiency and the fluorescence lifetime were measured again.

To measure the fluorescence quantum efficiency, the same multi-channel spectrometer as in example 1 was used. However, the fluorescence quantum efficiency (QY) excitation wavelength in the measurement of the QY was 350 nm, and the QY calculation fluorescence wavelength was 420 to 470 nm.

Further, to measure the fluorescence quantum efficiency, the same fluorescence lifetime measurement device as in example 1 was used. However, the excitation wavelength in the measurement of the fluorescence quantum efficiency was 365 nm and the fluorescence measurement wavelength was 445 nm. The results along with the measurement conditions are shown in Table 1.

TABLE 1
Table 1

| | | | | | Comparative |
|---|---|---|---|---|---|
| | | Example 1 | Example 2 | Example 3 | example |
| Heating conditions | | 80° C. | 100° C. | 100° C. | 80° C. |
| | | 60 minutes | 30 minutes | 30 minutes | 60 minutes |
| QY | QY excitation wavelength | 350 | 350 | 350 | 350 |
| measurement | (nm) | | | | |
| | QY calculation | 400 to 450 | 400 to 450 | 400 to 450 | 420 to 470 |
| | fluorescence wavelength | | | | |
| | (nm) | | | | |
| τ | Excitation wavelength | 365 | 365 | 365 | 365 |
| measurement | (nm) | | | | |
| | Fluorescence measurement | 425 | 425 | 425 | 445 |
| | wavelength | | | | |
| | (nm) | | | | |
| QY | Before heating | 21.5 | 38.0 | 16.9 | 48.7 |
| | After heating | 35.2 | 49.3 | 35.0 | 46.1 |
| τ | Before heating | 4.51 | 6.62 | 3.95 | 15.4 |
| | After heating | 6.29 | 8.47 | 9.25 | 15.5 |

In examples 1 to 3, the core 25a made of ZnSe and the shell 25a made of ZnS covering the core 25b are directly adjacent to each other. On the other hand, in the comparative example, the shell made of ZnSeS is interposed between the core made of ZnSe and the shell made of ZnS.

Therefore, in the case of examples 1 to 3, the fluorescent peak wavelength (λp) is 425 nm, and the particle diameter (d) of the QD 25 (average value of assumed particle diameters) is 8.5 nm, and thus d−(6.1/((1240/λp)−2.7)^{1/2}=3.2 nm.

On the other hand, in the comparative example, the fluorescent peak wavelength (λp) is 445 nm, and the particle diameter (d) of the QD 25 (average value of assumed particle diameters) is 12.3 nm, and thus d−(6.1/((1240/λp)−2.7))^{1/2}=3.9 nm.

Further, as understood from the results shown in Table 1, in examples 1 to 3, the fluorescence lifetime (τ) of the QD 25 in a thin film state is 50 ns or less, and the QD 25 maintains the characteristics in the solution state even in the thin film state. Further, by heating, the fluorescence lifetime (τ) of the QD 25 in the thin film state is 39.4500 in example 1, 27.95% in example 2, and 135.37% in example 3, each of which is an increase of 20% or more as compared with those before heating. Then, by this heating, the fluorescence quantum efficiency of the QD 25 in the thin film state is 63.72% in example 1, 29.73% in example 2, and 107.10% in example 3, each of which is an increase of 20% or more as compared with those before heating.

However, in the comparative example, the fluorescence lifetime of the QD in the thin film state does not change between before and after heating (within the range of error), and the fluorescence quantum efficiency of the QD in the thin film state rather decreases due to the heating.

As described above, according to the present embodiment, the QD 25 exhibiting a new advantageous effect of increasing the fluorescence quantum efficiency when in a thin film state by being heated can be provided. Further, because the fluorescence quantum efficiency can be increased by heating as described above, when the QD 25 is used for the QD layer 15, even if the luminance of the light-emitting device 1 temporarily decreases due to deterioration of the QD layer 15 or the like, the light-emitting device 1 capable of improving the decreased luminance can be provided.

### Second Embodiment

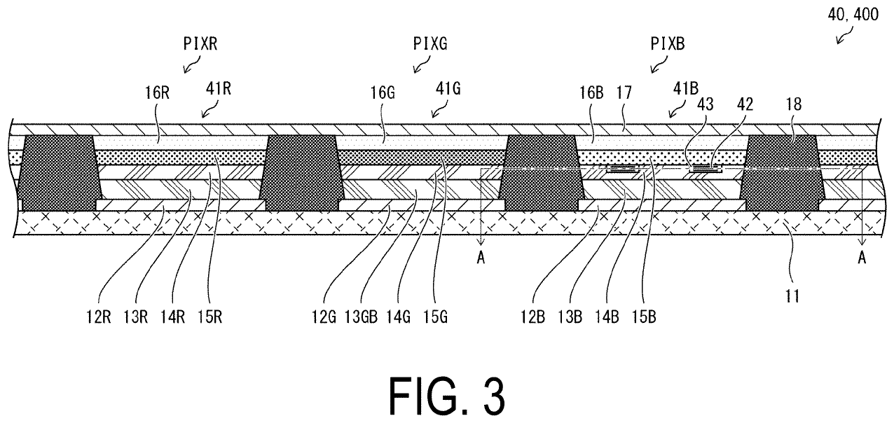

Another embodiment of the disclosure will be described below with reference to FIG. 3 to FIG. 11. Note that differences from the first embodiment will be described in the present embodiment. For convenience of description, members having the same functions as the members described in the first embodiment are designated by the same reference signs, and descriptions thereof are omitted.

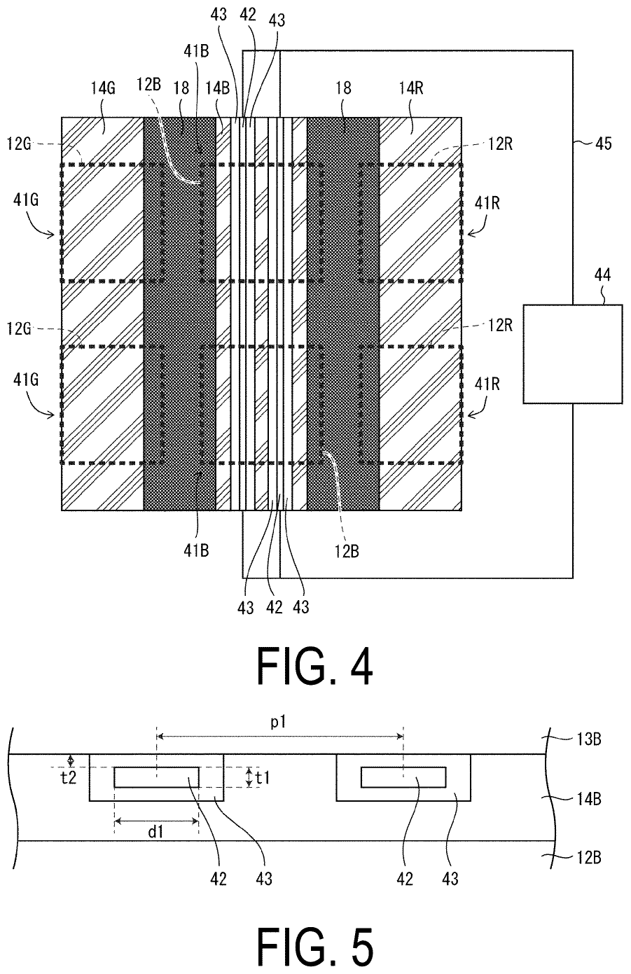

FIG. 3 is a cross-sectional view schematically illustrating a schematic configuration of main portions of a display device 400 according to the present embodiment. Further, FIG. 4 is a diagram schematically illustrating a schematic configuration of the main portions of the display device 400 according to the present embodiment in a cross section taken along line A-A in FIG. 3.

The display device 400 includes a light-emitting device 40. The light-emitting device 40 may be used as, for example, a display panel or a light source (illumination device) for the display device 400.

As illustrated in FIG. 3, the display device 400 (light-emitting device 40) according to the present embodiment includes a plurality of pixels including the R pixel (PIXR), the G pixel (PIXG), and the B pixel (PIXB). Note that the R pixel may be referred to as an R subpixel. This similarly applies to the G pixel and the B pixel.

In the display device 400, one picture element is constituted by the PIXR, the PIXG, and the PIXB. Further, in the present embodiment, when there is no need to distinguish these pixels PIXR, PIXG, PIXB, the pixels PIXR, PIXG, PIXB are collectively referred to simply as PIX.

The display device 400 has a structure provided with a light-emitting device layer including a plurality of types of light-emitting devices having different emission peak wavelengths.

The light-emitting device layer is provided with light-emitting devices corresponding to each PIX. In the PIXR, a light-emitting device 41R is provided as the red light-emitting device. In the PIXG, a light-emitting device 41G is provided as the green light-emitting device. In the PIXB, a light-emitting device 41B is provided as the blue light-emitting device.

The light-emitting device 41R, the light-emitting device 41G, and the light-emitting device 41B have the same configuration as that of the light-emitting device 1 according to the first embodiment, except that the light-emitting device 41B is provided with a heating element layer 42 as a heat source for heating the QD layer (light-emitting layer). Note that the red QD and the green QD used in the PIXR (light-emitting device 41R) and the PIXG (light-emitting device 41G) are not particularly limited. However, as described in the first embodiment, indium phosphide (InP), for example, can be suitably used as the red QD and the green QD, as long as the materials are limited to non-Cd-based materials.

Hereinafter, in the present embodiment, when there is no need to distinguish the light-emitting device 41R, the light-emitting device 41G, and the light-emitting device 41B from one another, these light-emitting devices are collectively referred to simply as a light-emitting device 41.

The light-emitting device layer has a structure in which each layer of the light-emitting device 41 is layered on the substrate 11. Hereinafter, as an example, a case in which an anode, a hole injection layer, a hole transport layer, a QD layer, an electron transport layer, and a cathode are layered in this order on the substrate 11 will be described. However, the present embodiment is not limited to this example. As described in the first embodiment, the cathode, the electron transport layer, the QD layer, the hole transport layer, the hole injection layer, and the anode may be layered in this order on the substrate 11.

In the present embodiment, as illustrated in FIGS. 3 and 4, the anode, for example, patterned in an island shape is individually provided to each PIX on the substrate 11. Hereinafter, (i) an anode provided on the PIXR (light-emitting device 41R) is referred to as an anode 12R, (ii) an anode provided on the PIXG (light-emitting device 41G) is referred to as an anode 12G, and (iii) an anode provided on the PIXB (light-emitting device 41B) is referred to as an anode 12B.

Note that the present embodiment, as illustrated in FIG. 4, illustrates as an example a case in which the display device 400 (light-emitting device 40) has stripe arrays in which the PIXs of the same color are respectively aligned in straight lines in a column direction and the PIXRs, the PIXGs, and the PIXBs are alternately aligned in this order in a row direction. However, the pixel arrangement of the display device 400 (light-emitting device 40) is not limited thereto. The display device 400 (light-emitting device 40) may have another pixel arrangement.

In the example illustrated in FIG. 4, a bank 18 for partitioning adjacent PIXs is formed as a pixel separation film on the substrate 11, partitioning PIXs of different colors only. Therefore, the banks 18 illustrated in FIG. 4 are not provided between the PIXs of the same color, but are formed in a stripe pattern along the PIX columns of the same color arranged in the column direction.

The pixel separation film is also used as an edge cover for covering an edge of a patterned lower electrode. Therefore, the light-emitting device including a portion of the bank 18 may be referred to as a light-emitting device. In other words, the light-emitting device may include a portion of the bank 18 as a bank.

The banks 18 according to the present embodiment covers edges between the PIXs of different colors of the anodes 12R, 12G, 12B.

The bank 18 is an insulating film. As the insulating material used for the bank 18, a known photosensitive resin can be used, for example. Examples of the photosensitive resin include acrylic resins and polyamide resins.

The anode 12R, the anode 12G, and the anode 12B are separated by the banks 18. Further, the hole injection layer, the hole transport layer, the QD layer, and the electron transport layer in the PIXR, the PIXG, and the PIXB are also separated by the banks 18.

Hereinafter, (i) a hole injection layer provided in the PIXR is referred to as a hole injection layer 13R, (ii) a hole injection layer provided in the PIXG is referred to as a hole injection layer 13G, and (iii) a hole injection layer provided in the PIXB is referred to as a hole injection layer 13B. Further, (i) a hole transport layer provided on the PIXR is referred to as a hole transport layer 14R, (ii) a hole transport layer provided on the PIXG is referred to as a hole transport layer 14G, and (iii) a hole transport layer provided on the PIXB is referred to as a hole transport layer 14B. Further, (i) a QD layer provided in the PIXR is referred to as a QD layer 15R, (ii) a QD layer provided in the PIXG is referred to as a QD layer 15G, and (iii) a QD layer provided in the PIXB is referred to as a QD layer 15B. Further, (i) an electron transport layer provided in the PIXR is referred to as an electron transport layer 16R, (ii) an electron transport layer provided in the PIXG is referred to as an electron transport layer 16G, and (iii) an electron transport layer provided in the PIXB is referred to as an electron transport layer 16B.

However, hereinafter, when there is no need to distinguish the anode 12R, the anode 12G, and the anode 12B from one another, these anodes are collectively referred to simply as the anode 12. Similarly, when there is no need to distinguish the hole injection layer, the hole transport layer, the QD layer, and the electron transport layer in each PIX, the hole injection layer, the hole transport layer, the QD layer, and the electron transport layer are simply referred to as the hole injection layer 13, the hole transport layer 14, the QD layer 15, and the electron transport layer 16, respectively.

Note that the cathode is not separated by the bank 18 and is formed in common to the PIXR, the PIXG, and the PIXB. Accordingly, the cathode is referred to as the cathode 17 regardless of the PIX in which the electrode is provided.

The light-emitting device 41R includes the anode 12R, the hole injection layer 13R, the hole transport layer 14R, the QD layer 15R, the electron transport layer 16R, and the cathode 17. The light-emitting device 41G includes the anode 12G, the hole injection layer 13G, the hole transport layer 14G, the QD layer 15G, the electron transport layer 16G, and the cathode 17. The light-emitting device 41B includes the anode 12B, the hole injection layer 13B, the hole transport layer 14B, the QD layer 15B, the electron transport layer 16B, and the cathode 17.

Further, the display device 400 (light-emitting device 40) includes, for example, a thin film transistor (TFT) array substrate as the substrate 11. On the substrate 11, a TFT layer provided with a plurality of TFTs is formed as a drive element layer.

The anode 12 provided in each PIX is electrically connected to each of the plurality of TFTs provided to the substrate 11.

As described in the first embodiment, the light-emitting device according to the disclosure has a high fluorescence quantum efficiency with the use of the QDs 25 described above in the QD layer. Further, in the light-emitting device according to the disclosure, because the fluorescence lifetime of the QDs 25 in a thin film state (τ, in other words, the fluorescence lifetime of the QD layer) increases and the fluorescence quantum efficiency increases (improves) by heating, even if the luminance decreases, the luminance can be returned (or brought close) to the original state.

Therefore, in the present embodiment, the light-emitting device 41B is provided with the heating element layer 42 as a heat source for heating the QD layer 15B.

The heating element layer 42 illustrated in FIGS. 3 and 4 is, for example, a wiring line layer made of a heating wiring line (heat source wiring line) having a thin line shape and connected to a heating power supply 44 via a connection wiring line 45. When voltage is applied to the heating power supply 44, the heating element layer 42 is resistively heated by a current flowing through the heating element layer 42. In the present embodiment, indirect resistance heating of the QD layer 15B is performed by the heating element layer 42 heated by this resistance heating. Note that, in the disclosure, a “thin line shape” refers to a line shape having a line width of 10 μm or less. The line width of the heating element layer (for example, the line width of the heating element layer 42) refers to a length of the heating element layer (in the present embodiment, the heating element layer 42) in a short-hand direction (direction orthogonal to a longitudinal direction) in plan view.

A material of the heating element layer 42 need only be any material that can be used as a heat source, and any material that can be generally used as a wiring line can be used. Therefore, the material of the heating element layer 42 is not particularly limited, and examples include metals such as aluminum (Al), stainless steel (SUS), titanium (Ti), iron (Fe), and copper (Cu), and alloys thereof Among these materials, Al is particularly preferable as the material of the heating element layer 42. Generally, Al is often used as an electrode of a light-emitting device. For this reason, Al has high versatility, making it possible to suppress the manufacturing cost by using an Al wiring line for the heating element layer 42.

As illustrated in FIGS. 3 and 4, the heating element layer 42 is covered with an insulating layer 43. Examples of the insulating material used for the insulating layer 43 include inorganic insulating materials such as silicon oxide (SiOx), silicon nitride (SiNx), and silicon oxynitride (SiON). One type of these insulating materials may be used, or two or more types thereof may be mixed and used as appropriate.

Note that the heating element layer 42 may heat the entire light-emitting device 41B, but desirably layers other than the QD layer 15B are not heated to the extent possible to avoid deterioration caused by heat. In other words, desirably only the QD layer 15B is heated. Therefore, desirably the heating element layer 42 is formed, for example, adjacent to the QD layer 15B or in a layer adjacent to the QD layer 15B.

As an example, the heating element layer 42 illustrated in FIGS. 3 and 4 is provided in the hole transport layer 14B adjacent to the QD layer 15B so as to be adjacent to the QD layer 15B with the insulating layer 43 interposed therebetween. An upper face of the insulating layer 43 illustrated in FIGS. 3 and 4 is flush with an upper face of the hole transport layer 14B, and the upper face of the insulating layer 43 is adjacent to (that is, in contact with) the QD layer 15B. The heating element layer 42 is adjacent to the QD layer 15B with the insulating layer 43 interposed therebetween.

As described above, the heating element layer 42 illustrated in FIGS. 3 and 4 is a wiring line layer formed of a heating wiring line having a thin line shape, and the banks 18 are formed in a stripe pattern along the PIX columns of the same color arranged in the column direction. As illustrated in FIG. 4, the heating element layer 42 according to the present embodiment is disposed across a plurality of the PIXBs surrounded by the banks 18 disposed in a stripe pattern. More specifically, the heating element layer 42 according to the present embodiment is disposed between the banks 18 adjacently disposed between the PIXG and the PIXB and between the PIXB and the PIXR, in parallel with the banks 18, and across a plurality of the PIXBs positioned between these banks 18.

As described above, by forming the heating element layer 42 using the heating wiring line having a thin line shape and extending across the plurality of PIXBs, the plurality of PIXBs can be easily and simultaneously heated with a simple configuration. Further, by thus forming the heating element layer 42 in a thin line shape, the QD layer 15B can be heated to a temperature required for improving the fluorescence quantum efficiency of the QD layer 15B with a very small current value. Further, because current can be efficiently converted into heat, energy can be saved. Further, with the heating element layer 42 thus formed in a thin line shape, in a case in which the LB emitted from the QD layer 15B is extracted from the heating element layer 42 side, a reduction in light output efficiency by the heating element layer 42 can be suppressed.

FIG. 5 is a cross-sectional view for describing a size of the heating element layer 42 illustrated in FIG. 3.

As illustrated in FIG. 5, given d1 as the line width of the heating element layer 42, the line width d1 of the heating element layer 42 having a thin line shape need only be 10 μm or less, but is preferably 100 nm or less. As a result, the resistance value can be increased, making it possible to heat the QD layer 15B to a temperature necessary for obtaining the advantageous effects described above with a very small current value as described above, and suppress a reduction in the light output efficiency caused by the heating element layer 42. Further, because current can be efficiently converted into heat, energy can be saved. Furthermore, the line width d1 is preferably 10 nm or greater, for example. In this case, processing is easy and a process cost can be reduced.

Further, as illustrated in FIG. 5, given t1 as a thickness of the heating element layer 42, the thickness t1 is preferably 100 nm or less. This makes it possible to heat the QD layer 15B to a temperature necessary for obtaining the advantageous effects described above with a very small current value as described above, and suppress a reduction in the light output efficiency caused by the heating element layer 42. Further, because current can be efficiently converted into heat, energy can be saved. Furthermore, the thickness t1 is preferably 5 nm or greater, and more preferably 10 nm or greater. This makes it possible to form the heating element layer 42 having a uniform thickness with easy processing. Note that, in the disclosure, the term “thickness” refers to the thickness in the layering direction of the light-emitting device unless otherwise specified.

Note that, among the heating element layers 42 satisfying the conditions described above, an Al wiring line with the line width d1 and the thickness t1 from 10 nm to 100 nm is particularly desirable as the heating element layer 42.

Further, a cross-sectional area (d1×t1) of a plane of the heating element layer 42 parallel to a line width direction is preferably 0.01 μm² or less. Note that a plane parallel to the line width direction of the heating element layer 42 refers to an XZ cross section given that the line width direction of the heating element layer 42 is an X direction and the thickness direction of the heating element layer 42 is a Z direction. This makes it possible to heat the QD layer 15B to a temperature necessary for obtaining the advantageous effects described above with a very small current value as described above, and suppress a reduction in the light output efficiency caused by the heating element layer 42. Further, because current can be efficiently converted into heat, energy can be saved.

A PIXB size in the line width direction is generally within a range from several μm to several tens of μm. As illustrated in FIG. 5, in a case in which a plurality of the heating element layers 42 are provided in the PIXB, given p1 as an arrangement pitch of the heating element layers 42 (wiring line pitch, in other words, pitch between the heating element layers 42 adjacent to each other), desirably the arrangement pitch p1 is within a range from 0.5 μm to 2 μm. This makes it possible to efficiently heat the QD layer 15B to a temperature necessary for obtaining the advantageous effects described above in the line width direction, and suppress a reduction in the light output efficiency caused by the heating element layers 42.

Further, as illustrated in FIG. 5, given t2 as a thickness (covering thickness) of the insulating layer 43 covering the heating element layer 42, the thickness t2 is more preferably within a range from 5 nm to 20 nm. With the thickness of the insulating layer 43 set to 5 nm or greater, the heating element layer 42 can be easily and uniformly covered, and with the thickness of the insulating layer 43 set to 20 nm or less, the QD layer 15B can be efficiently heated.

### Method for Manufacturing Display Device 400

Next, an example of a method for manufacturing the display device 400 (light-emitting device 40) according to the present embodiment will be described with reference to FIGS. 3 to 7.

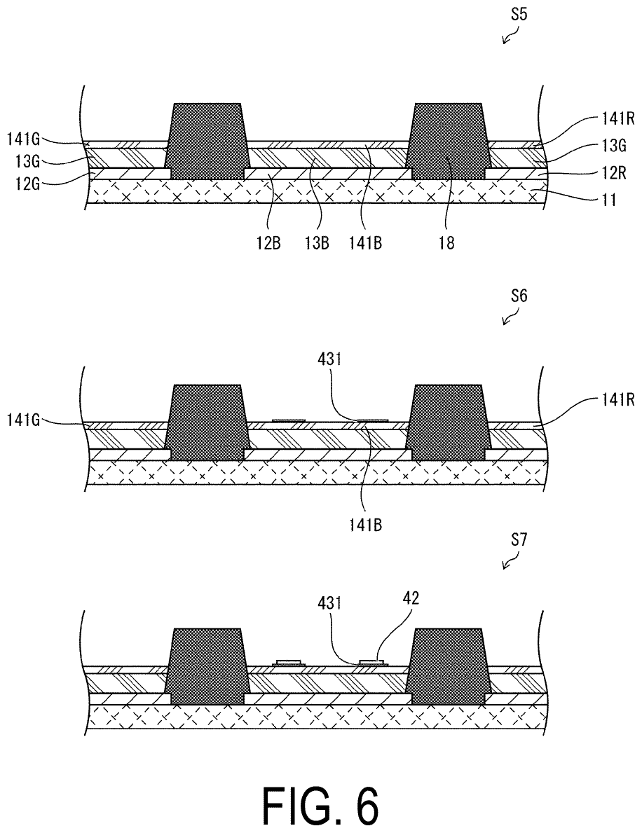

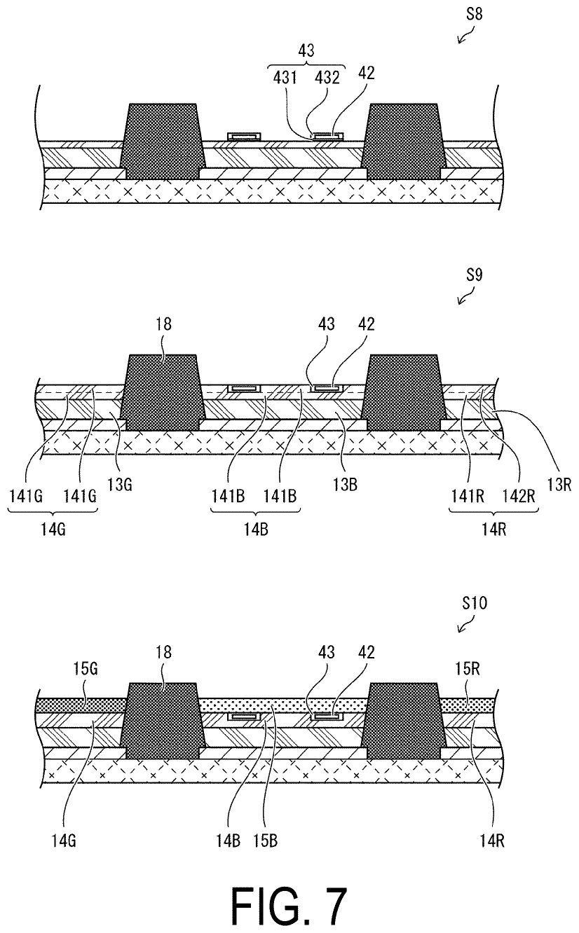

FIG. 6 is a cross-sectional view illustrating, in process order, a method for manufacturing the main portions of the display device 400 (light-emitting device 40) according to the present embodiment. FIG. 7 is another cross-sectional view illustrating, in process order, the method for manufacturing the main portions of the display device 400 (light-emitting device 40) according to the present embodiment. Note that FIG. 7 illustrates manufacturing processes after the manufacturing processes illustrated in FIG. 6.

First, the substrate 11 illustrated in FIG. 3 with a TFT layer (not illustrated) formed therein is formed (step S1, substrate formation process). The substrate 11 can be formed using a known TFT technique. Note that a TFT technique is a technique for forming a semiconductor film such as a silicon film on an insulating substrate such as a glass substrate to process the substrate into a transistor, for example. In the TFT layer, a flattening film (not illustrated) made of an organic insulating film such as an acrylic resin or a polyimide resin is formed covering the TFTs and the wiring lines. Further, contact holes for electrically connecting the anodes 12, for example, as the lower electrodes to the TFTs are formed in the flattening film described above.

Next, as illustrated in FIG. 3, as the anodes 12, the anodes 12R, 12G, 12B are each patterned on the substrate 11 (specifically, on the flattening film described above) (step S2, anode formation process).

The anodes 12R, 12G, 12B can be formed by using, for example, the same method as the formation method of the anode 12 in the first embodiment. However, in the present embodiment, the anode 12 is formed for each pixel. Accordingly, the anode 12 may be formed by using a mask, or may be formed for each pixel by forming the anode material into a solid-like film and then patterning the film. Note that, in the first embodiment, a case in which a sputtering method is used to form the anode 12 is described as an example, but formation of the anode 12 is not limited thereto. For the formation of the anode 12, various methods known in the related art as methods for forming an anode may be used.

Next, as illustrated in FIG. 3, the banks 18 are patterned on the substrate 11 (step S3, bank formation process). In the present embodiment, as illustrated in FIG. 4, the banks 18 are patterned so as to cover the edges of the anodes 12R, 12G, 12B between the PIXs of different colors. Note that, for the formation of the banks 18, various methods known in the related art as methods for forming a bank, such as photolithography, may be used.

Next, as illustrated in FIG. 3, as the hole injection layer 13, the hole injection layers 13R, 13G, 13B are respectively formed on the anodes 12R, 12G, 12B (step S4, hole injection layer formation process). The hole injection layers 13R, 13G, 13B can be formed by using, for example, the same method as the formation method of the hole injection layer 13 described in the first embodiment. However, the method is not limited thereto, and the hole injection layers 13R, 13G, 13B can be formed by using various known methods for forming a hole injection layer.

Next, as indicated by S5 in FIG. 6, first hole transport material layers 141R, 141G, 141B made of a hole transport material are formed on the hole injection layers 13R, 13G, 13B (step S5, first hole transport material layer formation process).

The first hole transport material layers 141R, 141G, 141B are portions of the hole transport layers 14R, 14G, 14B, and formed thinner than the hole transport layers 14R, 14G, 14B. The first hole transport material layers 141R, 141G, 141B can be formed by, for example, the same method as the formation method of the hole transport layer 14 described in the first embodiment. However, the method is not limited thereto, and the first hole transport material layers 141R, 141G, 141B can be formed by using various known methods for forming a hole transport layer.

Next, as indicated by S6 in FIG. 6, a first insulating layer 431 is patterned on the first hole transport material layer 141B by photolithography or the like (step S6, first insulating layer formation process).

The first insulating layer 431 is a portion of the insulating layer 43. In step S6, an insulating material used for the insulating layer 43 is applied by, for example, a sputtering method or the like, and is patterned by, for example, photolithography. In the present embodiment, for example, the insulating material used for the insulating layer 43 is applied by a sputtering method or the like to form an insulating material film, and subsequently a photoresist is applied thereon. This photoresist is then exposed using a photomask. For example, when a negative photoresist is used as the photoresist, the photoresist is exposed using a photomask including an opening having a thin line shape. For example, when a negative photoresist is used as the photoresist, the photoresist exposed from the opening is exposed and cured. The photoresist is then developed to remove the unexposed, uncured photoresist. Then, using the remaining photoresist as a mask, the insulating material film at the location where the photoresist was removed is etched. To etch the insulating material film, wet etching or dry etching can be used, for example. Subsequently, the remaining photoresist is removed with an organic solvent such as acetone. Thus, the first insulating layer 431 made of the insulating material film described above is formed on the first hole transport material layer 141B.

Next, as indicated by S7 of FIG. 6, the heating element layer 42 having a thin line shape and serving as a heat source wiring line is patterned on the first insulating layer 431 by photolithography or the like (step S7, heating element layer formation process (heat source formation process)). The heating element layer 42 is formed by forming a photoresist including an opening only at a position where the heating element layer 42 is to be formed by photolithography or the like, and vapor-depositing the material described above as the material of the heating element layer 42. Subsequently, the photoresist is lifted off to pattern the heating element layer 42 having a thin line shape.

Next, as indicated by S8 in FIG. 6, a second insulating layer 432 is patterned on the first hole transport material layer 141B by photolithography or the like so as to cove the heating element layer 42 (step S8, second insulating layer formation process). As a result, the insulating layer 43 made of the first insulating layer 431 and the second insulating layer 432 and covering the heating element layer 42 is formed. The second insulating layer 432 can be formed using a method similar to the formation method of the first insulating layer 431.

Next, as indicated by S9 in FIG. 7, second hole transport material layers 142R, 142G, 142B made of a hole transport material are formed on the first hole transport material layers 141R, 141G, 141B (step S9, second hole transport material layer formation process). Thus, the hole transport layers 14R, 14G, 14B made of the first hole transport material layers 141R, 141G, 141B and the second hole transport material layers 142R, 142G, 142B are formed on the hole injection layers 13R, 13G, 13B. Specifically, the hole transport layer 14R made of the first hole transport material layer 141R and the second hole transport material layer 142R is formed on the hole injection layer 13R. Further, the hole transport layer 14G made of the first hole transport material layer 141G and the second hole transport material layer 142G is formed on the hole injection layer 13G. Furthermore, the hole transport layer 14B made of the first hole transport material layer 141B and the second hole transport material layer 142B is formed on the hole injection layer 13B. The second hole transport material layers 142R, 142G, 142B can be formed using a method similar to the formation method of the first hole transport material layers 141R, 141G, 141B.

Note that, desirably, upper faces of the hole transport layers 14R, 14G, 14B (in other words, upper faces of the second hole transport material layers 142R, 142G, 142B) have the same height as an upper face of the second insulating layer 432. In other words, desirably, the upper face of the second hole transport material layer 142B and the upper face of the second insulating layer 432 are flush with each other. Accordingly, a photoresist covering the upper face of the second insulating layer 432 may be formed before formation of the second hole transport material layers 142R, 142G, 142B, and the photoresist may be lifted off after formation of the second hole transport material layers 142R, 142G, 142B. Thus, as indicated by S9 in FIG. 7, a step between the upper face of the second hole transport material layer 142B and the upper face of the second insulating layer 432 can be eliminated.

Next, as indicated by S10 in FIG. 6, the QD layers 15R, 15G, 15B are formed on the hole transport layers 14R, 14G, 14B (step S10, QD layer formation process (light-emitting layer formation process)). The QD layers 15R, 15G, 15B can be formed by applying a dispersion (liquid composition) in which QDs are dispersed, and volatilizing the solvent. The QD layer 15B can be formed by using the same method as the formation method of the QD layer 15 described in the first embodiment. The formation method of the QD layers 15R, 15G is not particularly limited, and various known methods for forming a light-emitting layer including QDs can be used. Note that, by using red QDs or green QDs instead of the blue QDs described in the first embodiment, the QD layers 15R, 15G can be formed by the same method as the formation method of the QD layer 15 described in the first embodiment.

Next, as illustrated in FIG. 3, the electron transport layers 16R, 16G, 16B made of an electron transport material are formed on the QD layers 15R, 15G, 15B (step S11, electron transport layer formation process). The electron transport layers 16R, 16G, 16B can be formed by, for example, the same method as the formation method of the electron transport layer 16 described in the first embodiment. However, the method is not limited thereto, and the electron transport layers 16R, 16G, 16B may be formed by using various known methods for forming an electron transport layer.

Next, as illustrated in FIG. 3, the cathode 17 is formed on the electron transport layers 16R, 16G, 16B and the banks 18 (step S12, cathode formation process). The cathode 17 can be formed by, for example, using the same method as the formation method of the cathode 17 described in the first embodiment. However, the method is not limited thereto, and the cathode 17 may be formed by using various known methods for forming a cathode.

Note that, in the present embodiment as well, after formation of the cathode 17, the substrate 11 and the layered body (the anode 12 to the cathode 17) formed on the substrate 11 may be sealed with a sealing member in an N₂ atmosphere.

The light-emitting devices 41R, 41G are formed by the above-described processes. Further, after each of the processes described above, electrical connection is made with the heating power supply 44 via the connection wiring line 45, and the QD layer 15B is heated at a temperature from 80° C. to 100° C. for 30 minutes to 600 minutes (blue QD layer heating process (light-emitting layer heating process)). In this way, the light-emitting device 41B is formed.

Next, an electronic circuit board (not illustrated) such as an integrated circuit (IC) chip and a flexible printed circuit board (FPC) is mounted onto a portion (terminal portion) outward of a display region in which the plurality of PIXs are formed (non-display region, frame). Thus, the display device 400 including the light-emitting device 40 with the light-emitting devices 41R, 41G, 41B formed therein is formed. Note that each of the above-described processes is performed by a display device manufacturing apparatus.

Note that, in the present embodiment, as an example, as each of the anodes 12R, 12G, 12B, an Al electrode having a layer thickness of 100 nm was formed. Further, as each of the hole injection layers 13R, 13G, 13B, a PEDOT layer having a layer thickness of 70 nm was formed. Furthermore, as each of the hole transport layers 14R, 14G, 14B, a PVK layer having a layer thickness of 70 nm was formed. As the QD layer 15B, the QD layer 15 described in the first embodiment was formed at a layer thickness of 20 nm. As the QD layer 15R and the QD layer 15G, InP layers made of InP having different particle diameters were formed, each at a layer thickness of 20 nm. As each of the electron transport layers 16R, 16G, 16B, a ZnO layer having a thickness of 50 nm was formed. As the cathode 17, a 20-nm ITO electrode was formed. As the heating element layer 42, an Al wiring line having the line width d1 of 50 nm and the thickness t1 of 50 nm was formed. The arrangement pitch p1 was 1 μm. Further, the insulating layer 43 was formed of silicon oxide (SiO₂), and the thickness t2 of the insulating layer 43 was 10 nm.

According to the present embodiment, as described above, by heating the QD layer 15B, the light-emitting device 41B having a high fluorescence quantum efficiency and a fluorescence lifetime (τ) in the QD layer 15B of 50 ns or less, and the light-emitting device 40 and the display device 400 including the light-emitting device 41B can be manufactured. At this time, as described above, the QD layer 15B is heated at a temperature from 80° C. to 100° C. for 30 minutes to 600 minutes to relatively increase the fluorescence lifetime (τ) of the QD layer 15B by 10% or more from the value before heating. This heating can then improve the fluorescence quantum efficiency of the light-emitting device 51B.

Further, the light-emitting device 41B includes the heating element layer 42 as a heat source as described above and thus, even when the luminance of the light-emitting device 41B is irreversibly reduced due to deterioration of the QD layer 15B, the peripheral layers thereof (electron transport layer, hole transport layer, electrodes, and the like), or the like due to environmental changes, the passage of time, or the like, the fluorescence quantum efficiency of the light-emitting device 41B can be improved by heating the QD layer 15B. Therefore, the lowered luminance of the light-emitting device 41B can be improved (for example, restored).

### First Modified Example

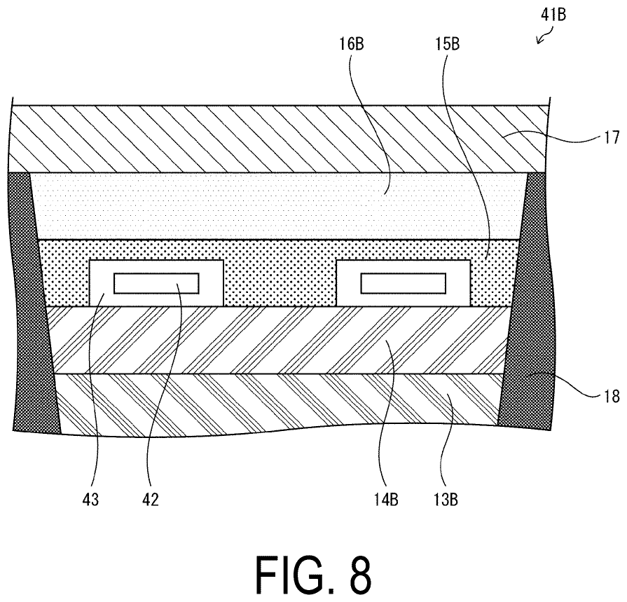

FIG. 8 is a cross-sectional view schematically illustrating one example of a schematic configuration of main portions of the display device 400 according to this modified example.

FIG. 3 illustrates, as an example, a case in which the heating element layer 42 is formed on the hole transport layer 14B adjacent to the QD layer 15B so as to be adjacent to the QD layer 15B with the insulating layer 43 interposed therebetween. However, the heating element layer 42 need only be capable of heating the QD layer 15B. Accordingly, the heating element layer 42 may be formed in the QD layer 15B as illustrated in FIG. 8.

The light-emitting device 41B illustrated in FIG. 8 can be manufactured by the method below.

For example, after steps Si to S4 described above, the hole transport layers 14R, 14G, 14B are formed instead of forming the first hole transport material layers 141R, 141G, 141B as portions of the hole transport layers 14R, 14G, 14B (step S5′, hole transport layer formation process). Subsequently, steps S6 to S8 are performed, and then step S10 is performed without performing process S9. That is, instead of filling the second hole transport material layers 142R, 142G, 142B between the heating element layer 42, covered with the insulating layer 43, and the banks 18, the QD layer 15B is formed covering the heating element layer 42 covered with the insulating layer 43. Subsequently, as in the manufacturing process of the light-emitting device 41B illustrated in FIG. 3, the light-emitting device 41B illustrated in FIG. 8 can be formed by performing step S11 and subsequent processes.

Even in this case, the heating element layer 42 is formed adjacent to the QD layer 15B with the insulating layer 43 interposed therebetween (in other words, the heating element layer 42 covered with the insulating layer 43 is provided adjacent to the QD layer 15B), and thus the QD layer 15B alone can locally be heated. This makes it possible to prevent layers other than the QD layer 15B of the light-emitting device 41B and members other than the light-emitting device such as an IC chip and a sensor from being deteriorated due to heat caused by unnecessary heating.

### Second Modified Example

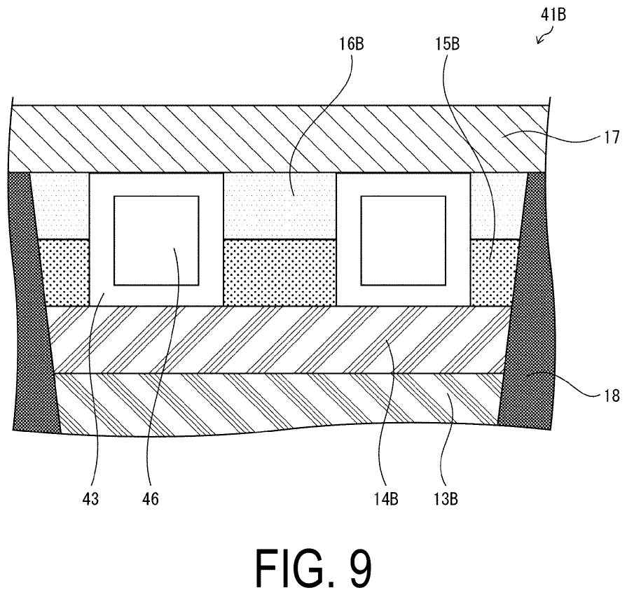

FIG. 9 is a cross-sectional view schematically illustrating one example of a schematic configuration of main portions of the display device 400 according to this modified example.

As illustrated in FIG. 9, the heating element layer 42 may be formed extending across two or more layers. That is, the heating element layer 42 may be formed extending across the QD layer 15B and at least one of the layers vertically adjacent to the QD layer 15B. FIG. 9 illustrates, as an example, a case in which the heating element layer 42 is formed extending across the QD layer 15B and the electron transport layer 16B. However, the heating element layer 42 is not limited thereto, and may be formed extending across the hole transport layer 14B and the QD layer 15B, for example. In this case as well, the heating element layer 42 is adjacent to the QD layer 15B with the insulating layer 43 interposed therebetween. In any case, the QD layer 15B can be efficiently heated by disposing a heat source (for example, the heating element layer 42) for heating the QD layer 15B at least in the QD layer 15B.

Note that the light-emitting device 41B illustrated in FIG. 9 can be easily formed by forming the heating element layer 42 thicker than the QD layer 15B and forming the insulating layer 43 covering the heating element layer 42 in steps S6 to S8 after step S5′ in the first modified example. For example, in steps S6 to S8, the light-emitting device 41B illustrated in FIG. 9 can be manufactured by forming the heating element layer 42 and the insulating layer 43 so that the upper face of the insulating layer 43 covering the heating element layer 42 (specifically, the upper face of the second insulating layer 432) is flush with an upper face of the electron transport layer 16B.

Note that, although FIG. 9 illustrates an example in which the upper face of the insulating layer 43 covering the heating element layer 42 is flush with the upper face of the electron transport layer 16B as described above, the present modified example is not limited thereto. The thicknesses of the heating element layer 42 and the insulating layer 43 can be changed relative to the thicknesses of the QD layer 15B and upper and lower layers thereof to form the light-emitting device 41B including the heating element layer 42 of a desired size.

Further, the size and shape of the heating element layer 42 are not limited to the example illustrated in FIG. 9. The heating element layer 42 may be formed at an interface between the QD layer 15B and any one of the upper and lower layers thereof so as to extend across the QD layer 15B and any one of the upper and lower layers thereof That is, the heating element layer 42 may have a configuration of being vertically interposed between a portion of the QD layer 15B and a portion of any one of the upper and lower layers thereof with the insulating layer 43 interposed therebetween.

### Third Modified Example

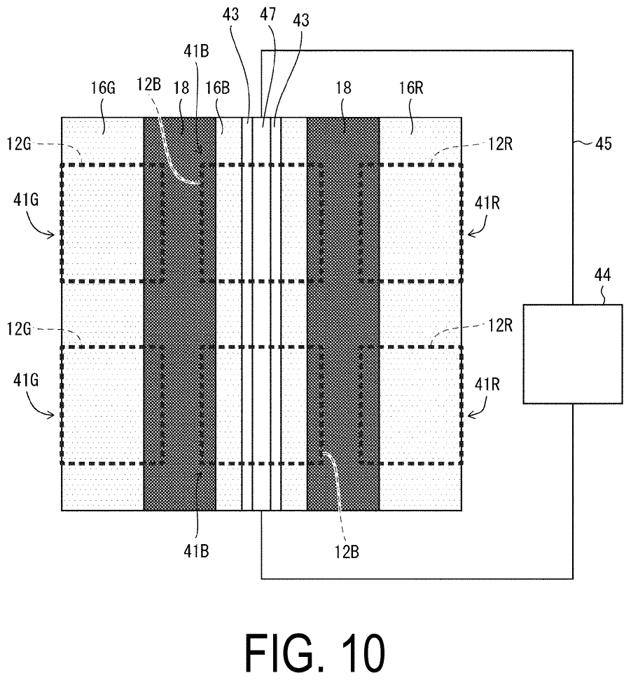

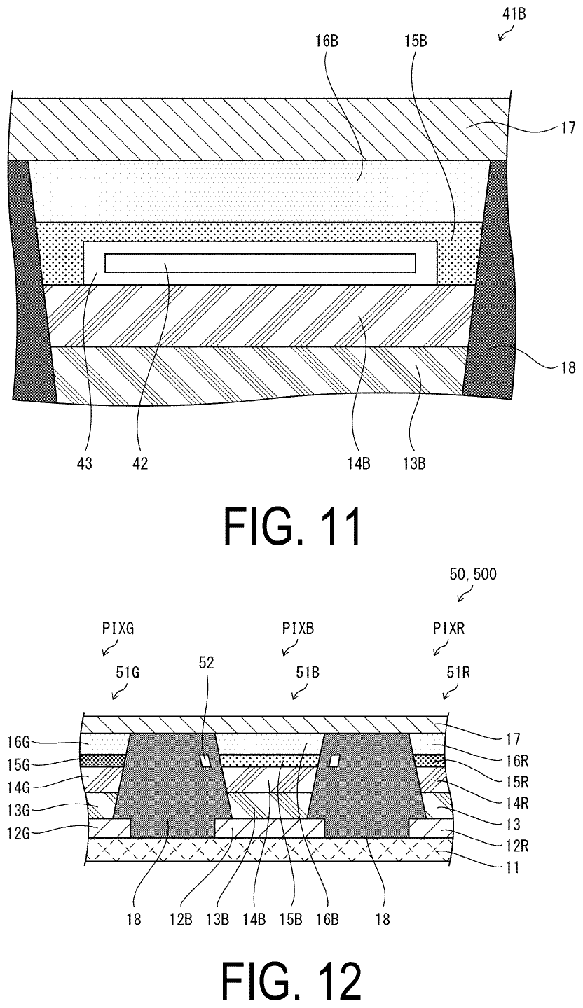

FIG. 10 is a perspective view schematically illustrating a schematic configuration of main portions of the display device 400 according to this modified example. FIG. 11 is a cross-sectional view schematically illustrating a schematic configuration of the main portions of the display device 400 according to the third modified example of the present embodiment. Note that, in FIG. 10, for convenience of illustration, illustration of the cathode 17 is omitted.

As understood from the example described above, the heating element layer 42 may be formed in the electron transport layer 16B adjacent to the QD layer 15B so as to be adjacent to the QD layer 15B with the insulating layer 43 interposed therebetween.

Further, in the present embodiment, a case in which the heating element layer 42 has a thin line shape is described as an example, but the shape of the heating element layer 42 is not limited thereto. For example, when the heating element layer 42 is provided on the side opposite to the light-output side of the QD layer 15B (specifically, a layer on the side opposite to the light-output face side of the QD layer 15B), the heating element layer 42 may be formed in a flat plate shape.

Further, at least one heat source (for example, the heating element layer 42) for heating the QD layer 15B need only be provided in one light-emitting device 41B.

FIGS. 10 and 11 illustrate, as an example, a case in which one heating element layer 42 is formed in the electron transport layer 16B adjacent to the QD layer 15B in each light-emitting device 41B so that the heating element layer 42 is adjacent to the QD layer 15B with the insulating layer 43 interposed therebetween. As illustrated in FIGS. 10 and 11, when the light-emitting device 41B is a BE-type light-emitting device that emits light downward from the QD layer 15 and the heating element layer 42 is provided above the QD layer 15B, the heating element layer 42 may have a flat plate shape. Note that, in this modified example as well, the heating element layer 42 may be disposed across the plurality of the PIXBs surrounded by the banks 18 disposed in a stripe pattern.

In a case in which the heating element layer 42 has a flat plate shape as described above, an area where the heating element layer 42 and the QD layer 15 face each other (in other words, overlap each other) is large compared to that in a case in which the heating element layer 42 has a thin line shape. This makes it possible to heat the QD layer 15B more efficiently.

On the other hand, in a case in which the heating element layer 42 has a thin line shape, when the heating element layer 42 is provided on the light-output face side of the QD layer 15B and light is output from the heating element layer 42 side, a reduction in the light-output efficiency caused by the heating element layer 42 can be suppressed.

### Other Modified Examples

As described above, the heat source (for example, the heating element layer 42) is preferably formed, for example, adjacent to the QD layer 15B or in a layer adjacent to the QD layer 15B. However, the position of the light source is not limited to the above-described position. The heat source need only be formed at a position where the QD layer 15B can be heated, such as between the hole transport layer 14B and the anode 12B, between the electron transport layer 16B and the cathode 17, between a lower electrode (anode 12 or cathode 17) and the substrate 11, or in the bank 18, for example. Accordingly, for example, an electric line connecting the TFT and the light-emitting device can also be used as a heat source. In particular, an electric line connecting the TFT and light-emitting device and having a width of 100 nm or less can be used as suitable heat source.

Further, the present embodiment illustrates, as an example, a case in which the heating element layer 42 is formed across, among the plurality of PIXs, the plurality of the PIXBs disposed in the column direction, but the present embodiment is not limited thereto. The heating element layer 42 may be formed in each PIXB, or may be formed across at least two of the PIXBs among the plurality of PIXs.

Further, the present embodiment illustrates, as an example, a case in which the blue QD layer heating process (light-emitting layer heating process) is performed after formation of the cathode 17 (in other words, immediately before completion of the light-emitting device 41). However, as described in the first embodiment, the blue QD layer heating process (light-emitting layer heating process) may be performed at any time as long as after the formation process of the QD layer 15B (step S10 (QD layer formation process (light-emitting layer formation process)).

### Third Embodiment

Another embodiment of the disclosure will be described below with reference to FIGS. 12 to 16. Note that differences from the first and the second embodiments will be described in the present embodiment. For convenience of description, members having the same functions as the members described in the first and second embodiments are designated by the same reference signs, and descriptions thereof are omitted.

FIG. 12 is a cross-sectional view schematically illustrating a schematic configuration of main portions of a display device 500 according to the present embodiment.

The display device 500 illustrated in FIG. 12 includes a light-emitting device 50. The light-emitting device 50 may be used as, for example, a display panel or a surface light source (illumination device) for the display device 500.

In the display device 500 (light-emitting device 50) illustrated in FIG. 12, a light-emitting device 51R is provided in the PIXR as a red light-emitting device. In the PIXG, a light-emitting device 51G is provided as a green light-emitting device. In the PIXB, a light-emitting device 51B is provided as the a blue light-emitting device.

In the present embodiment, heat sources for heating the QD layers 15B are formed in the banks 18.

As described above, the banks 18 are also used as edge covers that cover at least the edges of the lower electrode provided on the substrate 11 between the PIXs of different colors. Accordingly, in the following, description will be made assuming that the bank 18 is equally divided between the PIXs adjacent to each other, and that the light-emitting devices 51R, 51G, 51B each include a portion of the bank 18 (in other words, the bank 18 in each PIX) as an edge cover (bank).

Note that the present embodiment also describes, as an example, a case in which the lower electrode is the anode 12 and the upper electrode is the cathode 17. However, as in the first and second embodiments, the present embodiment is not limited thereto.

As illustrated in FIG. 12, the light-emitting device 51B has the same configuration as that of the light-emitting device 41B according to the second embodiment except that, as a heat source for heating the QD layer 15, a heating element layer 52 having a plate shape, for example, is provided in the bank 18 instead of the heating element layer 42. The heating element layer 52 is connected to a heating power supply similar to the heating power supply 44 via a wiring line similar to the connection wiring line 45. Further, the light-emitting device 51R has a configuration similar to that of the light-emitting device 41R according to the second embodiment. The light-emitting device 51G has a configuration similar to that of the light-emitting device 41G according to the second embodiment. The light-emitting device 51R has a configuration similar to that of the light-emitting device 1 according to the first embodiment. Therefore, the display device 500 illustrated in FIG. 12 has a configuration similar to that of the display device 400 illustrated in FIG. 3, for example, except that the heating element layer 52 for heating the QD layer 15B is provided in the bank 18 instead of the heating element layer 42.

Note that, for the heating element layer 52, a material similar to the material of the heating element layer 42 can be used.

The heating element layer 52 faces the QD layer 15B with a portion of the bank 18 (sidewall portion of the bank 18 covering the heating element layer 52) interposed therebetween. As illustrated in FIG. 12, the heating element layer 52 is formed, for example, at the same height from an upper face of the substrate 11 as a height of a lower face of the QD layer 15 (in other words, height of the upper face of the hole transport layer 14) and at the same thickness as the thickness of the QD layer 15 (specifically, the thickness of the QD layer 15B). In other words, with the upper face of the substrate 11 serving as a reference surface, for example, the heating element layer 52 is formed on a plane at the same height from the reference surface as the height of the lower face of the QD layer 15 so that the thickness of the heating element layer 52 in the layering direction of the light-emitting device 51B is equal to the thickness of the QD layer 15 in the layering direction of the light-emitting devices 51B. As a result, according to the present embodiment, only the QD layer 15B can locally be heated across the entire thickness direction thereof. Note that, although the upper face of the substrate 11 is used as the reference surface in the above description, the reference surface need only be plane that serves as a reference for height and is not limited to the upper face of the substrate 11.

In the present embodiment, the bank 18 functions as an insulating layer covering the heating element layer 52. A lower limit value of a covering thickness of the heating element layer 52 by the bank 18 is desirably the same as a lower limit value of the thickness t2 (covering thickness) of the insulating layer 43, that is, 5 nm. Thus, the heating element layer 52 can be insulated from the QD layer 15. Accordingly, a portion of the bank 18 interposed between the heating element layer 52 and the QD layer 15B (in other words, a distance between the heating element layer 52 and the QD layer 15B) is desirably 5 nm or greater.

Further, a thickness of the portion of the bank 18 interposed between the heating element layer 52 and the QD layer 15B is desirably the same as the upper limit value of the thickness t2 of the insulating layer 43, that is, 20 nm or less. This makes it possible to reduce the voltage value of the voltage applied to the heating power supply for heating the QD layer 15B and save energy.

Note that thicknesses of the portions of the bank 18 other than the portion interposed between the heating element layer 52 and the QD layer 15B are not particularly limited as long as the covering thickness of the heating element layer 52 by the bank 18 is 5 nm or greater as described above.

However, in the example illustrated in FIG. 12, as described above, the heating element layer 52 is formed at the same height from the upper face of the substrate 11 as the height of the lower face of the QD layer 15 and at the same thickness as the thickness of the QD layer 15. Accordingly, a thickness of the portion of the bank 18 between the upper face of the substrate 11 and the lower face of the heating element layer 52 is the same as a distance between the upper face of the substrate 11 and the QD layer 15B. Further, a thickness of the portion of the bank 18 between the upper face of the heating element layer 52 and the cathode 17 is the same as a distance between the upper face of the QD layer 15B and the cathode 17.

Further, in the present embodiment, the heating element layer 52 is provided only in the light-emitting device 51B. The heating element layer 52 is therefore formed with the heating element layer 52 being positioned closer to the QD layer 15B than a center of the bank 18 in the short-hand direction in plan view, and with the portion of the bank 18 interposed between the heating element layer 52 and the QD layer 15B desirably 5 nm or greater. A width of the heating element layer 52 in plan view (that is, width of the upper face and the lower face) need only be set so that the conditions described above are satisfied.

### Method for Manufacturing Display Device 500

Next, an example of a method for manufacturing the display device 500 (light-emitting device 50) according to the present embodiment will be described with reference to FIGS. 12 to 14.

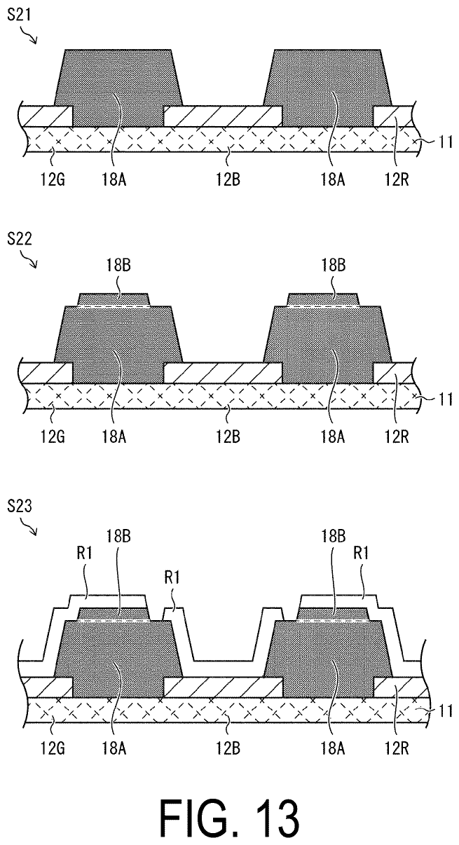

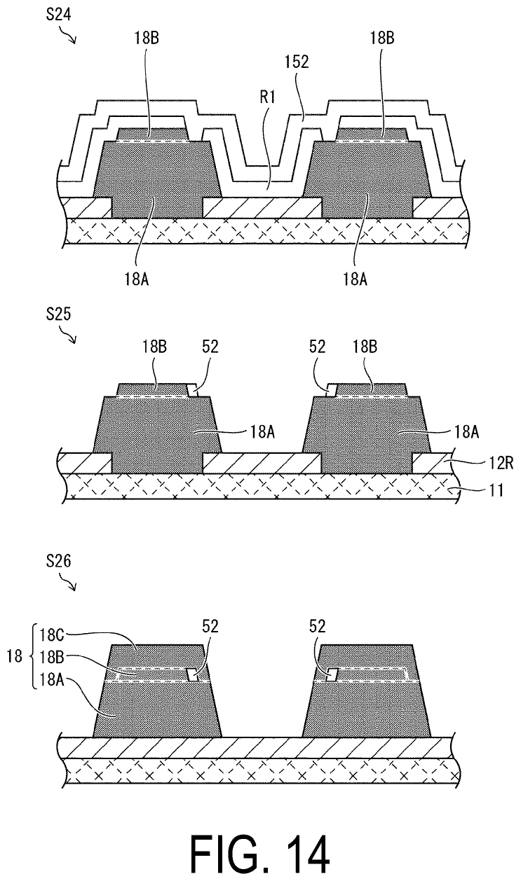

FIG. 13 is a cross-sectional view illustrating, in process order, a method for manufacturing the main portions of the display device 500 (light-emitting device 50) according to the present embodiment. FIG. 14 is another cross-sectional view illustrating, in process order, the method for manufacturing the main portions of the display device 500 (light-emitting device 50) according to the present embodiment. Note that FIG. 14 illustrates processes after the processes illustrated in FIG. 13.

In the present embodiment, first, the step S1 (substrate formation process) and the step S2 (anode formation process) are performed as in the second embodiment.

Next, as indicated by S21 in FIG. 13, a first bank portion 18A thinner than the bank 18 is patterned on the substrate 11 (step S21, first bank portion formation process). In other words, in step S21, the first bank portion 18A is patterned on the substrate 11 so that a height from the upper face of the substrate 11 to an upper face of the first bank portion 18A is lower than a height from the upper face of the substrate 11 to an upper face of the bank 18.

The first bank portion 18A serves as a support body that supports a lower face of the heating element layer 52. The first bank portion 18A includes a portion corresponding to a portion between the upper face of the substrate 11 and the lower face of the heating element layer 52, and a portion of the upper face of the first bank portion 18A corresponds to an interface with the lower face of the heating element layer 52. Therefore, when the display device 500 (light-emitting device 50) illustrated in FIG. 12 is manufactured, the first bank portion 18A is designed to have the same thickness as the designed height from the upper face of the substrate 11 to the upper face of the hole transport layer 14 (that is, the height to the upper face of the hole transport layer 14 formed in the subsequent step S4). Further, at this time, the first bank portion 18A is patterned so as to cover the edges of the anodes 12R, 12G, 12B between the PIXs of different colors.

Next, as indicated by S22 in FIG. 13, a second bank portion 18B smaller than the first bank portion 18A is patterned on the first bank portion 18A as an upper layer bank with the first bank portion 18A as a lower layer bank (step S22, second bank portion formation process). Note that, here, the second bank portion 18B being smaller than the first bank portion 18A means that the second bank portion 18B has a lower face that is smaller than the upper face of the first bank portion 18A.

As described above, the heating element layer 52 is, for example, formed at the same height from the upper face of the substrate 11 as the height of the lower face of the QD layer 15 (in other words, the height of the upper face of the hole transport layer 14) and at the same thickness as the thickness t1 of the QD layer 15. The second bank portion 18B serves as a support body that supports a side surface of the heating element layer 52. The heating element layer 52 is formed along a side surface of the second bank portion 18B, and the side surface of the heating element layer 52 serves as an interface with the side surface of the second bank portion 18B. Therefore, when the display device 500 (light-emitting device 50) illustrated in FIG. 12 is manufactured, the second bank portion 18B is formed to the same thickness as the thickness t1 of the QD layer 15.

Note that, for the formation of the first bank portion 18A and the second bank portion 18B, various methods known in the related art as methods for forming a bank, such as photolithography, may be used.

Further, the example in FIG. 13 illustrates, as an example, a case in which the first bank portion 18A is formed and then the second bank portion 18A is formed on the first bank portion 18B, but the formation method of the first bank portion 18A and the second bank portion 18B is not limited thereto. For example, a two-stage bank in which the second bank portion 18B is formed on the first bank portion 18A may be formed by forming an insulating film having a thickness from the upper face of the substrate 11 to an upper face of the second bank portion 18B and double-exposing the insulating film using a mask.

Next, as indicated in S23 in FIG. 13, a mask R1 made of a photoresist and open at a formation region of the heating element layer 52 is formed on the first bank portion 18A and the second bank portion 18B described above by photolithography or the like (step S23, mask formation process). Specifically, a photoresist is applied onto the first bank portion 18A and the second bank portion 18B, and this photoresist is exposed and developed using a photomask to form the mask R1 made of the photoresist and open at the formation region of the heating element layer 52.

Next, as indicated in S24 in FIG. 14, the material of the heating element layer 52 is vapor-deposited on the mask R1 (step S24, vapor deposition step).

Next, as indicated in S25 in FIG. 14, the mask R1 is lifted off to pattern the heating element layer 52 thereon (step S25, heating element layer formation process (heat source formation process)). As a result, the heating element layer 42 having the same height from the upper face of the substrate 11 as the height of the lower face of the QD layer 15 (in other words, the height of the upper face of the hole transport layer 14) and the same thickness as the thickness of the QD layer 15.

Next, as indicated in S26 in FIG. 14, a third bank portion 18C is patterned as a covering layer on the first bank portion 18A by photolithography or the like, covering the second bank portion 18B and the heating element layer 52 (step S26, third bank portion formation process). As a result, the bank 18 of a normal size, composed of the first bank portion 18A, the second bank portion 18B, and the third bank portion 18C, and with the heating element layer 52 formed therein is formed. Note that, the bank 18 of a normal size means that the bank 18 has a thickness from the upper face of the substrate 11 to the lower face of the cathode 17 (in other words, the upper face of the QD layer 15) as illustrated in FIG. 12.

Note that the first bank portion 18A, the second bank portion 18B, and the third bank portion 18C may be formed of the same insulating material, or may be formed of insulating materials different from one other. Further, any two of the first bank portion 18A, the second bank portion 18B, and the third bank portion 18C may be formed of the same insulating material, and the remaining one may be formed of an insulating material different from that of the other two. As the insulating material used for the first bank portion 18A, the second bank portion 18B, and the third bank portion 18C, an insulating material similar to the insulating material exemplified as the insulating material used for the bank 18 in the second embodiment can be used.

Subsequently, the step S4 (hole injection layer formation process), the step S5′ (hole transport layer formation process), the step S10 (QD layer formation process (light-emitting layer formation process)), the step S11 (electron transport layer formation process), and the step S12 (cathode formation process) are performed in this order. These steps S4, S5′, and S10 to S12 are as described in the second embodiment. In the present embodiment, the thickness of each layer of the light-emitting device 51B described above is set so that, with the upper face of the substrate 11 serving as the reference surface, the height from the reference surface to the lower face of the heating element layer 52 is the same as the height from the reference surface to the lower face of the QD layer 15B, and the height from the reference surface to the upper face of the heating element layer 52 is the same as the height from the reference surface to the upper face of the QD layer 15B.

Note that, in the present embodiment as well, after formation of the cathode 17, the substrate 11 and the layered body (the anode 12 to the cathode 17) formed on the substrate 11 may be sealed with a sealing member in an N₂ atmosphere.

The light-emitting devices 51R, 51G are formed by the above-described processes. Further, after each of the above-described processes, electrical connection is made with the heating power supply via the connection wiring line, and the QD layer 15B is heated at a temperature from 80° C. to 100° C. for 30 minutes to 600 minutes (blue QD layer heating process (light-emitting layer heating process)). In this way, the light-emitting device 51B is formed.

Next, an electronic circuit board (not illustrated) such as an integrated circuit (IC) chip and a flexible printed circuit board (FPC) is mounted onto a portion (terminal portion) outward of a display region in which the plurality of PIXs are formed (non-display region, frame). Thus, the display device 500 including the light-emitting device 50 with the light-emitting devices 51R, 51G, 51B formed therein is formed. Note that, in the present embodiment as well, each of the above-described processes is performed by a display device manufacturing apparatus.

Further, the present embodiment also illustrates, as an example, a case in which the blue QD layer heating process (light-emitting layer heating process) is performed after the cathode 17 is formed (in other words, immediately before completion of the light-emitting device 51B). However, as in the second embodiment, the blue QD layer heating process (light-emitting layer heating process) may be performed at any time after the formation process of the QD layer 15B (step S10 (QD layer formation process (light-emitting layer formation process)).

In the present embodiment as well, as described above, by heating the QD layer 15B, the light-emitting device 51B having a high fluorescence quantum efficiency and a fluorescence lifetime (τ) in the QD layer 15B of 50 ns or less, and the light-emitting device 50 and the display device 500 including the light-emitting device 51B can be manufactured. At this time, as described above, the QD layer 15B is heated at a temperature from 80° C. to 100° C. for 30 minutes to 600 minutes to relatively increase the fluorescence lifetime (τ) of the QD layer 15B by 10% or more from the value before heating. This heating can then improve the fluorescence quantum efficiency of the QD layer 15B.

Further, the light-emitting device 51B includes the heating element layer 52 as a heat source as described above and thus, even when the luminance of the light-emitting device 51B is irreversibly reduced due to deterioration of the QD layer 15B, the peripheral layers thereof (electron transport layer, hole transport layer, electrodes, and the like), or the like due to environmental changes, the passage of time, or the like, the fluorescence quantum efficiency of the QD layer 15B can be improved by heating the QD layer 15B. Therefore, the lowered luminance of the light-emitting device 51B can be improved (for example, restored).

### First Modified Example

Note that, the present embodiment, as in the second embodiment, illustrates, as an example, a case in which a non-Cd-based material is used for the red QDs and the green QDs. Non-Cd-based QDs are relatively not thermally stable. Therefore, when the QDs 25 described in the first embodiment are used for the blue QDs and the non-Cd-based QDs are used for the QD layers 15R, 15G of the red light-emitting device and the green light-emitting device according to the disclosure, a heat source of a minute region capable of heating the QD layer 15B only is required. In this case, fine temperature control can be performed for each light-emitting device, and thus the luminance can be more finely improved.

However, Cd-based QDs are thermally stable. Therefore, when the QDs 25 described in the first embodiment are used for the blue QDs and the Cd-based QDs are used for the QD layers 15R, 15G of the red light-emitting device and the green light-emitting device according to the disclosure, the heat source for heating the QD layer 15B may be a heat source that simultaneously heats the QD layers 15R, 15G as well. In this case, it is not necessary to form a heat source for each blue light-emitting device, making it easy to manufacture the heat source and thus possible to reduce the manufacturing cost.

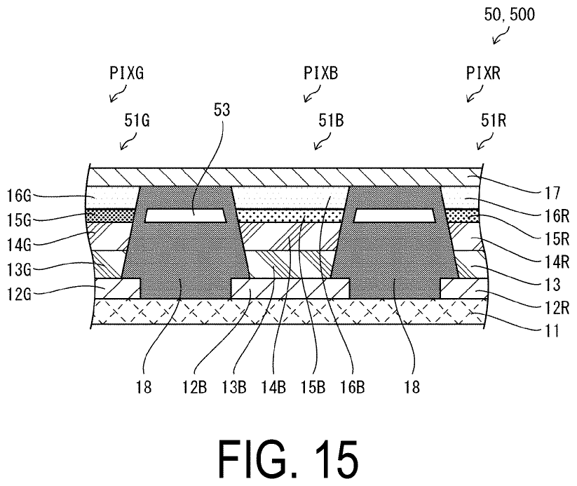

FIG. 15 is a cross-sectional view schematically illustrating a schematic configuration of main portions of the display device 500 according to this modified example.

The display device 500 illustrated in FIG. 15 has, for example, the same configuration as that of the display device 500 illustrated in FIG. 12, except that a heating element layer 53 for simultaneously heating the QD layers 15R, 15G, and 15B is provided in the bank 18 instead of the heating element layer 52. Therefore, the light-emitting device 51B according to this modified example has a configuration similar to that of the light-emitting device 51B illustrated in FIG. 12 except that the heating element layer 53 having a block shape, for example, is provided in the bank 18 as a heat source for heating the QD layer 15 instead of the heating element layer 52.

As illustrated in FIG. 15, the heating element layer 53 provided in the bank 18 formed at a boundary portion between the PIXG and the PIXB is provided in common to the PIXG and the PIXB. Further, the heating element layer 53 provided in the bank 18 formed at the boundary portion between the PIXB and the PIXR is provided in common to the PIXB and the PIXR. Therefore, the light-emitting device 51R according to this modified example has a configuration similar to that of the light-emitting device 51R illustrated in FIG. 12 except that the heating element layer 53 having a block shape, for example, is provided in the bank 18 as a heat source for heating the QD layer 15. The light-emitting device 51G according to this modified example has a configuration similar to that of the light-emitting device 51G illustrated in FIG. 12 except that the heating element layer 53 having a block shape, for example, is provided in the bank 18 as a heat source for heating the QD layer 15.

Note that, for the heating element layer 53, a material similar to the material of the heating element layers 42, 52 can be used.

The heating element layer 53 faces each of the QD layers 15 with a portion of the bank 18 (sidewall portion of the bank 18 covering the heating element layer 53) interposed therebetween. The heating element layer 53, as in the heating element layer 52, is, for example, formed at the same height from the upper face of the substrate 11 as the height of the lower face of the QD layer 15 (in other words, the height of the upper face of the hole transport layer 14) and at the same thickness as the thickness of the QD layer 15. As a result, according to the present embodiment, only the QD layer 15 can locally be heated across the entire thickness direction thereof.

In this modified example, the bank 18 functions as an insulating layer covering the heating element layer 53. A lower limit value of a covering thickness of the heating element layer 53 by the bank 18 is desirably the same as the lower limit value of the thickness t2 (covering thickness) of the insulating layer 43, that is, 5 nm. Thus, the heating element layer 53 can be insulated from the QD layer 15. Accordingly, a thickness of the portion of the bank 18 interposed between the heating element layer 53 and each QD layer 15 (in other words, a distance between the heating element layer 53 and each QD layer 15) is desirably 5 nm or greater.

Further, the thickness of the portion of the bank 18 interposed between the heating element layer 53 and each QD layer 15 is desirably the same as the upper limit value of the thickness t2 of the insulating layer 43, that is, 20 nm or less. This makes it possible to reduce the voltage value of the voltage applied to the heating power supply for heating each QD layer 15 and thus save energy.

Note that, in this modified example as well, thicknesses of portions of the bank 18 other than the portion interposed between the heating element layer 53 and each QD layer 15 are not particularly limited as long as the covering thickness of the heating element layer 53 by the bank 18 is 5 nm or greater as described above.

However, in this modified example as well, as described above, the heating element layer 53 is formed at the same height from the upper face of the substrate 11 as the height of the lower face of the QD layer 15 and at the same thickness as the thickness of the QD layer 15. Accordingly, a thickness of the portion of the bank 18 between the upper face of the substrate 11 and a lower face of the heating element layer 53 is the same as a distance between the upper face of the substrate 11 and each QD layer 15. Further, a thickness of a portion of the bank 18 between an upper face of the heating element layer 53 and the cathode 17 is the same as a distance between the upper face of each QD layer 15 and the cathode 17.

### Method for Manufacturing Display Device 500 According to Modified Example

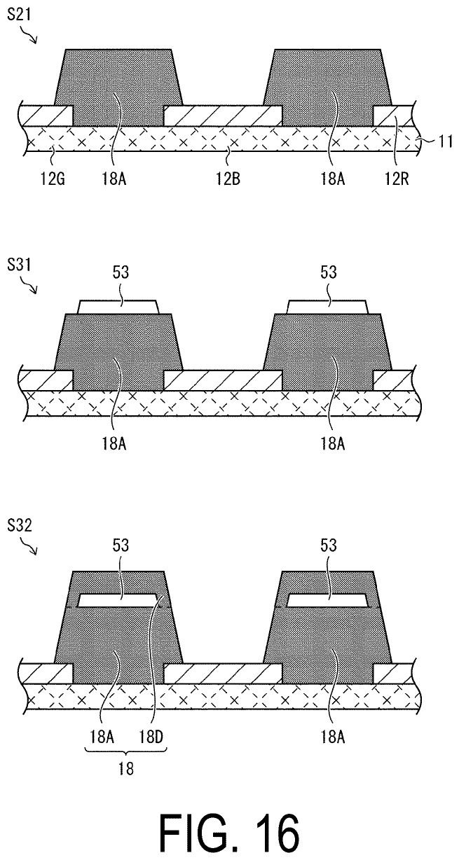

Next, an example of a method for manufacturing the display device 500 (light-emitting device 50) according to this modified example will be described with reference to FIGS. 15 to 16.

FIG. 16 is a cross-sectional view illustrating, in process order, a method for manufacturing the main portions of the display device 500 (light-emitting device 50) according to the present embodiment.

First, steps S1 and S2 are performed as in the first and second embodiments. Next, as indicated in S21 in FIG. 16, step S21 (first bank portion formation process) is performed as in the second embodiment.

The first bank portion 18A serves as a support body that supports the lower face of the heating element layer 53. The first bank portion 18A includes a portion between the upper face of the substrate 11 and the lower face of the heating element layer 53, and a portion of the upper face of the first bank portion 18A serves as an interface with the lower face of the heating element layer 53. Therefore, when the display device 500 (light-emitting device 50) illustrated in FIG. 15 is manufactured, the thickness of the first bank portion 18A is designed to be the same as the designed height from the upper face of the substrate 11 to the upper face of the hole transport layer 14 (that is, the height to the upper face of the hole transport layer 14 formed in the subsequent step S4). At this time, in this modified example as well, the first bank portion 18A is patterned so as to cover the edges of the anodes 12R, 12G, 12B between the PIXs of different colors.

Next, as indicated by S31 in FIG. 16, the heating element layer 53 having a block shape and the same thickness as the thickness of the QD layer 15 is patterned on the first bank portion 18A by photolithography or the like (step S31, heating element layer formation process (heat source formation process)).

Next, as indicated by S32 in FIG. 16, a second bank portion 18D is patterned as a covering layer on the first bank portion 18A so as to cover the heating element layer 53 by photolithography or the like (step S32, second bank portion formation process). As a result, the bank 18 having the normal size described above, composed of the first bank portion 18A and the second bank portion 18D, and with the heating element layer 53 formed therein is formed.

Note that the first bank portion 18A and the second bank portion 18D may be formed of the same insulating material, or may be formed of insulating materials different from each other. As the insulating material used for the first bank portion 18A and the second bank portion 18D, an insulating material similar to the insulating material exemplified as the insulating material for the bank 18 in the second embodiment can be used.

Subsequently, in this modified example as well, step S4 and subsequent processes described above in the third embodiment are performed, making it possible to manufacture the light-emitting device 51B, and the light-emitting device 50 and the display device 500 including the light-emitting device 51B, according to this modified example illustrated in FIG. 15.

### Second Modified Example

The present embodiment illustrates, as an example, a case in which the heating element layer (for example, the heating element layer 52, the heating element layer 53) serving as a heat source faces only the QD layer 15 in the horizontal direction (planar direction) with a portion of the bank 18 interposed therebetween so as to locally heat the QD layer 15. However, the heat source need only be formed at a position where at least the QD layer 15B can be heated. Accordingly, the heat source need only be formed in the bank 18 and facing at least the QD layer 15.

Therefore, the heat source (for example, the heating element layer 52, the heating element layer 53) may be formed facing a plurality of layers including the QD layer 15 with a portion of the bank 18 interposed therebetween, and may be formed facing, for example, the QD layer 15B and at least one of layers vertically adjacent to the QD layer 15B. Further, the heat source may be formed facing even more layers including the QD layer 15B.

Note that the thickness, the width, and the height from the upper face of the substrate 11 to the lower face of the heating element layer 52 of the heating element layer 52 can be changed by, for example, changing the sizes (heights) and the widths in plan view of the first bank portion 18A and the second bank portion 18B. Further, the height from the upper face of the substrate 11 to the lower face of the heating element layer 53 can be changed, for example, by changing the size of the first bank portion 18A.

### Fourth Embodiment

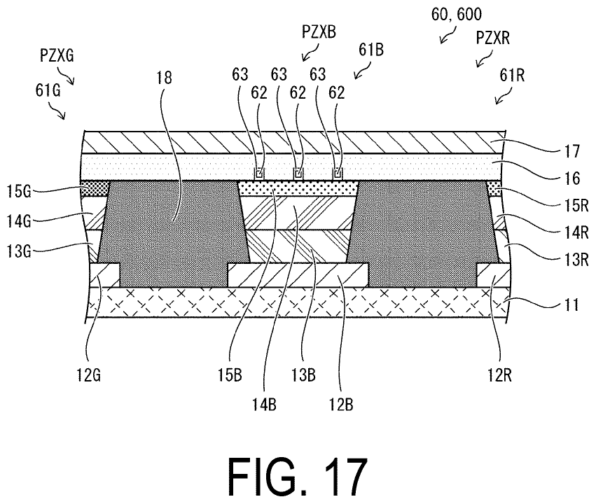

Another embodiment of the disclosure will be described below with reference to FIGS. 17 to 19. Note that differences from the first embodiment to the third embodiment will be described in the present embodiment. For convenience of description, members having the same functions as the members described in the first to third embodiments are designated by the same reference signs, and descriptions thereof are omitted.

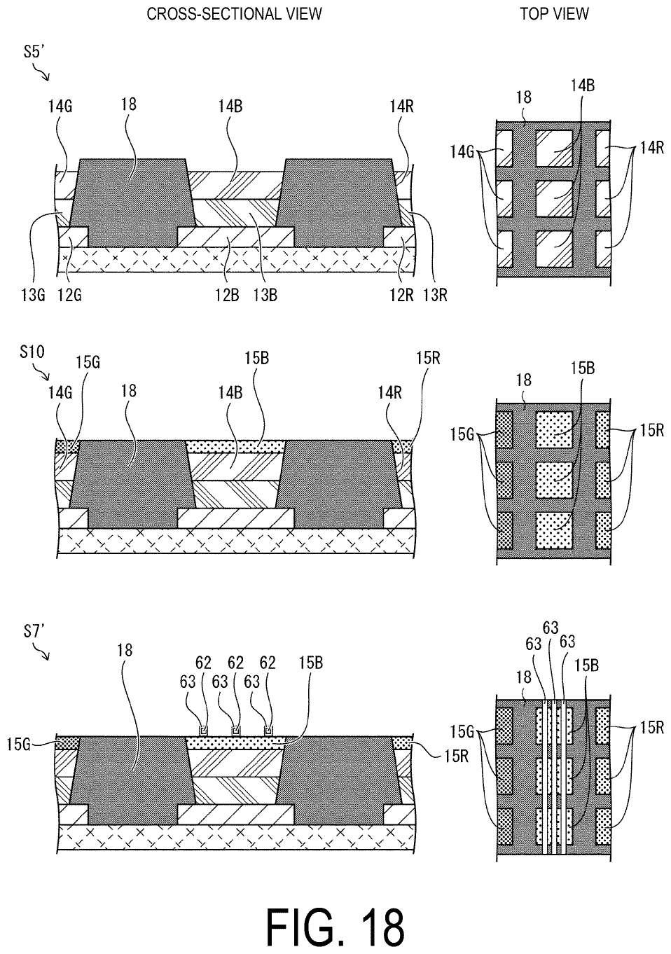

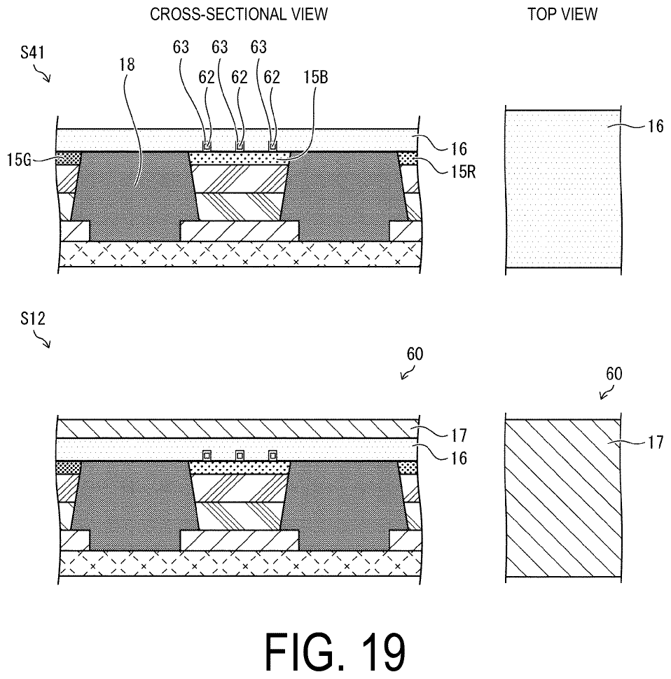

FIG. 17 is a cross-sectional view schematically illustrating a schematic configuration of main portions of a display device 600 according to the present embodiment. FIG. 18 is a diagram illustrating, in a cross-sectional view and a top view and in process order, a method for manufacturing the main portions of the display device 600 (light-emitting device 60) according to the present embodiment. FIG. 19 is another diagram illustrating, in a cross-sectional view and a top view and in process order, a method for manufacturing the main portions of the display device 600 (light-emitting device 60) according to the present embodiment. Note that FIG. 19 illustrates processes after the processes illustrated in FIG. 18.

The display device 600 illustrated in FIG. 17 includes the light-emitting device 60. The light-emitting device 60 may be used as, for example, a display panel or a surface light source (illumination device) for the display device 600.

In the display device 600 (light-emitting device 60) illustrated in FIG. 17, the light-emitting device 61R is provided in the PIXR as a red light-emitting device. In the PIXG, the light-emitting device 61G is provided as a green light-emitting device. In the PIXB, the light-emitting device 61B is provided as a blue light-emitting device.

In the present embodiment, as illustrated in FIGS. 18 and 19, the bank 18 partitions all of the PIXs regardless of the luminescent color. Therefore, the bank 18 according to the present embodiment covers each peripheral end of each lower electrode (all edges between PIXs).

Further, in the present embodiment, as illustrated in FIG. 17, the lower electrode, the QD layer 15, and the layers between the lower electrode and the QD layer 15 are separated for each PIX by the bank 18, but the upper electrode and the layers between the upper electrode and the QD layer 15 are not separated by the bank 18. An upper face of the bank 18 is flush with the upper face of the QD layer 15, and an upper electrode and layers between the upper electrode and the QD layer 15 are provided in common to each PIX (all PIXs), covering the bank 18 as a common electrode and a common layer.

In FIG. 17, description is made using, as an example, a case in which the anode 12, the hole injection layer 13, the hole transport layer 14, the QD layer 15, the electron transport layer 16, and the cathode 17 are layered in this order on the substrate 11.

Therefore, in the display device 600 illustrated in FIG. 17, the anode 12, the hole injection layer 13, the hole transport layer 14, and the QD layer 15 are separated (spaced apart) for each PIX by the bank 18, and the electron transport layer 16 and the cathode 17 are provided in common to each PIX.

In addition, in the display device 600 illustrated in FIG. 17, as a heating source for heating the QD layer 15, a heating element layer 62 having a thin line shape is provided in the electron transport layer 16 adjacent to the QD layer 15B.

Note that, a heat source for heating the QD layer 15 may be provided in the electron transport layer (for example, in the electron transport layer 16B) adjacent to the QD layer 15B as described in the second embodiment. However, in the second embodiment, the heating element layer 42 having a thin line shape is disposed between and in parallel with the banks 18 adjacent to each other in a stripe pattern, and across the plurality of the PIXBs positioned between these banks 18.

In the present embodiment, as described above, the upper face of the bank 18 is formed flush with the upper face of the QD layer 15, and the QD layer 15 is separated for each PIX by the bank 18, while the electron transport layer 16 is formed in common to all the PIXs so as to cover the bank 18.

Therefore, in the present embodiment, the heating element layer 62 having a thin line shape extends across the bank 18 including an upper face flush with the upper face of the QD layer 15 and intersecting the PIXB column, and adjacent to the QD layer 15, extending across the plurality of PIXBs.

In the light-emitting device 61B, as described above, the bank 18 partitions all the PIXs from each other, the upper face of the bank 18 is formed flush with the upper face of the QD layer 15, and the heating element layer 62 is provided instead of the heating element layer 42 as a heat source for heating the QD layer 15. As illustrated in FIG. 17, the heating element layer 62 is covered with an insulating layer 63. A lower face of the insulating layer 63 illustrated in FIG. 17 is flush with a lower face of the electron transport layer 16, and an upper face of the insulating layer 63 is adjacent to (that is, in contact with) the QD layer 15B. The heating element layer 62 is adjacent to the QD layer 15B with the insulating layer 63 interposed therebetween. The light-emitting device 61B has a configuration similar to that of the light-emitting device 41B according to the second embodiment except for this point. Further, the light-emitting device 61R and the light-emitting device 61G have the same configurations as those of the light-emitting device 41R and the light-emitting device 41G according to the second embodiment, respectively, except that the bank 18 partitions all the PIXs, and the upper face of the bank 18 is formed flush with the upper face of the QD layer 15. Accordingly, the display device 600 illustrated in FIG. 17 has a configuration similar to that of the display device 400 illustrated in FIG. 3, for example, except for the points described above.

Note that, in the present embodiment as well, a line width of the heating element layer 62 is desirably set within the same range as the line width d1 of the heating element layer 42 described above. Further, a thickness of the heating element layer 62 is desirably set within the same range as the thickness t1 of the heating element layer 42 described above. Therefore, a cross-sectional area of a plane parallel to the line width direction of the heating element layer 62 is desirably set within the same range as the cross-sectional area of the plane parallel to the line width direction of the heating element layer 42. Further, desirably, an arrangement pitch of the heating element layers 62 (wiring line pitch, in other words, pitch between adjacent heating element layers 62) is set within the same range as the arrangement pitch p1 of the heating element layers 42 described above. This makes it possible to efficiently heat the QD layer 15B to a temperature necessary for obtaining the advantageous effects described above in the line width direction, and suppress a reduction in the light output efficiency caused by the heating element layer 62. Therefore, in the following, the line width, the thickness, and the arrangement pitch of the heating element layer 62 are indicated by d1, t1, and p1, respectively, similarly to the line width, the thickness, and the arrangement pitch of the heating element layer 42.

Further, desirably, a thickness (covering thickness) of the insulating layer 63 covering the heating element layer 62 is set within the same range as the thickness (covering thickness) t2 of the insulating layer 43 covering the heating element layer 42. Therefore, in the following, the thickness (covering thickness) of the insulating layer 63 is indicated by t2 similarly to the thickness (covering thickness) of the insulating layer 43.

A material of the heating element layer 62 need only be any material that can be used as a heat source, and any material that can be generally used as a wiring line can be used. As the material of the heating element layer 62, for example, a material similar to the material of the heating element layer 42 described above can be used. Among them, as the material of the heating element layer 62, Al is particularly preferable for the same reason as that for the heating element layer 42.

Further, as the insulating material used for the insulating layer 63, the same material as the material of the insulating layer 43 described above can be used.

Next, an example of a method for manufacturing the display device 600 (light-emitting device 60) according to the present embodiment will be described with reference to FIGS. 17 to 19.

In the present embodiment, first, step Si (substrate formation process) and step S2 (anode formation process) are performed as in the second embodiment.

Next, the step S3 (bank formation process) is performed as in the second embodiment. However, at this time, in the present embodiment, as illustrated in FIG. 17, the thickness of the bank 18 is designed to be the same as the designed height from the upper face of the substrate 11 to the upper face of the QD layer 15 (that is, the height to the upper face of the QD layer 15 formed in the subsequent step S10). Note that the line width (bank width) of the bank 18 in plan view is, for example, within a range from 1 to 1.5 μm. In the present embodiment, for the bank 18, polyimide is used as an example. However, the present embodiment is not limited to this example.

Next, the step S4 (hole injection layer formation process) is performed as in the second embodiment. Next, as indicated by S5′ in FIG. 18, the step S5′ (hole transport layer formation process) is performed as in the second embodiment. Next, as indicated by S10 in FIG. 18, the step S10 (QD layer formation process (light-emitting layer formation process)) is performed as in the second embodiment.

As indicated by S10 in FIG. 18, in the present embodiment, the QD layers 15R, 15G, 15B are separated by the bank 18.

Next, as indicated by S7′ in FIG. 18, the heating element layer 62 having a thin line shape as the heat source wiring line covered with the insulating layer 63 is patterned on the QD layer 15B (step S7′, heating element layer formation process (heat source formation process)).

The insulating layer 63 and the heating element layer 62 can be formed by a method similar to the formation method of the insulating layer 43 and the formation method of the heating element layer 42 in the first embodiment. Specifically, first, as in the first insulating layer formation process of step S6 in the first embodiment, a first insulating layer on the lower layer side of the heating element layer 62, which is a portion of the insulating layer 63, is patterned on the QD layer 15B by photolithography or the like. Thus, a first insulating layer similar to the first insulating layer 431 illustrated in FIGS. 6 and 7 is formed as a portion of the insulating layer 63. Next, as in the heating element layer formation process of step S7 in the first embodiment, the heating element layer 62 having a thin line shape and serving as a heat source wiring line is patterned on the first insulating layer by photolithography or the like. Note that the heating element layer 62 may be formed by sputtering using a metal mask, for example, instead of pattern formation by photolithography or the like. Next, as in the second insulating layer formation process of step S8 in the first embodiment, a second insulating layer that covers a side surface and an upper face of the insulating layer 63 is patterned on the QD layer 15B by photolithography or the like, covering the heating element layer 62. At this time, to form the second insulating layer, a method similar to the formation method of the first insulating layer may be used. Thus, a second insulating layer similar to the second insulating layer 432 illustrated in FIG. 7 is formed as a portion of the insulating layer 63. In this way, the heating element layer 62 and the insulating layer 63 made of the first insulating layer and the second insulating layer and covering the heating element layer 62 are formed.

In the present embodiment, as the heating element layer 62, an Al wiring line having the line width d1 of 50 nm and the thickness t1 of 50 nm was formed. The arrangement pitch p1 was 1 μm. Further, the insulating layer 63 was formed of silicon oxide (SiO₂), and the thickness t2 of the insulating layer 63 was 10 nm.

Next, as indicated by S41 in FIG. 19, the electron transport layer 16 made of an electron transport material is formed on the QD layers 15R, 15G, 15B and the bank 18 as a common layer common to the PIXs and thus covers the heating element layer 62 covered with the insulating layer 63 (step S41, electron transport layer formation process).

Note that the electron transport layer 16 may be formed by using various known methods for forming an electron transport layer. For example, instead of a fine mask in which an opening is formed for each PIX, an open mask in which the entire pixel region (display region) provided with the plurality of PIXs is open may be used as a mask for formation as with the electron transport layers 16R, 16G, 16B.

Next, as indicated by S12 in FIG. 19, the step S12 (cathode formation process) is performed as in the second embodiment. However, in the present embodiment, as described above, the electron transport layer 16 is formed on the QD layers 15R, 15G, 15B and the banks 18. Therefore, in the present embodiment, the cathode 17 is formed on the electron transport layer 16 which is the common layer.

Note that the processes after formation of the cathode 17 are the same as those in the second and third embodiments. After the cathode 17 is formed, the display device 600 including the light-emitting device 60 in which the light-emitting devices 61R, 61G, 61B are formed is formed by performing processing similar to that in the second and third embodiments. Note that, in the present embodiment as well, each of the above-described processes is performed by a display device manufacturing apparatus.

In the present embodiment as well, as in the second and third embodiments, by heating the QD layer 15B, the light-emitting device 61B having a high fluorescence quantum efficiency and a fluorescence lifetime (τ) in the QD layer 15B of 50 ns or less, and the light-emitting device 60 and the display device 600 including the light-emitting device 61B can be manufactured. At this time, as described above, the QD layer 15B is heated at a temperature from 80° C. to 100° C. for 30 minutes to 600 minutes to relatively increase the fluorescence lifetime (τ) of the QD layer 15B by 10% or more from the value before heating. This heating can then improve the fluorescence quantum efficiency of the light-emitting device 61B.

Further, the light-emitting device 61B includes the heating element layer 62 as a heat source as described above and thus, even when the luminance of the light-emitting device 61B is irreversibly reduced due to deterioration of the QD layer 15B, the peripheral layers thereof (electron transport layer, hole transport layer, electrodes, and the like), or the like due to environmental changes, the passage of time, or the like, the fluorescence quantum efficiency of the light-emitting device 61B can be improved by heating the QD layer 15B. Therefore, the lowered luminance of the light-emitting device 61B can be improved (for example, restored).

For example, when the heating element layer 42 having a thin line shape is formed between the banks 18 adjacent to each other as in the second embodiment and the mask for forming the heating element layer 42 having a thin line shape is displaced, the heating element layer 42 having a thin line shape may be formed on sidewalls of the banks 18. When the heat source having a thin line shape is thus formed on the sidewall of the bank 18, the heat source may not be properly formed in a thin line shape, resulting in problems such as an insufficient heating performance.

However, as described above, by forming the heating element layer 62 having a thin line shape as described above in an upper layer above the bank 18, the heating element layer 62 is never formed on the sidewall of the bank 18. Further, because the upper face of the bank 18 and the upper face of the QD layer 15B are flush and there is no step on the formation surface of the heating element layer 62, the problem of the heating element layer 62 not being properly formed in a thin line shape does not occur even if the mask is displaced. This makes it possible to prevent the heating performance of the heat source from becoming insufficient.

### First Modified Example

As described above, the present embodiment illustrates, as an example, a case in which the PIXs of the same color each have a stripe array of being arranged in a straight line in the column direction, and the heating element layer 62 is disposed across the plurality of PIXBs extending across the bank 18 intersecting the PIXB column. However, the present embodiment is not limited thereto. When the Cd-based QDs are used for the QD layers 15R, 15G of the light-emitting devices 61R, 61G, the heat source for heating the QD layer 15B may be a heat source for simultaneously heating the QD layers 15R, 15G. Therefore, in this case, the heating element layer 62 may be formed across the bank 18 partitioning the PIXs having different luminescent colors, and the display device 600 (light-emitting device 60) may have a pixel arrangement such as an S-Stripe array or a PenTile array, for example. In this case as well, the bank 18 is covered with the electron transport layer 16, and the heating element layer 62 is formed in the electron transport layer 16, extending across the upper face of the bank 18, and thus advantageous effects similar to the advantageous effects described above can be achieved.

### Second Modified Example

Further, the example illustrated in FIG. 17 illustrates, as an example, a case in which the heating element layer 62 is formed in the electron transport layer 16. However, the present embodiment is not limited to this example. For example, in a case in which the cathode 17, the electron transport layer 16, the QD layer 15, the hole transport layer 14, and the anode 12 are formed in this order on the substrate 11, the upper face of the bank 18 and the upper face of the QD layer 15B may be flush, and the heating element layer 62 may be formed in the hole transport layer 14. Also in this case, similar advantageous effects to those described above can be obtained.

### Third Modified Example

Further, the present embodiment illustrates, as an example a case in which the heating element layer 62 having a thin line shape is formed as the heat source. However, the present embodiment is not limited to this example. In the present embodiment as well, when the heating element layer 62 is provided on the side opposite to the light-output side of the QD layer 15B (specifically, a layer on the side opposite to the light-output face side of the QD layer 15B), the heating element layer 62 may be formed in a flat plate shape.

### Fifth Embodiment

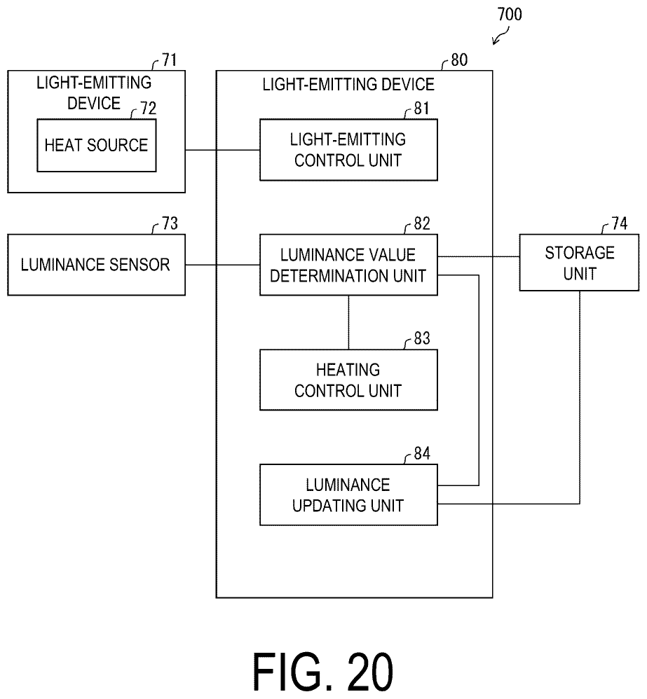

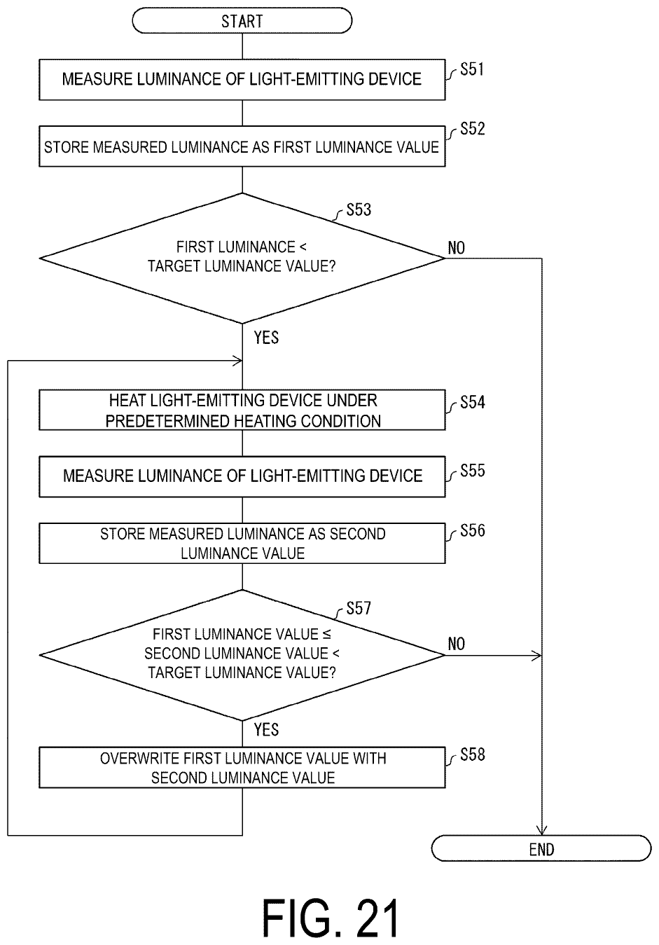

Another embodiment of the disclosure will be described below with reference to FIGS. 20 and 21. Note that differences from the first to the fourth embodiments will be described in the present embodiment. For convenience of description, members having the same functions as the members described in the first to fourth embodiments are designated by the same reference signs, and descriptions thereof are omitted.

The display device according to the present embodiment is provided with the light-emitting device including the heat source described in any one of the second to fourth embodiments and a luminance sensor that measures luminance when the light-emitting device emits light. In the present embodiment, as a control method of a display device, a luminance improvement control method for improving luminance by heating the light-emitting layer of the light-emitting device by the heat source when the luminance of the light-emitting device measured by the luminance sensor is lower than a target luminance will be described.

### Schematic Configuration of Main Portions of Display Device

FIG. 20 is a block diagram illustrating a schematic configuration of main portions of a display device 700 according to the present embodiment.

As illustrated in FIG. 20, the display device 700 according to the present embodiment includes, as a light-emitting device, a light-emitting device 71 including a heat source 72 for heating the light-emitting layer, a luminance sensor 73, a storage unit 74, and a control unit 80. The light-emitting device 71, the luminance sensor 73, and the storage unit 74 are connected to the control unit 80.

Further, the control unit 80 includes a light-emitting control unit 81, a luminance value determination unit 82, a heating control unit 83, and a luminance updating unit 84.

The light-emitting device 71 emits light by a current being applied from the light-emitting control unit 81. That is, the light-emitting control unit 81 controls the light emission of the light-emitting device 71. Specifically, the light-emitting control unit 81 applies, to the light-emitting device 71, a current of a predetermined current value set so that light is emitted at a desired luminance.

The luminance sensor 73 measures the luminance of at least one light-emitting device 71 when the light-emitting device 71 emits light. Examples of the luminance sensor 73 include a photodiode or a phototransistor having a photoelectric conversion function of receiving light from the PIXB and outputting a photocurrent. As the photodiode, for example, a known photodiode such as a silicon (Si) photodiode, an indium gallium arsenide (InGaAs) photodiode, a gallium arsenide phosphide (GaAsP) photodiode, or a germanium (Ge) photodiode can be used.

The display device 700 includes the luminance sensor 73 and, as described below, when the actual luminance of the light-emitting device 71 is measured by the luminance sensor 73 and is lower than a specific luminance value set in advance as a target luminance value due to deterioration or the like, the luminance can be improved by heating the light-emitting layer of the light-emitting device 71 by the heat source 72. Therefore, the luminance in accordance with a deteriorated state of the luminance of the light-emitting device 71 can be improved.

The luminance measured by the luminance sensor 73 is stored in the storage unit 74 as a luminance value. The storage unit 74 stores, as a first luminance value, the luminance measured by the luminance sensor 73 when the light-emitting device 71 emits light before being heated by the heat source 72. Further, when the first luminance value is less than the target luminance value set in advance, the storage unit 74 stores, as a second luminance value, the luminance when the light-emitting device 71 emits light after being heated by the heat source 72.

The luminance value stored in the storage unit 74 is read by a luminance value determination unit 82, as necessary. The luminance value determination unit 82 determines magnitudes of the two luminance values stored in the storage unit 74, and sends the determination result to a heating control unit 83 in a subsequent stage. Note that details of the luminance value determination process of the luminance value determination unit 82 will be described below.

Examples of the light-emitting device 71 include a light-emitting device having the same configuration as that of the light-emitting device 41B, the light-emitting device 51B, or the light-emitting device 61B. In other words, the light-emitting device 71 may be any one of the light-emitting device 41B, the light-emitting device 51B, and the light-emitting device 61B. Accordingly, examples of the light-emitting layer of the light-emitting device 71 include the QD layer 15B of the light-emitting device 41B, the light-emitting device 51B, or the light-emitting device 61B. Further, examples of the heat source 72 include the same heat source as the heat source of the light-emitting device 41B, the light-emitting device 51B, or the light-emitting device 61B.

The heat source 72 heats the light-emitting layer of the light-emitting device 71. Control of the heating operation of the heat source 72 (heating control of the light-emitting layer of the light-emitting device 71 by the heat source 72) is executed by the heating control unit 83. That is, the heating control unit 83 controls the heating of the light-emitting layer of the light-emitting device 71 by the heat source 72 in accordance with the determination result from the luminance value determination unit 82. For example, when the determination result of the luminance value determination unit 82 indicates that the heating of the light-emitting layer of the light-emitting device 71 by the heat source 72 is to be executed, the heating control unit 83 causes the heat source 72 to heat the light-emitting layer of the light-emitting device 71 under predetermined heating conditions. Here, the predetermined heating conditions includes at least a heating temperature and a heating time period. The heating temperature at this time is within a range from 80° C. to 100° C., and the heating time period is within a range from 30 minutes to 600 minutes. For this reason, the heating control unit 83 causes the heat source 72 to heat the light-emitting layer of the light-emitting device 71 at a temperature from 80° C. to 100° C. for 30 minutes to 600 minutes. At this time, the heating control unit 83 heats the light-emitting layer of the light-emitting device 71 at 80° C. for 60 minutes or at 100° C. for 30 minutes, for example.

The luminance updating unit 84 stores, in the storage unit 74 as the first luminance value, the luminance of the light-emitting device 71 measured by the luminance sensor 73 when the light-emitting device 71 emits light before being heated by the heat source 72. Further, when the first luminance value stored in the storage unit 74 is less than the target luminance value set in advance, the luminance updating unit 84 stores, in the storage unit 74 as the second luminance value, the luminance of the light-emitting device 71 measured by the luminance sensor 73 when the light-emitting device 71 emits light after the light-emitting layer of the light-emitting device 71 is heated by the heat source 72 under the predetermined heating conditions. Further, when the second luminance value stored in the storage unit 74 is equal to or greater than the first luminance value and less than the target luminance value, the luminance updating unit 84 overwrites the first luminance value with the second luminance value stored in the storage unit 74.

Note that, the first luminance value stored in the storage unit 74 being less than the target luminance value set in advance indicates that the luminance value determination unit 82 determined that the first luminance value stored in the storage unit 74 is less than the target luminance value set in advance. Further, the second luminance value stored in the storage unit 74 being equal to or greater than the first luminance value and less than the target luminance value indicates that the luminance value determination unit 82 determined that the second luminance value stored in the storage unit 74 is equal to or greater than the first luminance value and less than the target luminance value.

### Luminance Improvement Control Method

Next, an example of a luminance improvement control method of the display device 700 will be described below with reference to FIG. 21.

FIG. 21 is a flowchart illustrating a flow of processing of the luminance improvement control executed by the control unit 80 of the display device 700 illustrated in FIG. 20.

First, the luminance when the light-emitting device 71 emits light is measured by the luminance sensor 73 (step S51, luminance measurement process). Here, the luminance sensor 73 measures the luminance of the light-emitting device 71 when the light-emitting control unit 81 applies a current of a predetermined current value set in advance to the light-emitting device 71.

Note that examples of the predetermined current value described above include 10 mA. However, the above current value is an example, and the predetermined current value is not limited to the above current value.

Next, the luminance measured in the step S51 is stored in the storage unit 74 as the first luminance value (step S52, first luminance value storage process).

Next, the luminance value determination unit 82 determines whether the first luminance value stored in the storage unit 74 in step S52 is less than the target luminance value set in advance (first luminance value <target luminance value) (step S53, luminance value determination process).

Here, the target luminance value may be a value set in advance before product shipment or may be a value that can be set as desired by a user after product shipment. The target luminance value is stored in advance in the storage unit 74 before the luminance improvement control is performed by the control unit 80.

Next, in step S53, when the luminance value determination unit 82 determines that the first luminance value is less than the target luminance value (YES), the luminance of the light-emitting device 71 is determined to be deteriorated, and the heating control unit 83 heats the light-emitting device 71 by the heat source 72 under the predetermined heating conditions set in advance (step S54, light-emitting layer heating process).

Here, the predetermined heating conditions are, for example, 80° C. for 30 minutes. That is, the heating control unit 83 causes the heat source 72 to heat the light-emitting layer (QD layer) of the light-emitting device 71 at 80° C. for 30 minutes. Thus, in the light-emitting device 71, the fluorescence quantum efficiency of the light-emitting layer is improved by heating the light-emitting layer, and the luminance is thereby improved. Note that, the predetermined heating conditions are desirably set to, for example, a temperature from 80° C. to 100° C. within the range from 30 minutes to 600 minutes, as described in the first embodiment.

Note that, although desirably the heating conditions are set before product shipment, the heating conditions may be changed via a network after product shipment.

On the other hand, when the luminance value determination unit 82 determines that the first luminance value is not less than the target luminance value (NO) in the step S53, that is, when the first luminance value is equal to or greater than the target luminance value (first luminance value ≥luminance value set in advance), the luminance of the light-emitting device 71 is determined to be not deteriorated, and the processing is ended.

Further. the luminance sensor 73 measures the luminance when the light-emitting device 71 emits light after the heating in step S54 (step S55, post-heating luminance value measurement process).

Here, as in step S51, the luminance sensor 73 measures the luminance of the light-emitting device 71 after the light-emitting control unit 81 applies, to the light-emitting device 71, a current of a predetermined current value set in advance. As the predetermined current value at this time, the same current value as that in step S51 (for example, 10 mA) is used.

Next, the luminance measured in the step S55 is stored in the storage unit 74 as the second luminance value (step S56, second luminance value storage process).

Subsequently, the luminance value determination unit 82 determines whether the second luminance value stored in the storage unit 74 in step S56 is equal to or greater than the first luminance value stored in the storage unit 74 and less than the target luminance value (first luminance value <second luminance value <target luminance value) (step S57, post-heating luminance value determination process).

Next, in step S57, when the luminance value determination unit 82 determines that the above-described conditions (first luminance value <second luminance value <target luminance value) is not satisfied (NO), the processing is ended. That is, if the second luminance value is equal to or greater than the target luminance value (second luminance value ≥target luminance value), it is determined that the luminance of the light-emitting device 71 has been sufficiently improved by the heating and no further heating is required, and the processing is ended. On the other hand, if the second luminance value is less than the first luminance value (first luminance value >second luminance value), it is determined that the luminance of the light-emitting device 71 has deteriorated due to some cause (for example, malfunction of the heat source 72), and the processing is ended.

On the other hand, when the luminance value determination unit 82 determines in step S57 that the second luminance value is equal to or greater than the first luminance value and less than the target luminance value (YES), it is determined that the heating is insufficient, and the first luminance value is overwritten with the second luminance value stored in the storage unit 74 (step S58, luminance value updating process).

Further, after the first luminance value is overwritten with the second luminance value stored in the storage unit 74 in step S58, the processing proceeds to step S54, and the light-Attorney emitting device 71 is heated again under predetermined conditions set in advance. As the predetermined conditions at this time, the same conditions as those of step S54 are used.

As described above, each step of the luminance improvement control processing is repeated until the luminance value of the light-emitting device 71 exceeds the target luminance value or the luminance decreases due to the heating of the light-emitting device 71.

In the luminance improvement control processing, the luminance of the light-emitting device 71 is checked and heating is repeated, making it possible to achieve precise luminance improvement.

Note that, although the luminance sensor 73 may be provided for each PIX (for example, for each light-emitting device 71), a light-emitting device 71 for testing may be provided separately from the light-emitting device 71 for display, and a luminance sensor may be provided only for the light-emitting device 71 for testing. In this case, by changing the temperature and the heating time period applied from the heat source 72 to the light-emitting device 71 for testing in a stepwise manner, heating conditions under which the deteriorated luminance becomes a desired luminance (target luminance) can be found. If the heating conditions thus found are used as the heating conditions for the light-emitting device 71 for display having deteriorated luminance, there is no need to provide the luminance sensor 73 for determining the heating conditions to each light-emitting device for display, making it possible to inexpensively improve the luminance in accordance with the luminance deterioration state.

Note that the luminance improvement control processing is desirably performed periodically (for example, once a week, once every 100 hours of operation, or each set period), and is desirably performed during a time period when the user does not use the display device 700. Accordingly, step S51 is desirably performed periodically (for example, once a week, once every 100 hours of operation, or each set period), and is desirably performed during a time period when the user does not use the display device 700, such as during the night, for example. Note that the above-described luminance improvement control processing may be triggered by the switching of the power supply of the display device 700 from ON to OFF or the like.

However, the present embodiment is not limited thereto, and the display operation of the display device 700 and the luminance improvement control processing may be performed simultaneously. The frequency of performing the luminance improvement control processing is not particularly limited, and may be performed continually, for example.

### Modified Example

As described above, the present embodiment illustrates, as an example, a case in which the display device 700 includes the luminance sensor 73, the storage unit 74, and the control unit 80, and the light-emitting control unit 81, the luminance value determination unit 82, the heating control unit 83, and the luminance updating unit 84 of the control unit 80 perform the luminance improvement control processing described above.

However, the present embodiment is not limited to this example. For example, to simplify the luminance improvement control processing, the light-emitting layer (QD layer) of the light-emitting device 71 may be heated by the heat source 72 at a regular interval (for example, at a regular time interval such as once a week, once every 100 hours of operation, or each set period) without measuring the luminance. In this case, the control unit 80 need only include the light-emitting control unit 81 and the heating control unit 83. Note that, in this case, the heating operation of the heat source 72 is controlled by the heating control unit 83. Accordingly, the display device 700 may include the heating control unit 83 as a control unit that controls the heating operation of the heat source 72, and the heating control unit 83 may have a configuration in which the light-emitting layer (QD layer) of the light-emitting device 71 is heated by the heat source 72 at a regular time interval under heating conditions set in advance. Thus, the luminance can be simply improved at low cost.

Further, the luminance improvement control processing illustrated in FIG. 21 and the simplified luminance improvement control processing may be combined, and the simplified luminance improvement control processing may be performed a plurality of times and subsequently the luminance improvement control processing illustrated in FIG. 21 may be performed.

### Example of Implementation with Software

Note that control blocks (in particular, the light-emitting control unit 81, the luminance value determination unit 82, the heating control unit 83, and the luminance updating unit 84) of the display device 700 may be executed by a logic circuit (hardware) formed in an integrated circuit (IC chip) or the like, or may be executed by software.

In the latter case, the display device 700 includes a computer that executes an instruction of a program which is software for implementing each function. The computer includes, for example, at least one processor (control device) and includes at least one computer-readable recording medium storing the program. Further, in the computer, the processor reads and executes the program from the storage medium, whereby the object of the disclosure is achieved. For example, a central processing unit (CPU) can be used as the processor. In addition to a “non-transitory tangible medium”, for example, a read only memory (ROM) or the like, examples of the storage medium described above may include a tape, a disk, a card, a semiconductor memory, and a programmable logic circuit. Furthermore, a random access memory (RAM) or the like in which the program is loaded may be further provided. Furthermore, the program may be supplied to the computer through any transmission medium that can transmit the program (a communication network, broadcast waves, or the like). Note that an aspect of the disclosure can also be implemented in the form of data signals that are embedded in carrier waves, in which the program is implemented by electronic transmission.

The disclosure is not limited to the embodiments described above, and various modifications may be made within the scope of the claims. Embodiments obtained by appropriately combining technical approaches disclosed in the different embodiments also fall within the technical scope of the disclosure. Moreover, novel technical features may be formed by combining the technical approaches stated in each of the embodiments.

### REFERENCE SIGNS LIST

1, 41B, 51B, 61B, 71 Light-emitting device
12, 12B Anode (electrode)
13, 13B Hole injection layer (function layer)
14, 14B Hole transport layer (function layer, layer adjacent to light-emitting layer)
15, 15B QD layer (light-emitting layer)
16, 16B Electron transport layer (function layer, layer adjacent to light-emitting layer)
17 Cathode (electrode)
18 Bank
QD (quantum dot)
25a Core
25b Shell
40, 50, 60 Light-emitting device
42, 52, 53, 62 Heating element layer (heat source)
43, 63 Insulating layer
44 Heating power supply
45 Connection wiring line
72 Heat source
73 Luminance sensor
74 Storage unit
80 Control unit
83 Heating control unit (control unit)
400, 500, 600, 700 Display device

1. An electroluminescent device comprising:
a first electrode:
a second electrode; and
a light-emitting layer provided between the first electrode and the second electrode, the light-emitting layer includes the quantum dot,
the quantum dot comprising:
a core including Zn and Se; and
a shell composed of ZnS and provided on a surface of the core, adjacently to the core,
wherein the quantum dot emits blue light, is Cd free, and has a particle diameter within a range from 3 nm to 20 nm and a fluorescence lifetime in a thin film state of 50 ns or less.

2. An electroluminescent device comprising:
a first electrode:
a second electrode; and
a light-emitting layer provided between the first electrode and the second electrode, the light-emitting layer includes the quantum dot,
the quantum dot comprising:
a core composed of ZnSe; and
a shell composed of ZnS and provided on a surface of the core, adjacently to the core,
wherein the quantum dot emits blue light and is Cd free, and
3≤d≤20 and d−(6.1/((1240/λp)−2.7))^{1/2}≤3.2, where λp (nm) is a fluorescent peak wavelength and d (nm) is a particle diameter of the quantum dot.

3-5. (canceled)

6. The electroluminescent device according to claim 1, further comprising:
at least one heat source configured to heat the light-emitting layer.

7. The electroluminescent device according to claim 6, comprising:
at least one function layer provided at least either between the first electrode and the light-emitting layer, or between the second electrode and the light-emitting layer,
wherein the heat source is formed in the at least one function layer, in a layer adjacent to the light-emitting layer.

8. The electroluminescent device according to claim 7, comprising:
a bank configured to cover an edge of the first electrode,
wherein the first electrode, the light-emitting layer, and the second electrode are layered in this order from a lower layer side,
a first function layer is provided at least between the second electrode and the light-emitting layer,
the bank is covered with the first function layer, and
the heat source is formed in the first function layer, extending across an upper face of the bank.

9. The electroluminescent device according to claim 6,
wherein the heat source is formed in at least the light-emitting layer.

10. The electroluminescent device according to claim 6,
wherein the heat source is formed in the light-emitting layer only.

11. The electroluminescent device according to claim 6,
wherein the heat source has a thin line shape.

12. The electroluminescent device according to claim 11,
wherein the heat source has a line width of 100 nm or less.

13. The electroluminescent device according to claim 11,
wherein the heat source has a thickness within a range from 5 nm to 100 nm.

14. The electroluminescent device according to claim 11,
wherein the heat source has a cross-sectional area of a plane parallel to a line width direction of 0.01 μm² or less.

15. The electroluminescent device according to claim 11,
wherein the heat source is an Al wiring line having a line width and a thickness from 10 nm to 100 nm each.

16. The electroluminescent device according to claim 11,
wherein the heat source is provided in a layer on a light-output face side of the light-emitting layer.

17. The electroluminescent device according to claim 6,
wherein the heat source has a flat plate shape.

18. The electroluminescent device according to claim 17,
wherein the heat source is provided in a layer on a face side opposite to a light-output face of the light-emitting layer.

19. The electroluminescent device according to claim 6, comprising:
a bank configured to cover an edge of the first electrode,
wherein the heat source is formed in the bank.

20. The electroluminescent device according to claim 19,
wherein the heat source faces at least the light-emitting layer with a portion of the bank interposed therebetween.

21. The electroluminescent device according to claim 19,
wherein the heat source is formed in the bank, facing only the light-emitting layer in a horizontal direction with a portion of the bank interposed therebetween.

22. The electroluminescent device according to claim 21,
wherein the heat source is formed in the bank at the same height from a reference surface as a height of the light-emitting layer from the reference surface and at the same thickness as a thickness of the light-emitting layer.

23. The electroluminescent device according to claim 19,
wherein the light source has a block shape.

24. (canceled)

25. A display device comprising:
a plurality of pixels including at least one blue pixel,
wherein each of the plurality of pixels is provided with an electroluminescent device, and
the blue pixel is provided with the electroluminescent device according to claim 6.

26. The display device according to claim 25, comprising:
a plurality of the blue pixels,
wherein the heat source extends across, among the plurality of pixels, at least two of the plurality of the blue pixels.

27. The display device according to claim 25, further comprising:
a luminance sensor configured to measure, when at least one of the electroluminescent devices emits light, a luminance of the electroluminescent device.

28-32. (canceled)
